(19) United States
(12) Patent Application Publication
(10) Pub. No.: US 2019/0094692 A1
(43) Pub. Date: Mar. 28, 2019

(54) PHOTOSENSITIVE RESIN COMPOSITION, CURED FILM, DISPLAY DEVICE, AND PATTERN FORMING METHOD

(71) Applicant: TOKYO OHKA KOGYO CO., LTD., Kawasaki-shi (JP)

(72) Inventors: Tatsuro ISHIKAWA, Kawasaki-shi (JP); Naozumi MATSUMOTO, Kawasaki-shi (JP); Dai SHIOTA, Kawasaki-shi (JP)

(21) Appl. No.: 16/136,717

(22) Filed: Sep. 20, 2018

(30) Foreign Application Priority Data
Sep. 26, 2017 (JP) 2017-185324
Dec. 26, 2017 (JP) 2017-249820

(51) Int. Cl. G03F 7/031; G03F 7/032; G03F 7/075; G03F 7/016; G03F 7/16; G03F 7/26; C08K 3/04; C08K 5/00; C09B 3/14; C09B 23/01

(52) U.S. Cl. CPC G03F 7/031; G03F 7/032; G03F 7/0755; G03F 7/0163; C09B 23/0075; G03F 7/265; C08K 3/04; C08K 5/0041; C09B 3/14; G03F 7/168

(57) ABSTRACT

A photosensitive resin composition which gives a cured film having high light shielding properties and enables stable curing by baking at low temperature, a cured film obtained by curing the composition, a display device provided with the cured film, and a pattern forming method using the composition. A light shielding film-forming process which does not impart thermal damage to a light-emitting element with respect to a substrate provided with a light-emitting element. In a photosensitive resin composition including a binder resin, a photopolymerizable compound, a photopolymerization initiator, a coloring agent, and a thermosetting compound, a carbon black and/or an inorganic black pigment, and an organic pigment are used in combination as the coloring agent, and a photosensitive resin composition in which T2/T1 is 0.80 or more is used.

### RELATED APPLICATIONS

This application claims to from Japanese Patent Application No. 2017-185324, filed Sep. 26, 2017; and Japanese Patent Application No. 2017-249820, filed Dec. 26, 2017, the entire contents of which are incorporated herein by reference.

### BACKGROUND OF THE INVENTION

### Field of the Invention

The present invention relates to a photosensitive resin composition, a cured film obtained by curing the photosensitive resin composition, a display device provided with the cured film, and a pattern forming method using the photosensitive resin composition mentioned above.

### Related Art

In panels for display devices such as a liquid crystal display device, light shielding films patterned with black matrix, black column spacer, or the like are usually formed. There have been proposed various photosensitive compositions including a light shielding black pigment and a photopolymerization initiator, which are used for forming a light shielding film in these applications.

There have been proposed, as these photosensitive compositions, for example, black resin compositions including a perylene-based black pigment and carbon black which are organic pigments (see Patent Document 1). It is generally recognized that the carbon black exhibits high light shielding properties and the perylene-based black pigment is a material having low electrical conductivity. Therefore, the black resin composition mentioned in Patent Document 1 is excellent in fluidity and stability and is expected to be capable of forming a cured film excellent in light shielding properties, electrical properties, transmittance in a near infrared region, and the like.
Patent Document 1: Japanese Unexamined Patent Application, Publication No. 2012-068613

### SUMMARY OF THE INVENTION

However, in recent days, a light shielding cured film may have been formed in image display devices such as an organic EL display using a material having low heat resistance. In this case, it is desirable that a cured film cured satisfactorily by baking at lower temperature can be formed. The black resin composition mentioned in Patent Document 1 left room for improvement from the point of view of stably curing at low temperature. From such circumstances, there is also a technical need for a process which can form a light shielding film without imparting thermal damage to a light-emitting element used in an image display device.

The present invention has been made in light of the problems mentioned above, and an object thereof is to provide a photosensitive resin composition which gives a cured film having high light shielding properties and enables stable curing by baking at low temperature, a cured film obtained by curing the photosensitive resin composition, a display device provided with the cured film, and a pattern forming method using the photosensitive resin composition mentioned above. Another object thereof is to provide a forming method capable of forming a light shielding film without imparting thermal damage to a light-emitting element used in a display device.

The present inventors have found that the above-mentioned problems can be solved by using as (D) a coloring agent, (D1) a carbon black and/or an inorganic black pigment in combination with (D2) an organic pigment in a photosensitive resin composition including (A) a binder resin, (B) a photopolymerizable compound, (C) a photopolymerization initiator, (D) a coloring agent, (E) a thermosetting compound, and thus the present invention has been completed. Specifically, the present invention provides the following.

A first aspect of the present invention is a photosensitive resin composition including:

(A) a binder resin,
(B) a photopolymerizable compound,
(C) a photopolymerization initiator,
(D) a coloring agent, and
(E) a thermosetting compound, wherein
the (D) coloring agent includes (D1) a carbon black and/or an inorganic black pigment, and (D2) an organic black pigment, and wherein
when the photosensitive resin composition is cured under the following conditions to obtain a cured film, T2/T1 is 0.80 or more, where T1 is a thickness of the cured film and T2 is a thickness of the cured film after immersing in propylene glycol monomethyl ether acetate for 300 seconds:

### (Conditions)

the photosensitive resin composition is applied on a glass substrate in a thickness of 1±0.1 μm, followed by exposure at an exposure dose of 200 mJ/cm² and further baking under conditions at 100° C. for 30 minutes to form a cured film.

A second aspect of the present invention is a photosensitive resin composition including:

(A) a binder resin,
(B) a photopolymerizable compound,
(C) a photopolymerization initiator,
(D) a coloring agent, and
(E) a thermosetting compound, wherein
the (D) coloring agent includes (D1) a carbon black and/or an inorganic black pigment, and (D2) an organic black pigment, and wherein
the amount of (D1) the carbon black and/or the inorganic black pigment in the total (D) coloring agent is 30% by mass or more and 65% by mass or less, and the amount of (D2) the organic black pigment is 10% by mass or more and 70% by mass or less.

A third aspect of the present invention is a cured film obtained by curing the photosensitive resin composition according to the first aspect or the second aspect.

A fourth aspect of the present invention is a display device including the cured film according to the third aspect.

A fifth aspect of the present invention is a pattern forming method, which includes the steps of:

applying the photosensitive resin composition according to the first aspect or the second aspect to form a coating film, regioselectively exposing the coating film,
developing the exposed coating film, and
baking the developed coating film to obtain a cured film.

A sixth aspect of the present invention is a pattern forming method, which includes the steps of:

applying the photosensitive resin composition according to the first aspect or the second aspect on a substrate provided with a light-emitting element to form a coating film,
regioselectively exposing the coating film,
developing the exposed coating film, and
baking the developed coating film to obtain a cured film.

According to the present invention, it is possible to provide a photosensitive resin composition which gives a cured film having high light shielding properties and enables stable curing by baking at low temperature, a cured film obtained by curing the photosensitive resin composition, a display device provided with the cured film, and a pattern forming method using the photosensitive resin composition mentioned above. According to the present invention, it is possible to provide a light shielding film forming method capable of forming a light shielding film without imparting thermal damage to a light-emitting element used in a display device.

### DETAILED DESCRIPTION OF THE INVENTION

The present invention will be described below by way of preferred embodiments. A range expressed herein using “to” is defined as a range that includes the numbers or ratios at both ends.

### <<First Photosensitive Resin Composition>>

The first photosensitive resin composition includes (A) a binder resin, (B) a photopolymerizable compound, (C) a photopolymerization initiator, (D) a coloring agent, and (E) a thermosetting compound. The (D) coloring agent includes (D1) a carbon black and/or an inorganic black pigment, and (D2) an organic pigment in combination. When the photosensitive resin composition is cured under the following conditions to obtain a cured film, T2/T1 is 0.80 or more, where T1 is a thickness of the cured film and T2 is a thickness of the cured film after immersing in propylene glycol monomethyl ether acetate for 300 seconds:

### (Conditions)

the photosensitive resin composition is applied on a glass substrate in a thickness of 1±0.1 μm, followed by exposure at an exposure dose of 200 mJ/cm² and further baking under conditions at 100° C. for 30 minutes to form a cured film.

There is no particular limitation on the method in which the above-mentioned value T2/T1 is adjusted to 0.80 or more.

Preferred methods include a method of appropriately adjusting the amount of (D1) the carbon black and/or inorganic black pigment, and the amount of (D2) the organic pigment in the entire (D) coloring agent. In this case, by adjusting a blending ratio of the two, it is possible to enhance the light transmitting properties in a wavelength region which can be utilized by (C) the photopolymerization initiator in the photosensitive resin composition without impairing the light shielding properties of the photosensitive resin composition. Therefore, when the coating film made of the photosensitive resin composition is exposed, curing by exposure can sufficiently proceed. Furthermore, since the present photosensitive resin composition contains (E) the thermosetting compound, a cured film cured satisfactorily is formed even if baking at low temperature is performed after exposure.

Other preferred methods include a method in which a compound with high sensitivity is blended as (C) the photopolymerization initiator, a method in which the amount of (C) the photopolymerization initiator to be used is increased as long as it does not interfere with the properties of the photosensitive resin composition. According to these methods, when the coating film made of the photosensitive resin composition is exposed, a cured film cured satisfactorily is formed by sufficient proceeding of the curing by exposure even if baking at low temperature is performed after exposure. “Exposure” in (Conditions) in the present specification is defined as exposure which was performed by a high pressure mercury lamp under conditions of an exposure gap of 50 μm, using Proximity Aligner (product name: TME-150RTO) manufactured by TOPCON CORPORATION. To obtain the coating film having a thickness of 1±0.1 μm, prebaking may be performed under conditions where each component is not cured. T2/T1 is more preferably 0.82 or more, still more preferably 0.85 or more, and yet more preferably 0.90 or more. T2/T1 is preferably 1 or less.

Regarding the first photosensitive resin composition, essential or optional components will be described below. In the description of the first photosensitive resin composition, when simply referred to as “photosensitive resin composition”, it means the first photosensitive resin composition.

### <(A) Binder Resin>

The photosensitive composition includes (A) a binder resin. Therefore, when the photosensitive resin composition is applied, satisfactory film-forming properties are exhibited. It is easy to form a cured film having satisfactory shape and mechanical properties using the photosensitive resin composition. There is no particular limitation on the (A) binder resin, and it is possible to appropriately select from resins which have conventionally been blended in various photosensitive resin compositions.

Since developability of the photosensitive resin composition with an alkali developing solution is satisfactory, and it is easy to form a cured film having satisfactory shape using the photosensitive resin composition, the (A) binder resin is preferably an alkali-soluble resin. Herein, in the present specification, the alkali-soluble resin is a resin having a functional group imparting alkali-solubility (for example, a phenolic hydroxy group, a carboxy group, a sulfonic group, and the like).

It is preferred that the (A) binder resin such as an alkali-soluble resin contains a resin having a photopolymerizable group in a molecule. In this case, when a cured film is formed using the photosensitive resin composition, crosslinking occurs between the (A) binder resins, or the (A) binder resin and the (B) photopolymerizable compound. Therefore, even if the baking temperature at which a cured film is formed is a temperature such as 150° C. or lower for example, it is easy to form a cured film excellent in solvent resistance and adhesion to a substrate. Typical examples of the photopolymerizable group include functional groups having an unsaturated double bond, such as a vinyl group, an allyl group, and a (meth)acryloyl group.

It is preferred that the (A) binder resin such as an alkali-soluble resin contains a resin having a cardo structure in a molecule. The cardo structure will be described in detail later. When using the resin having a cardo structure in a molecule, it is easy to obtain a photosensitive resin composition excellent in resolution, and it is easy to form a cured film which scarcely causes excessive flow due to heating, using the photosensitive resin composition.

Suitable examples of the alkali-soluble resin suitable as the (A) binder resin will be described.

[Resin Having a Cardo Structure (a-1)]

It is possible to use, as the resin having a cardo structure (a-1) (hereinafter also referred to as cardo resin (a-1)), a resin which has a cardo structure in a molecule and has predetermined alkali-solubility. The cardo structure means a skeleton in which a second cyclic structure and a third cyclic structure are bonded to one ring carbon atom constituting the first cyclic structure. The second cyclic structure and the third cyclic structure may be the same or different. Typical examples of the cardo structure include a skeleton in which two aromatic rings (for example, benzene ring) are bonded to the carbon atom at the 9-position of a fluorene ring.

There is no particular limitation on the cardo resin (a-1), and conventionally known resins can be used. Among the conventionally known resins, a resin represented by the following formula (a-1) is preferable. The resin represented by the following formula (a-1) has a (meth)acryloyl group in a molecule, as shown in the following formula (a-2). Therefore, the resin represented by the following formula (a-1) corresponds to a resin having a photopolymerizable group in a molecule.

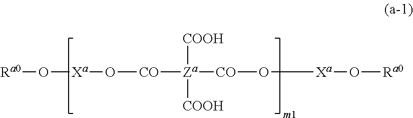

In the formula (a-1), X^{a} represents a group represented by the following formula (a-2). m1 represents an integer of 0 or more and 20 or less.

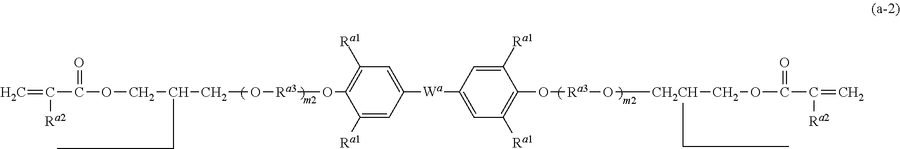

In the formula (a-2), R^{a1}s each independently represent a hydrogen atom, a hydrocarbon group having 1 or more and 6 or less carbon atoms, or a halogen atom, R^{a1}s each independently represent a hydrogen atom or methyl group, R^{a3}s each independently represent a straight-chain or branched-chain alkylene group, m2 represents 0 or 1, and W^{a} represents a group represented by the following formula (a-3).

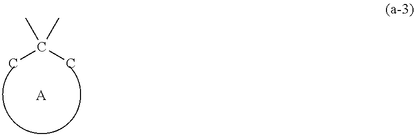

In the formula (a-2), R^{a3} is preferably an alkylene group having 1 or more and 20 or less carbon atoms, more preferably an alkylene group having 1 or more and 10 or less carbon atoms, particularly preferably an alkylene group having 1 or more and 6 or less carbon atoms, and the most preferably an ethane-1,2-diyl group, a propane-1,2-diyl group, and a propane-1,3-diyl group.

The ring A in the formula (a-3) represents an optionally substituted alicyclic ring which may be fused with an aromatic ring. The alicyclic ring may be an aliphatic hydrocarbon ring or an aliphatic heterocycle. Examples of the alicyclic ring include monocycloalkanes, bicycloalkanes, tricycloalkanes, tetracycloalkanes, and the like. Specific examples include monocycloalkanes such as cyclopentane, cyclohexane, cycloheptane and cyclooctane, and adamantane, norbornane, isobornane, tricyclodecane and tetracyclododecane. The aromatic ring which may be fused with the alicyclic ring may be an aromatic hydrocarbon ring or an aromatic heterocycle, and preferably an aromatic hydrocarbon ring. Specifically, a benzene ring and a naphthalene ring are preferred.

Suitable examples of the divalent group represented by the formula (a-3) include following groups.

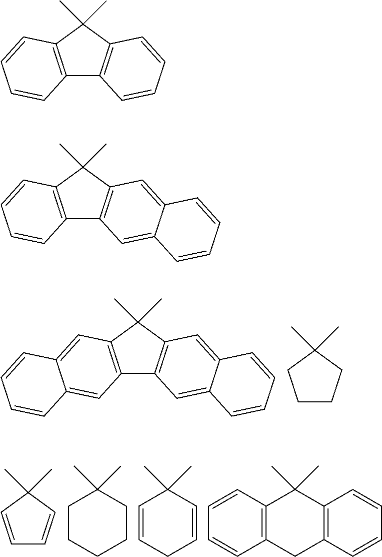

The divalent group X^{a} in the formula (a-1) is introduced into the cardo resin (a-1) by reacting a tetracarboxylic acid anhydride providing a residual group Z^{a} with a diol compound represented by the following formula (a-2a).

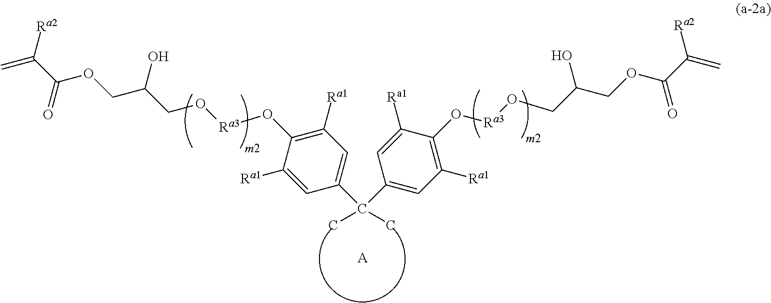

In the formula (a-2a), R^{a1}, R^{a2}, R^{a3}, and m2 are the same as those described for the formula (a-2). In the formula (a-2a), Ring A is the same as that described for the formula (a-3).

A diol compound represented by the formula (a-2a) can be produced, for example, by the following method. First, the hydrogen atom in a phenolic hydroxyl group possessed by the diol compound represented by the following formula (a-2b) is optionally substituted with a group represented by —R^{a3}—OH in accordance with a conventional method, followed by glycidylization with epichlorohydrin to obtain an epoxy compound represented by the following formula (a-2c). Then, the epoxy compound represented by the following formula (a-2c) is reacted with acrylic acid or methacrylic acid to obtain a diol compound represented by the formula (a-2a). In the formula (a-2b) and the formula (a-2c), R^{a1}, R^{a3}, and m2 are as described for the formula (a-2). The ring A in the formula (a-2b) and the formula (a-2c) is as described for the formula (a-3). The method for producing a diol compound represented by the formula (a-2a) is not limited to the method mentioned above.

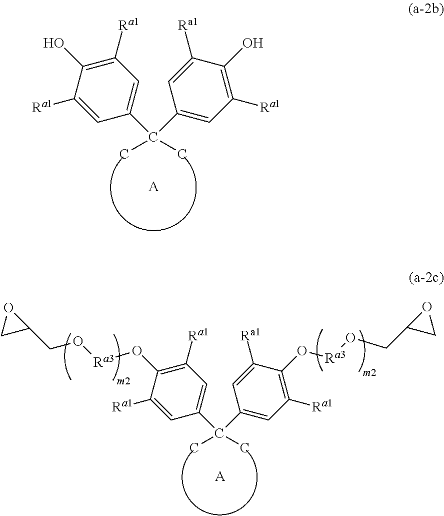

Suitable examples of the diol compound represented by the formula (a-2b) include following diol compounds.

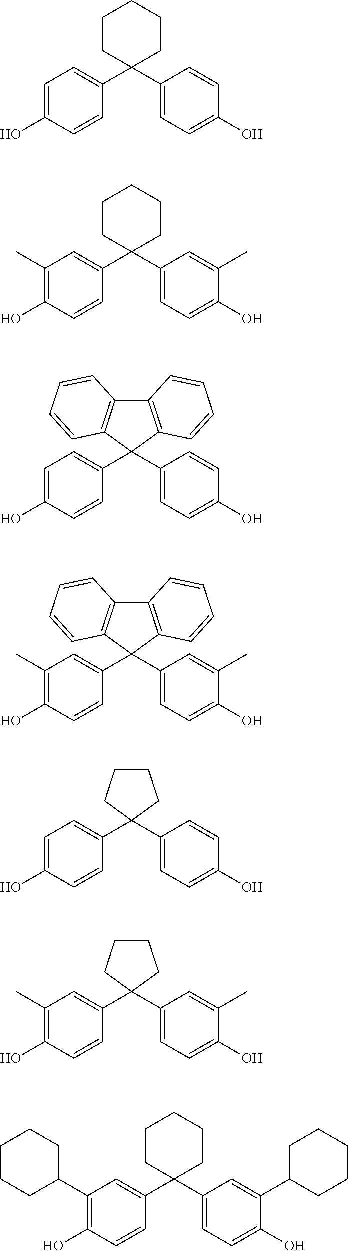

In the formula (a-1), R^{a0} is a hydrogen atom or a group represented by —CO—Y^{a}—COOH. Herein, Y^{a} represents a residue obtainable by removing an acid anhydride group (—CO—O—CO—) from dicarboxylic acid anhydride. Examples of the dicarboxylic anhydride include maleic anhydride, succinic anhydride, itaconic anhydride, phthalic anhydride, tetrahydrophthalic anhydride, hexahydrophthalic anhydride, methylendomethylenetetrahydrophthalic anhydride, chlorendic anhydride, methyltetrahydrophthalic anhydride, anhydrous glutaric acid, and the like.

Furthermore, in the formula (a-1), Z^{a} is a residue obtainable by removing two acid anhydride groups from tetracarboxylic acid dianhydride. Examples of the tetracarboxylic acid dianhydride include tetracarboxylic acid dianhydride represented by the following formula (a-4), pyromellitic dianhydride, benzophenonetetracarboxylic dianhydride, biphenyltetracarboxylic dianhydride, diphenylethertetracarboxylic dianhydride, and the like. In addition, in the formula (a-1), m represents an integer of 0 or more and 20 or less.

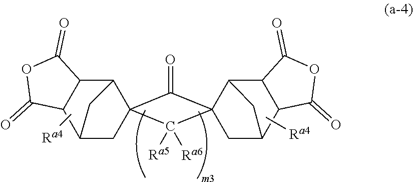

In the formula (a-4), R^{a4}, R^{a5}, and R^{a6} each independently represent one selected from the group consisting of a hydrogen atom, an alkyl group having 1 or more and 10 or less carbon atoms, and a fluorine atom, and m3 represents an integer of 0 or more and 12 or less.

An alkyl group which may be selected as R^{a4} in the formula (a-4) is an alkyl group having 1 or more and 10 or less carbon atoms. By setting the number of carbon atoms of the alkyl group in this range, heat resistance of the obtained carboxylic acid ester is especially improved. When R^{a4} is alkyl group, the number of carbon atoms thereof is preferably 1 or more and 6 or less, more preferably 1 or more and 5 or less, further preferably 1 or more and 4 or less, and particularly preferably 1 or more and 3 or less, since a cardo resin having excellent heat resistance is easily obtained. When R^{a4} is alkyl group, the alkyl group may be any one of straight-chain and branched-chain alkyl groups.

R^{a4} in the formula (a-4) each independently represent a hydrogen atom or an alkyl group having 1 or more and 10 or less carbon atoms, more preferably, since a cardo resin having excellent heat resistance is easily obtained. R^{a4} in the formula (a-4) is more preferably a hydrogen atom, a methyl group, an ethyl group, an n-propyl group or an isopropyl group, and particularly preferably a hydrogen atom or a methyl group. Plural R^{a4}s in the formula (a-4) are preferably the same group, since a tetracarboxylic acid dianhydride with high purity can easily be prepared.

In the formula (a-4), m3 represent an integer of 0 or more and 12 or less. When value of m3 is 12 or less, purification of the tetracarboxylic acid dianhydride is easy. The upper limit of m3 is preferably 5, and more preferably 3, since purification of the tetracarboxylic acid dianhydride is easy. The lower limit of m3 is preferably 1, and more preferably 2, in view of the chemical stability of the tetracarboxylic acid dianhydride. In the formula (a-4), m3 is preferably 2 or 3.

An alkyl group having 1 or more and 10 or less carbon atoms which may be selected as R^{a5} and R^{a6} in the formula (a-4) is same as the alkyl group having 1 or more and 10 or less carbon atoms which may be selected as R^{a4}. R^{a5} and R^{a6} are preferably a hydrogen atom or an alkyl group having 1 or more and 10 or less (preferably 1 or more and 6 or less, more preferably 1 or more and 5 or less, still more preferably 1 or more and 4 or less, and particularly preferably 1 or more and 3 or less), and more preferably a hydrogen atom or a methyl group, since purification of tetracarboxylic acid dianhydride is easy.

Examples of the tetracarboxylic dianhydride represented by the formula (a-4) include norbornane-2-spiro-α-cyclopentanone-α′-spiro-2″-norbornane-5,5″,6,6″-tetracarboxylic dianhydride (another name “norbornane-2-spiro-2′-cyclopentanone-5′-spiro-2”-norbornane-5,5″,6,6″-tetracarboxylic dianhydride″), methylnorbornane-2-spiro-α-cyclopentanone-α′-spiro-2″-(methylnorbornane)-5,5″,6,6″-tetracarboxylic dianhydride, norbornane-2-spiro-α-cyclohexanone-α′-spiro-2″-norbornane-5,5″,6,6″-tetracarboxylic dianhydride (another name “norbornane-2-spiro-2′-cyclohexanone-6′-spiro-2”-norbornane-5,5″,6,6″-tetracarboxylic dianhydride″), methylnorbornane-2-spiro-α-cyclohexanone-α′-spiro-2″-(methylnorbornane)-5,5″,6,6″-tetracarboxylic dianhydride, norbornane-2-spiro-α-cyclopropanone-α′-spiro-2″-norbornane-5,5″,6,6″-tetracarboxylic dianhydride, norbornane-2-spiro-α-cyclobutanone-α′-spiro-2″-norbornane-5,5″,6,6″-tetracarboxylic dianhydride, norbornane-2-spiro-α-cycloheptanone-α′-spiro-2″-norbornane-5,5″,6,6″-tetracarboxylic dianhydride, norbornane-2-spiro-α-cyclooctanone-α′-spiro-2″-norbornane-5,5″,6,6″-tetracarboxylic dianhydride, norbornane-2-spiro-α-cyclononanone-α′-spiro-2″-norbornane-5,5″,6,6″-tetracarboxylic dianhydride, norbornane-2-spiro-α-cyclodecanone-α′-spiro-2″-norbornane-5,5″,6,6″-tetracarboxylic dianhydride, norbornane-2-spiro-α-cycloundecanone-α′-spiro-2″-norbornane-5,5″,6,6″-tetracarboxylic dianhydride, norbornane-2-spiro-α-cyclododecanone-α′-spiro-2″-norbornane-5,5″,6,6″-tetracarboxylic dianhydride, norbornane-2-spiro-α-cyclotridecanone-α′-spiro-2″-norbornane-5,5″,6,6″-tetracarboxylic dianhydride, norbornane-2-spiro-α-cyclotetradecanone-α′-spiro-2″-norbornane-5,5″,6,6″-tetracarboxylic dianhydride, norbornane-2-spiro-α-cyclopentadecanone-α′-spiro-2″-norbornane-5,5″,6,6″-tetracarboxylic dianhydride, norbornane-2-spiro-α-(methylcyclopentanone)-α′-spiro-2″-norbornane-5,5″,6,6″-tetracarboxylic dianhydride, norbornane-2-spiro-α-(methylcyclohexanone)-α′-spiro-2″-norbornane-5,5″,6,6″-tetracarboxylic dianhydride, and the like.

A weight average molecular weight of a cardo resin (a-1) is preferably 1,000 or more and 40,000 or less, more preferably 1,500 or more and 30,000 or less, and still more preferably 2,000 or more and 10,000 or less. When the weight average molecular weight is in above-mentioned range, sufficient heat resistance and mechanical strength of the cured film can be obtained while satisfactory heat resistance and mechanical strength are obtained.

[Novolak Resin (a-2)]

From the viewpoint of imparting high heat resistance causing less flow or deformation due to heat to a cured film, the (A) binder resin preferably contains, as the alkali-soluble resin, a novolak resin (a-2). It is possible to use, as the novolak resin (a-2), various novolak resins which have been conventionally blended in the photosensitive resin composition. The novolak resin (a-2) is preferably obtained by subjecting an aromatic compound having a phenolic hydroxy group (hereinafter simply referred to as “phenols”) and aldehydes to cause addition condensation in the presence of an acid catalyst.

### (Phenols)

Examples of phenols used to fabricate the novolak resin (a-2) include phenol; cresols such as o-cresol, m-cresol, and p-cresol; xylenols such as 2,3-xylenol, 2,4-xylenol, 2,5-xylenol, 2,6-xylenol, 3,4-xylenol, and 3,5-xylenol; ethylphenols such as o-ethylphenol, m-ethylphenol, and p-ethylphenol; alkylphenols such as 2-isopropylphenol, 3-isopropylphenol, 4-isopropylphenol, o-butylphenol, m-butylphenol, p-butylphenol, and p-tert-butylphenol; trialkylphenols such as 2,3,5-trimethylphenol and 3,4,5-trimethylphenol; polyhydric phenols such as resorcinol, catechol, hydroquinone, hydroquinone monomethyl ether, pyrogallol, and phloroglucinol; alkylpolyhydric phenols (any alkyl group has 1 or more and 4 or less carbon atoms) such as alkylresorcin, alkylcatechol, and alkylhydroquinone; α-naphthol; β-naphthol; hydroxydiphenyl; and bisphenol A. These phenols can be used alone or in combination of two or more types thereof.

Among these phenols, m-cresol and p-cresol are preferable, and it is more preferable to use m-cresol and p-cresol in combination. In this case, it is possible to adjust various properties such as heat resistance of the cured film formed by using the photosensitive resin composition by adjusting a blending ratio of the two. The blending ratio of m-cresol to p-cresol is not particularly limited and is preferably 3/7 to 8/2 in terms of a molar ratio of m-cresol/p-cresol. It is possible to easily obtain a photosensitive resin composition capable of forming a cured film excellent in heat resistance by using m-cresol and p-cresol at a ratio in the above range.

A novolak resin produced by using m-cresol in combination with 2,3,5-trimethylphenol is also preferable. When using such a novolak resin, it is possible to particularly easily obtain a photosensitive resin composition capable of forming a cured film having high heat resistance that causes less flow or deformation due to heat. The blending ratio of m-cresol to 2,3,5-trimethylphenol is not particularly limited and is preferably 70/30 to 95/5 in terms of a molar ratio of m-cresol/2,3,5-trimethylphenol.

### (Aldehydes)

Examples of aldehydes used to fabricate a novolak resin (a-2) include formaldehyde, paraformaldehyde, furfural, benzaldehyde, nitrobenzaldehyde, and acetaldehyde. These aldehydes can be used alone or in combination of two or more types thereof.

### (Acid Catalyst)

Examples of the acid catalyst used to fabricate a novolak resin (a-2) include inorganic acids such as hydrochloric acid, sulfuric acid, nitric acid, phosphoric acid, and phosphorous acid; organic acids such as formic acid, oxalic acid, acetic acid, diethylsulfuric acid, and paratoluenesulfonic acid; and metal salts such as zinc acetate. These acid catalysts can be used alone or in combination of two or more types thereof.

### (Molecular Weight)

Regarding a polystyrene-equivalent weight average molecular weight (Mw; hereinafter also simply referred to as “weight average molecular weight”) of the novolak resin (a-2), from a viewpoint of the heat resistance of a cured film formed by using the photosensitive resin composition, the lower limit is preferably 2,000, more preferably 5,000, particularly preferably 10,000, still more preferably 15,000, and most preferably 20,000, and the upper limit is preferably 50,000, more preferably 45,000, still more preferably 40,000, and most preferably 35,000.

It is possible to use, as the novolak resin (a-2), at least two novolak resins each having a different polystyrene-equivalent weight average molecular weight in combination. By using those each having a different weight average molecular weight in combination, it is possible to keep balance between the developability of the photosensitive resin composition and the heat resistance of a cured film formed by using the photosensitive resin composition.

[Modified Epoxy Resin (a-3)]

In view of easily imparting high water resistance to the cured film, the (A) binder resin may contain, as the alkali-soluble resin, a polybasic anhydride (a-3c) adduct (a-3) of a reaction product of an epoxy compound (a-3a) and an unsaturated group-containing carboxylic acid (a-3b). Such adduct is also referred to as “modified epoxy resin (a-3)”. In the specification and claims of the present application, the compound which corresponds to the above definition and does not correspond to the resin (a-1) having a cardo structure mentioned above is referred to as a modified epoxy resin (a-3).

The epoxy compound (a-3a), the unsaturated group-containing carboxylic acid (a-3b), and the polybasic anhydride (a-3c) will be described below.

<Epoxy Compound (a-3a)>

The epoxy compound (a-3a) is not particularly limited as long as it is a compound having an epoxy group, and may be either an aromatic epoxy compound having an aromatic group or an aliphatic epoxy compound having no aromatic group, and is preferably an aromatic epoxy compound having an aromatic group. The epoxy compound (a-3a) may be either a monofunctional epoxy compound or a difunctional or higher polyfunctional epoxy compound, and is preferably a polyfunctional epoxy compound. The upper limit of the number of functional groups of the polyfunctional epoxy compound is not particularly limited and is, for example, 4 or less.

Specific examples of the epoxy compound (a-3a) include difunctional epoxy resins such as a bisphenol A type epoxy resin, a bisphenol F type epoxy resin, a bisphenol S type epoxy resin, a bisphenol AD type epoxy resin, a naphthalene type epoxy resin, and a biphenyl type epoxy resin; glycidyl ester type epoxy resins such as a dimer acid glycidyl ester and a triglycidyl ester; glycidyl amine type epoxy resins such as tetraglycidyl aminodiphenylmethane, triglycidyl-p-aminophenol, tetraglycidyl metaxylylenediamine, and tetraglycidyl bisaminomethylcyclohexane; heterocyclic epoxy resins such as triglycidyl isocyanurate; trifunctional type epoxy resins such as phloroglucinol triglycidyl ether, trihydroxybiphenyl triglycidyl ether, trihydroxyphenylmethane triglycidyl ether, glycerin triglycidyl ether, 2-[4-(2,3-epoxypropoxy)phenyl]-2-[4-[1,1-bis[4-(2,3-epoxypropoxy)phenyl]ethyl]phenyl]propane, and 1,3-bis[4-[1-[4-(2,3-epoxypropoxy)phenyl]-1-[4-[1-[4-(2,3-epoxypropoxy)phenyl]-1-methylethyl]phenyl]ethyl]phenoxy]-2-propanol; and tetrafunctional type epoxy resins such as tetrahydroxyphenylethane tetraglycidyl ether, tetraglycidyl benzophenone, bisresorcinol tetraglycidyl ether, and tetraglycidoxybiphenyl.

The epoxy compound (a-3a) is preferably an epoxy compound having a biphenyl skeleton. It is preferred that the epoxy compound having a biphenyl skeleton has at least one biphenyl skeleton represented by the following formula (a-3a-1) in a main chain. The upper limit of the number of biphenyl skeletons represented by the following formula (a-3a-1) in the main chain is not particularly limited and is, for example, 10 or less. The epoxy compound having a biphenyl skeleton is preferably a polyfunctional epoxy compound having two or more epoxy groups. The upper limit of the number of functional groups of the polyfunctional epoxy compound is not particularly limited and is, for example, 4 or less. It is easy to obtain a photosensitive resin composition capable of forming a cured film excellent in balance between the sensitivity and the developability, and excellent in the adhesion to a substrate by using the epoxy compound having a biphenyl skeleton.

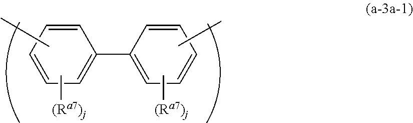

In the formula (a-3a-1), R^{a7} each independently is a hydrogen atom, an alkyl group having 1 or more and 12 or less carbon atoms, a halogen atom, or an optionally substituted phenyl group, and j is an integer of 1 or more and 4 or less.

When R^{a7} is an alkyl group having 1 or more and 12 or less carbon atoms, specific examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, an n-undecyl group, and an n-dodecyl group.

When R^{a7} is a halogen atom, specific examples of the halogen atom include a fluorine atom, a chlorine atom, a bromine atom, and an iodine atom.

When R^{a7} is an optionally substituted phenyl group, there is no particular limitation on the number of substituents on the phenyl group. The number of substituents on the phenyl group is 0 or more and 5 or less, and preferably 0 or 1. Examples of the substituent include an alkyl group having 1 or more and 4 or less carbon atoms, an alkoxy group having 1 or more and 4 or less carbon atoms, an aliphatic acyl group having 2 or more and 4 or less carbon atoms, a halogen atom, a cyano group, and a nitro group.

The epoxy compound (a-3a) having a biphenyl skeleton represented by the formula (a-3a-1) is not particularly limited and includes, for example, an epoxy compound represented by the following formula (a-3a-2).

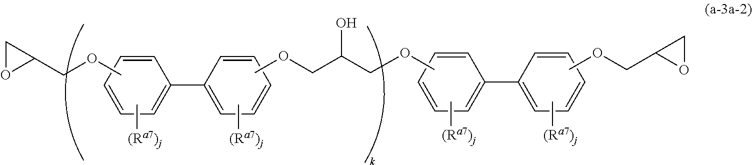

In the formula (a-3a-2), R^{a7} and j are the same as those in the formula (a-3a-1), and k is an average repetition number of a constituent unit in parentheses and is 0 or more and 10 or less.

Among the epoxy compounds represented by the formula (a-3a-2), a compound represented by the following formula (a-3a-3) is preferable since it is particularly easy to obtain a photosensitive resin composition excellent in balance between the sensitivity and the developability.

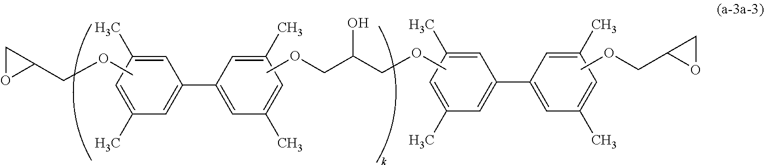

In the formula (a-3a-3), k is the same as that in the formula (a-3a-2).
(Unsaturated Group-Containing Carboxylic Acid (a-3b))

In preparation of a modified epoxy compound (a-3), an epoxy compound (a-3a) is reacted with an unsaturated group-containing carboxylic acid (a-3b). The unsaturated group-containing carboxylic acid (a-3b) is preferably monocarboxylic acid having a reactive unsaturated double bond such as an acryl group or a methacryl group in a molecule. Examples of such unsaturated group-containing carboxylic acid include acrylic acid, methacrylic acid, β-styrylacrylic acid, β-furfurylacrylic acid, α-cyanocinnamic acid, cinnamic acid, and the like. The unsaturated group-containing carboxylic acid (a-3b) may be used alone or may be used in combination of two or more types thereof.

It is possible to react an epoxy compound (a-3a) with an unsaturated group-containing carboxylic acid (a-3b) by a known method. Preferred reaction methods include, for example, a method in which an epoxy compound (a-3a) is reacted with an unsaturated group-containing carboxylic acid (a-3b) in an organic solvent at a reaction temperature of 50° C. or higher and 150° C. or lower for several hours to several tens of hours using, as a catalyst, tertiary amines such as triethylamine and benzylethylamine, quaternary ammonium salts such as dodecyltriethylammonium chloride, tetramethylammonium chloride, tetraethylammonium chloride, and benzyltriethylammonium chloride, pyridine, or triphenylphosphine.

Usually, a ratio of the amounts of the two in the reaction of the epoxy compound (a-3a) with the unsaturated group-containing carboxylic acid (a-3b) is preferably 1:0.5 to 1:2, more preferably 1:0.8 to 1:1.25, and particularly preferably 1:0.9 to 1:1.1 in terms of a ratio of an epoxy equivalent of an epoxy compound (a-3a) and a carboxylic acid equivalent of an unsaturated group-containing carboxylic acid (a-3b). When a ratio of the amount of the epoxy compound (a-3a) used to the amount of the unsaturated group-containing carboxylic acid (a-3b) used is 1:0.5 to 1:2 in terms of the equivalent ratio, crosslinking efficiency tends to be improved, which is preferable.

(Polybasic Anhydride (a-3c))

The polybasic anhydride (a-3c) is an anhydride of carboxylic acid having two or more carboxyl groups. Regarding the polybasic anhydride (a-3c), the upper limit of the number of carboxyl groups constituting an anhydride of carboxylic acid is not particularly limited and is, for example, 4 or less. Examples of the polybasic anhydride (a-3c) include, but are not limited to, maleic anhydride, succinic anhydride, itaconic anhydride, phthalic anhydride, tetrahydrophthalic anhydride, hexahydrophthalic anhydride, methylhexahydrophthalic anhydride, methyltetrahydrophthalic anhydride, trimellitic anhydride, pyromellitic anhydride, benzophenonetetracarboxylic dianhydride, 3-methylhexahydrophthalic anhydride, 4-methylhexahydrophthalic anhydride, 3-ethylhexahydrophthalic anhydride, 4-ethylhexahydrophthalic anhydride, tetrahydrophthalic anhydride, 3-methyltetrahydrophthalic anhydride, 4-methyltetrahydrophthalic anhydride, 3-ethyltetrahydrophthalic anhydride, 4-ethyltetrahydrophthalic anhydride, a compound represented by the following formula (a-3c-1), and a compound represented by the following formula (a-3c-2). These polybasic anhydrides (a-3c) may be used alone or may be used in combination of two or more types thereof.

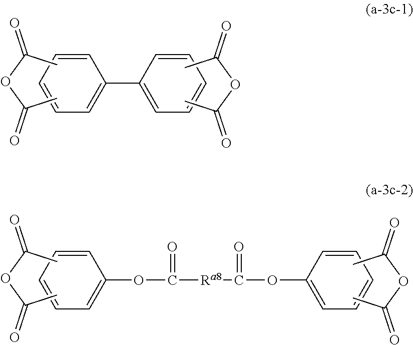

(In the formula (a-3c-2), R^{a8} represents an optionally substituted alkylene group having 1 or more and 10 or less carbon atoms.)

The polybasic anhydride (a-3c) is preferably a compound having two or more benzene rings since it is easy to obtain a photosensitive resin composition excellent in balance between the sensitivity and the developability. It is more preferred that the polybasic anhydride (a-3c) contains at least one of the compound represented by the formula (a-3c-1) and the compound represented by the formula (a-3c-2).

It is possible to appropriately select the method in which the epoxy compound (a-3a) is reacted with the unsaturated group-containing carboxylic acid (a-3b), followed by a reaction with the polybasic anhydride (a-3c) from known methods. A ratio of the amounts of these compounds used is usually 1:1 to 1:0.1, and preferably 1:0.8 to 1:0.2, in terms of an equivalent ratio of a molar number of OH groups in the components after reacting the epoxy compound (a-3a) with the unsaturated group-containing carboxylic acid (a-3b) to an equivalent ratio of an acid anhydride group of the polybasic anhydride (a-3c). When the ratio is within the above range, it is easy to obtain photosensitive resin composition with satisfactory developability.

An acid value of the modified epoxy resin (a-3) is preferably 10 mgKOH/g or more and 150 mgKOH/g or less, and more preferably 70 mgKOH/g or more and 110 mgKOH/g or less, in terms of a resin solid component. When the acid value of the resin is set at 10 mgKOH/g or more, sufficient solubility in a developing solution is obtained. When the acid value of the resin is set at 150 mgKOH/g or less, sufficient curability can be obtained, thus obtaining satisfactory surface properties.

A weight average molecular weight of the modified epoxy resin (a-3) is preferably 1,000 or more and 40,000 or less, and more preferably 2,000 or more and 30,000 or less. When the weight average molecular weight is 1,000 or more, it is easy to form a cured film excellent in heat resistance and strength. When the weight average molecular weight is 40,000 or less, it is easy to obtain a photosensitive resin composition which exhibits sufficient solubility in the developing solution.

[Acrylic Resin (a-4)]

As an alkali-soluble resin used as (A) a binder resin, an acrylic resin (a-4) is also preferred. As the acrylic resin (a-4), a resin containing a constituent unit derived from a (meth)acrylic acid and/or a constituent unit derived from other monomers such as a (meth)acrylic acid ester can be used. The (meth)acrylic acid is an acrylic acid or a methacrylic acid. The (meth)acrylic acid ester is represented by the following formula (a-4-1), and is not particularly limited as long as the object of the present invention is not inhibited.

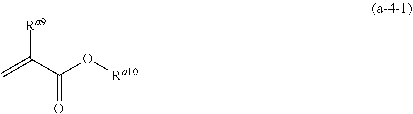

In the formula (a-4-1), R^{a9} represents a hydrogen atom or a methyl group, and R^{a10} is a monovalent organic group. This organic group may have a bond or a substituent, other than a hydrocarbon group such as a heteroatom, in the organic group. This organic group may be a straight-chain group, a branched-chain, or a cyclic group.

A substituent in an organic group as R^{a10} is not particularly limited, and examples of the substituent include a halogen atom, a hydroxy group, a mercapto group, a sulfide group, a cyano group, an isocyano group, a cyanato group, an isocyanato group, a thiocyanato group, an isothiocyanato group, a silyl group, a silanol group, an alkoxy group, an alkoxycarbonyl group, a carbamoyl group, a thiocarbamoyl group, a nitro group, a nitroso group, a carboxy group, a carboxylate group, an acyl group, an acyloxy group, a sulfino group, a sulfo group, a sulfonato group, a phosphino group, a phosphinyl group, a phosphono group, a phosphonato group, a hydroxyimino group, an alkylether group, an alkylthioether group, an arylether group, an arylthioether group, an amino group (—NH₂, —NHR, and —NRR′: wherein R and R′ each independently represent a hydrocarbon group), and the like. A hydrogen atom included in the above-mentioned substituent may be substituted with a hydrocarbon group. Furthermore, the hydrocarbon group included in the above-mentioned substituent may be a straight-chain group, a branched-chain group, or a cyclic group.

The organic group as R^{a10} may have reactive functional groups such as an acryloyloxy group, a methacryloyloxy group, an epoxy group, and an oxetanyl group. Acyl groups having an unsaturated double bond, such as an acryloyloxy group and a methacryloyloxy group can be produced, for example, by reacting at least one part of epoxy groups in an acrylic resin (a-4) including a constituent unit having epoxy groups with an unsaturated carboxylic acid such as acrylic acid or methacrylic acid.

R^{a10} is preferably an alkyl group, an aryl group, an aralkyl group, or a heterocyclic group. These groups may be substituted with a halogen atom, a hydroxy group, an alkyl group, or a heterocyclic group. When these groups include an alkylene moiety, the alkylene moiety is interrupted by an ether bond, thioether bond, or ester bond.

When the alkyl group is a straight-chain or branched-chain group, the number of carbon atoms thereof is preferably 1 or more and 20 or less, more preferably 1 or more and 15 or less, and particularly preferably 1 or more and 10 or less. Suitable examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like.

When the alkyl group is an alicyclic group or a group including an alicyclic group, examples of the alicyclic group included in the alkyl group include a monocyclic alicyclic group such as cyclopentyl group and cyclohexyl group, and a polycyclic alicyclic group such as adamantyl group, norbornyl group, isobornyl group, tricyclononyl group, and tetracyclododecyl group.

When a compound represented by the formula (a-4-1) has a chain group having an epoxy group as R^{a10}, specific examples of the compound represented by the formula (a-4-1) include (meth)acrylic acid epoxyalkyl esters such as glycidyl (meth)acrylate, 2-methyl glycidyl (meth)acrylate, 3,4-epoxybutyl (meth)acrylate, and 6,7-epoxyheptyl (meth)acrylate.

The compound represented by the formula (a-4-1) may be an alicyclic epoxy group-containing (meth)acrylic acid ester. An alicyclic group constituting the alicyclic epoxy group may be either monocyclic or polycyclic. Examples of the monocyclic alicyclic group include a cyclopentyl group, a cyclohexyl group, and the like. Examples of the polycyclic alicyclic group include a norbornyl group, an isobornyl group, a tricyclononyl group, a tricyclodecyl group, a tetracyclododecyl group, and the like.

When the compound represented by the formula (a-4-1) is an alicyclic epoxy group-containing (meth)acrylic acid ester, specific examples thereof include compounds represented by the following formulas (a-4-1a) to (a-4-1o). Among these compounds, compounds represented by the following formulas (a-4-1a) to (a-4-1e) are preferable, and compounds represented by the following formulas (a-4-1a) to (a-4-1c) are more preferable, so as to obtain appropriate developability.

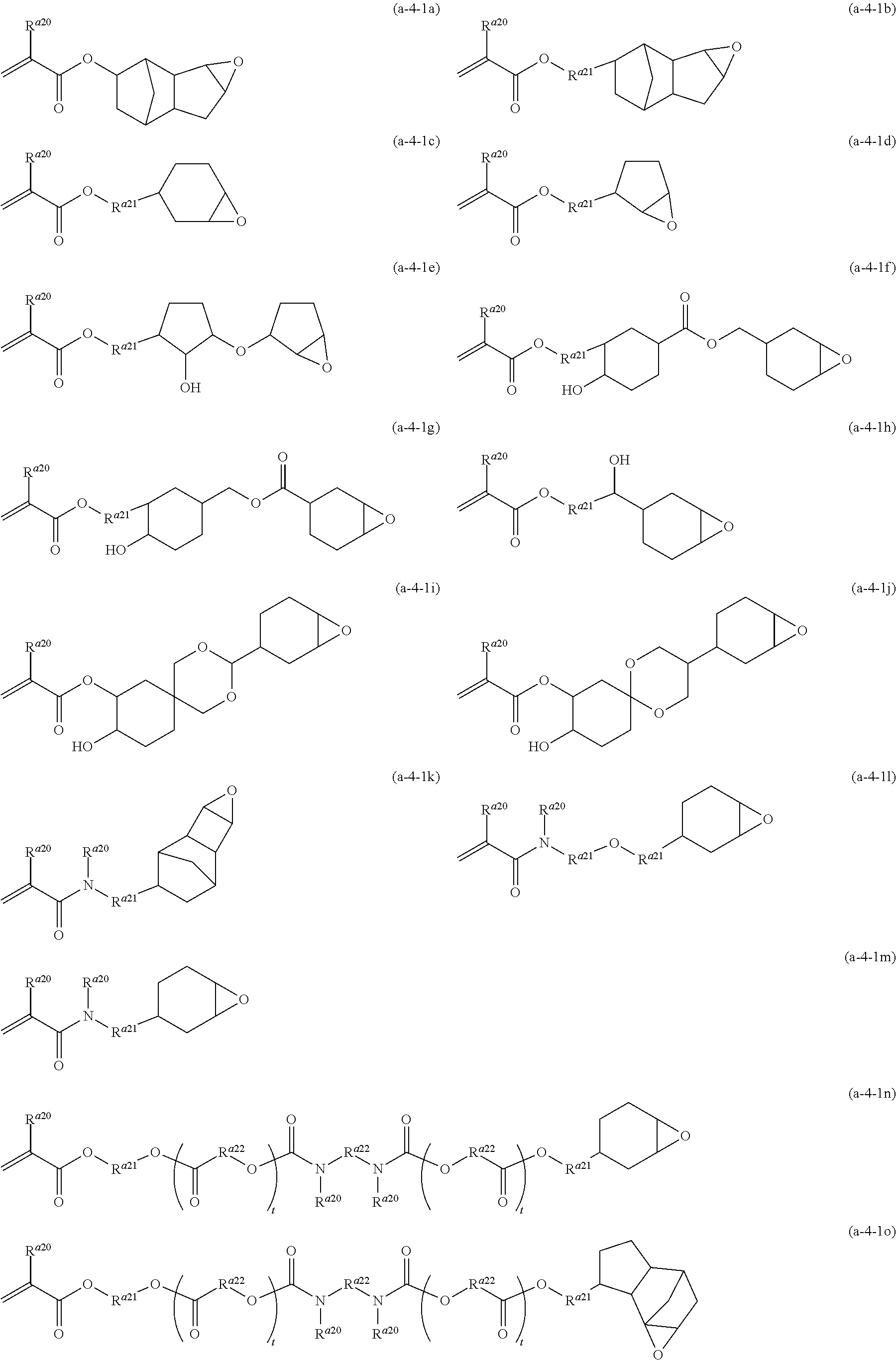

In the above formulas, R^{a20} represents a hydrogen atom or a methyl group, R^{a21} represents a divalent aliphatic saturated hydrocarbon group having 1 or more and 6 or less carbon atoms, R^{a22} represents a divalent hydrocarbon group having 1 or more and 10 or less carbon atoms, and t represents an integer of 0 or more and 10 or less. R^{a21} is preferably, a straight-chain or branched-chain alkylene group, for example, a methylene group, an ethylene group, a propylene group, a tetramethylene group, an ethylethylene group, a pentamethylene group, or a hexamethylene group. R^{a22} is preferably, for example, a methylene group, an ethylene group, a propylene group, a tetramethylene group, an ethylethylene group, a pentamethylene group, a hexamethylene group, a phenylene group, a cyclohexylene group, or —CH₂-Ph-CH₂— (Ph represents a phenylene group).

Furthermore, the acrylic resin (a-4) may be that in which a monomer other than (meth)acrylic acid is polymerized. Examples of such monomer include (meth)acrylamides, unsaturated carboxylic acids, allyl compounds, vinyl ethers, vinyl esters, styrenes, and the like. These monomers can be used alone or in combination of two or more types thereof.

Examples of (meth)acrylamides include (meth)acrylamide, N-alkyl(meth)acrylamide, N-aryl(meth)acrylamide, N,N-dialkyl(meth)acrylamide, N,N-diaryl(meth)acrylamide, N-methyl-N-phenyl(meth)acrylamide, N-hydroxyethyl-N-methyl(meth)acrylamide, and the like.

Examples of unsaturated carboxylic acids include mono carboxylic acids such as crotonic acid; dicarboxylic acids such as maleic acid, fumaric acid, citraconic acid, mesaconic acid, and itaconic acid; anhydrides of these dicarboxylic acids and the like.

Examples of the allyl compounds include allyl esters such as allyl acetate, allyl caproate, allyl caprylate, allyl laurate, allyl palmitate, allyl stearate, allyl benzoate, allyl acetoacetate, and allyl lactate; allyloxyethanol; and the like.

Examples of vinyl ethers include alkyl vinyl ethers such as hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, and tetrahydrofurfuryl vinyl ether; vinylaryl ethers such as vinyl phenyl ether, vinyl tolyl ether, vinyl chlorophenyl ether, vinyl-2,4-dichlorophenyl ether, vinyl naphthyl ether, and vinyl anthranyl ether; and the like.

Examples of vinyl esters include vinyl butyrate, vinyl isobutyrate, vinyl trimethyl acetate, vinyl diethyl acetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenyl butyrate, vinyl benzoate, vinyl salicylate, vinyl chlorobenzoate, vinyl tetrachlorobenzoate, vinyl naphthoate, and the like.

Examples of styrenes include styrene; alkylstyrenes such as methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, and acetoxymethylstyrene; alkoxystyrenes such as methoxystyrene, 4-methoxy-3-methylstyrene, and dimethoxystyrene; halostyrenes such as chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene; and the like.

In the acrylic resin (a-4), the content of the constituent unit derived from (meth)acrylic acid and the content of the constituent unit derived from other monomers are not limited as long as the object of the present invention is not inhibited. In the acrylic resin (a-4), the content of the constituent unit derived from (meth)acrylic acid is preferably 5% by mass or more and 50% by mass or less, and more preferably 10% by mass or more and 30% by mass or less with respect to the mass of the acrylic resin (a-4).

When the acrylic resin (a-4) includes a constituent unit having an unsaturated double bond, the amount of the constituent unit having an unsaturated double bond in the acrylic resin (a-4) is preferably 1% by mass or more and 50% by mass or less, more preferably 1% by mass or more and 30% by mass or less, and particularly preferably 1% by mass or more and 20% by mass or less. When the acrylic resin (a-4) includes a constituent unit having an unsaturated double bond within the above range, it is possible to homogenize by incorporating an acrylic resin into a crosslinking reaction in a resist film, so that it is effective to improve the heat resistance and mechanical properties of the cured film.

The weight average molecular weight of the acrylic resin (a-4) is preferably 2,000 or more and 50,000 or less, and more preferably 3,000 or more and 30,000 or less. When the content is in the above-mentioned range, a balance of film-forming properties of the photosensitive resin composition and developing properties after exposure tends to be easily achieved.

The content of the (A) binder resin is preferably 3% by mass or more and 55% by mass or less, and more preferably 5% by mass or more and 45% by mass or less, based on the mass of the entire solid component of the photosensitive resin composition. Particularly, when the (A) binder resin is an alkali-soluble resin, it is easy to obtain a photosensitive resin composition excellent in developability by adjusting the content within the above range.

Those in which the (A) binder resin contains, as the alkali-soluble resin, a cardo resin (a-1) and an acrylic resin (a-4) in combination are also preferred. For example, when a black column spacer is formed using the photosensitive resin composition, it is necessary to change the height of the black column spacer at every position by taking the height of an element such as TFT formed on a substrate into consideration. In such a case, the height of the black column spacer is adjusted by exposing using a half-tone mask. When using a photosensitive resin composition containing the (A) binder resin which contains a cardo resin (a-1) and an acrylic resin (a-4) in combination, if the height of the black column spacer using a full-tone mask is taken as H1, it is possible to form a black column spacer having the height closer to H1 by increasing an opening width in the half-tone mask than an opening width of the full-tone mask and, when using a half-tone mask including an opening having the same opening width as that of the full-tone mask, it is possible to form a black column spacer having the height lower than H1. In other words, it is easy to control the height of the black column spacer by adjusting the opening width of the opening in the half-tone mask. Namely, when using a photosensitive resin composition containing the (A) binder resin which contains a cardo resin (a-1) and an acrylic resin (a-4) in combination, it is possible to form a black column spacer having the same shape even when using either a half-tone mask or a full-tone mask.

When the (A) binder resin contains, as the alkali-soluble resin, a cardo resin (a-1) and an acrylic resin (a-4), the content of the cardo resin (a-1) in the (A) binder resin is preferably 99% by mass or less and 30% by mass or more, more preferably 99% by mass or less and 50% by mass or more, and particularly preferably 99% by mass or less and 70% by mass or more. When the (A) binder resin contains, as the alkali-soluble resin, a cardo resin (a-1) and an acrylic resin (a-4), the content of the acrylic resin (a-4) in the (A) binder resin is preferably 1% by mass or more and 70% by mass or less, more preferably 1% by mass or more and 50% by mass or less, and particularly preferably 1% by mass or more and 30% by mass or less.

### <(B) Photopolymerizable Compound>

The photosensitive resin composition contains (B) a photopolymerizable compound. The (B) photopolymerizable compound is preferably a compound having an ethylenically unsaturated group. Such photopolymerizable compound includes a monofunctional compound and a polyfunctional compound.

Examples of the monofunctional compound include (meth)acrylamide, methylol(meth)acrylamide, methoxymethyl(meth)acrylamide, ethoxymethyl(meth)acrylamide, propoxymethyl(meth)acrylamide, butoxyethoxymethyl(meth)acrylamide, N-methylol(meth)acrylamide, N-hydroxymethyl(meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamidesulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerin mono(meth)acrylate, tetrahydrofurfuryl (meth)acrylate, dimethylaminoethyl (meth)acrylate, glycidyl (meth)acrylate, 2,2,2-trifluoroethyl (meth)acrylate, 2,2,3,3-tetrafluoropropyl (meth)acrylate, a half (meth)acrylate of a phthalic acid derivative, and the like. These monofunctional compounds may be used alone or in combination of two or more types thereof.

Examples of the polyfunctional compound include ethylene glycol di(meth)acrylate, diethylene glycol di(meth)acrylate, triethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerin di(meth)acrylate, pentaerythritol triacrylate, pentaerythritol tetraacrylate, dipentaerythritol pentaacrylate, dipentaerythritol hexaacrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, ethylene glycol diglycidyl ether di(meth)acrylate, diethylene glycol diglycidyl ether di(meth)acrylate, phthalic acid diglycidyl ester di(meth)acrylate, glycerin triacrylate, glycerin polyglycidyl ether poly(meth)acrylate, urethane (meth)acrylate (i.e., a reaction product of tolylene diisocyanate, trimethylhexamethylene diisocyanate, hexamethylene diisocyanate, 2-hydroxyethyl (meth)acrylate, and the like), methylenebis(meth)acrylamide, (meth)acrylamide methylene ether, a polyfunctional compound such as a fused product of polyvalent alcohol and N-methylol(meth)acrylamide, triacryl formal, and the like. These polyfunctional compounds may be used alone or in combination of two or more types thereof.

Among these photopolymerizable compounds having an ethylenically unsaturated group, a trifunctional or higher polyfunctional compound is preferred, a teterafunctional or higher polyfunctional monomer is more preferred, and a pentafunctional or higher polyfunctional compound is still more preferred, in view of the fact that they tend to enhance the adhesion of the photosensitive resin composition to the substrate and the strength of the photosensitive resin composition after curing. The upper limit of the number of functional groups of the polyfunctional compound to be used as the photopolymerizable compound having an ethylenically unsaturated group is not particularly limited and is, for example, 6 or less. Specifically, a pentafunctional or higher polyfunctional compound is preferably used, and dipentaerythritol penta(meth)acrylate and/or dipentaerythritol hexa(meth)acrylate is/are more preferably used.

The content of the (B) photopolymerizable compound in the photosensitive resin composition is preferably 1% by mass or more and 50% by mass or less, and more preferably 3% by mass or more and 35% by mass or less, based on the mass of the total solid component of the photosensitive resin composition. By adjusting the content in the above range, it is easy to keep a balance among sensitivity, developability, and resolution.

### <(C) Photopolymerization Initiator>

The (C) photopolymerization initiator is not particularly limited, and it is possible to use a conventionally known photopolymerization initiator.

Specific examples of the (C) photopolymerization initiator include 1-hydroxycyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl)ketone, 2-methyl-1-[4-(methylthio)phenyl]-2-morpholinopropan-1-one, 2-benzyl-2-dimethylamino-1-(4-morpholinophenyl)-butan-1-one, 0-acetyl-1-[6-(2-methylbenzoyl)-9-ethyl-9H-carbazol-3-yl]ethanone oxime, 0-acetyl-1-[6-(pyrrol-2-ylcarbonyl)-9-ethyl-9Hcarbazol-3-yl]ethanone oxime, (9-ethyl-6-nitro-9H-carbazol-3-yl)[4-(2-methoxy-1-methylethoxy)-2-methylphenyl]methanone 0-acetyl oxime, 2-(benzoyloxyimino)-1-[4-(phenylthio)phenyl]-1-octanone, 2,4,6-trimethylbenzoyl diphenylphosphine oxide, 4-benzoyl-4′-methyldimethyl sulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-β-methoxyethylacetal, benzyldimethylketal, 1-phenyl-1,2-propanedione-2-(0-ethoxycarbonyl)oxime, methyl o-benzoylbenzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethylanthraquinone, 1,2-benzanthraquinone, 2,3-diphenylanthraquinone, azobisisobutyronitrile, benzoyl peroxide, cumene hydroperoxide, 2-mercaptobenzimidazole, 2-mercaptobenzoxazole, 2-mercaptobenzothiazole, 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, benzyl, benzoin, benzoin methyl ether, benzoin ethyl ether, benzoin isopropyl ether, benzoin n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, dibenzosuberone, pentyl-4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(furan-2-yl)ethenyl]-4,6-bis(trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine, and the like.

These photopolymerization initiators can be used alone or in combination of two or more types thereof. It is preferred that the (C) photopolymerization initiator contains two or more photopolymerization initiators in combination. In this case, it is easy to effectively utilize light having a wavelength in a wide range included in exposure light and it is easy to adjust the sensitivity of the photosensitive resin composition within an appropriate range.

Among these compounds, an oxime ester compound is used as the (C) photopolymerization initiator, particularly preferably, in view of the sensitivity. Examples of the compound which is preferable as the oxime ester compound include O-acetyl-1-[6-(2-methylbenzoyl)-9-ethyl-9H-carbazol-3-yl]ethanone oxime, 0-acetyl-1-[6-(pyrrol-2-ylcarbonyl)-9-ethyl-9Hcarbazol-3-yl]ethanone oxime, and 2-(benzoyloxyimino)-1-[4-(phenylthio)phenyl]-1-octanone.

When using oxime ester compound as the (C) photopolymerization initiator, as mentioned above, it is also preferred to use the oxime ester compound in combination with photopolymerization initiators other than the oxime ester compound. When using the oxime ester compound in combination with other photopolymerization initiators, it is easy to adjust the sensitivity of the photosensitive resin composition within an appropriate range. Therefore, since excessive curing due to exposure scarcely proceeds, a patterned cured film having a width wider than a desired width is scarcely formed. Other photopolymerization initiators to be used in combination with the oxime ester compound are preferably α-aminoalkylphenone-based photopolymerization initiators. Suitable examples of the a-aminoalkylphenone-based photopolymerization initiator include 2-methyl-1-[4-(methylthio)phenyl]-2-morpholinopropan-1-one (Irgacure 907 (IR-907), product name, manufactured by BASF Corporation), and 2-benzyl-2-dimethylamino-1-(4-morpholinophenyl)-butan-1-one (Irgacure 369E (IR-369E), product name, manufactured by BASF Corporation). Since the photosensitive resin composition to be used to form a cured film contains a light shielding (D) coloring agent, energy required to sufficiently exhibit photo-properties is limited during exposure. However, when the photosensitive resin composition contains an oxime ester compound and an α-aminoalkylphenone-based photopolymerization initiator as the (C) photopolymerization initiator, it is ease for the photosensitive resin composition to exhibit sufficient photosensitivity.

It is also preferred to use, as the oxime ester compound, an oxime ester compound represented by the following formula (c1):

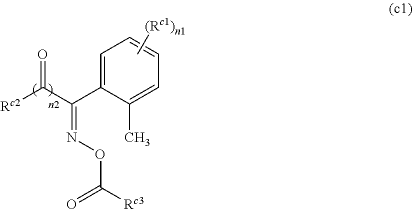

wherein R^{c1} is a group selected from the group consisting of a monovalent organic group, an amino group, halogen, a nitro group, and a cyano group,
n1 is an integer of 0 or more and 4 or less,
n2 is 0 or 1,
R^{c2} is an optionally substituted phenyl group or an optionally substituted carbazolyl group, and
R^{c3} is a hydrogen atom, or an alkyl group having 1 or more and 6 or less carbon atoms.

In the formula (c1), R^{c1} is not particularly limited as long as the object of the present invention is not inhibited, and is appropriately selected from various organic groups. When R^{c1} is an organic group, suitable examples include an alkyl group, an alkoxy group, an cycloalkyl group, an cycloalkoxy group, a saturated aliphatic acyl group, a saturated aliphatic acyloxy group, an alkoxycarbonyl group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an amino group, an amino group substituted with one or two organic groups, a morpholin-1-yl group, a piperazin-1-yl group, a halogen, a nitro group, a cyano group, and the like. When n1 is an integer of 2 or more and 4 or less, R^{c1} may be the same or different. The number of carbon atoms of the substituent does not include the number of carbon atoms of the substituent possessed by the substituent.

When R^{c1} is an alkyl group, the number of carbon atoms of the alkyl group is preferably 1 or more and 20 or less, and more preferably 1 or more and 6 or less. When R^{c1} is an alkyl group, the alkyl group may be either one of a straight-chain or branched-chain alkyl group. When R^{c1} is an alkyl group, specific examples include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. When R^{c1} is an alkyl group, the alkyl group may contain an ether bond (—O—) in the carbon chain. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, a methoxypropyl group, and the like.

When R^{c1} is an alkoxy group, the number of carbon atoms of the alkoxy group is preferably 1 or more and 20 or less, and more preferably 1 or more and 6 or less. When R^{c1} is an alkoxy group, the alkoxy group may be either one of a straight-chain or branched-chain alkoxy group. When R^{c1} is an alkoxy group, specific examples include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, an isodecyloxy group, and the like. When R^{c1} is an alkoxy group, the alkoxy group may include an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, a methoxypropyloxy group, and the like.

When R^{c1} is a cycloalkyl group or a cycloalkoxy group, the number of carbon atoms of the cycloalkyl group or cycloalkoxy group is preferably 3 or more and 10 or less, and more preferably 3 or more and 6 or less. When R^{c1} is a cycloalkyl group, specific examples include a cyclopropyl group, a cyclobutyl group, a cyclopentyl group, a cyclohexyl group, a cycloheptyl group, a cyclooctyl group, and the like. When R^{c1} is a cycloalkoxy group, specific examples include a cyclopropyloxy group, a cyclobutyloxy group, a cyclopentyloxy group, a cyclohexyloxy group, a cycloheptyloxy group, a cyclooctyloxy group, and the like.

When R^{c1} is a saturated aliphatic acyl group or a saturated aliphatic acyloxy group, the number of carbon atoms of the saturated aliphatic acyl group or saturated aliphatic acyloxy group is preferably 2 or more and 20 or less, and more preferably 2 or more and 7 or less. When R^{c1} is a saturated aliphatic acyl group, specific examples include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, n-hexadecanoyl group, and the like. When R^{c1} is a saturated aliphatic acyloxy group, specific examples include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, an n-hexadecanoyloxy group, and the like.

When R^{c1} is an alkoxycarbonyl group, the number of carbon atoms of the alkoxycarbonyl group is preferably 2 or more and 20 or less, and more preferably 2 or more and 7 or less. When R^{c1} is an alkoxycarbonyl group, specific examples include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, an isodecyloxycarbonyl group, and the like.

When R^{c1} is a phenylalkyl group, the number of carbon atoms of the phenylalkyl group is preferably 7 or more and 20 or less, and more preferably 7 or more and 10 or less. When R^{c1} is a naphthylalkyl group, the number of carbon atoms of the naphthylalkyl group is preferably 11 or more and 20 or less, and more preferably 11 or more and 14 or less. When R^{c1} is a phenylalkyl group, specific examples include a benzyl group, a 2-phenylethyl group, a 3-phenylpropyl group, and a 4-phenylbutyl group. When R^{c1} is a naphthylalkyl group, specific examples include an α-naphthylmethyl group, a β-naphthylmethyl group, a 2-(α-naphthyl)ethyl group, and a 2-(β-naphthyl)ethyl group. When R^{c1} is a phenylalkyl group or naphthylalkyl group, R^{c1} may further have a substituent on a phenyl group or a naphthyl group.

When R^{c1} is a heterocyclyl group, the heterocyclyl group is a 5- or 6-membered single ring containing one or more N, S, and O, or a heterocyclyl group in which single rings are fused each other, or a single ring is fused with a benzene ring. When the heterocyclyl group is a fused ring, the number of rings in the fused ring is 3 or less. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzoimidazole, benzotriazole, benzoxazole, benzothiazole, carbazole, purine, quinoline, isoquinoline, quinazoline, phthalazine, cinnoline, quinoxaline, and the like. When R^{c1} is a heterocyclyl group, the heterocyclyl group may have a substituent.

When R^{c1} is an amino group substituted with one or two organic groups, suitable examples of the organic group include an alkyl group having 1 or more and 20 or less carbon atoms, a cycloalkyl group having 3 or more and 10 or less carbon atoms, a saturated aliphatic acyl group having 2 or more and 20 or less carbon atoms, an optionally substituted phenyl group, an optionally substituted benzoyl group, an optionally substituted phenylalkyl group having 7 or more and 20 or less carbon atoms, an optionally substituted naphthyl group, an optionally substituted naphthoyl group, an optionally substituted naphthylalkyl group having 11 or more and 20 or less carbon atoms, a heterocyclyl group, and the like. Specific examples of suitable organic group are the same as those in R^{c1}. Specific examples of the amino group substituted with one or two organic group include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, an propanoylamino group, an n-butanoylamino group, an n-pentanoylamino group, an n-hexanoylamino group, an n-heptanoylamino group, an n-octanoylamino group, an n-decanoylamino group, a benzoylamino group, an α-naphthoylamino group, a β-naphthoylamino group, and the like.

When an phenyl group, an naphthyl group, and a heterocyclyl group included in R^{c1} further have a substituent, examples of the substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group which has an alkyl group having 1 or more and 6 or less carbon atoms, a dialkylamino group which has two alkyl groups having 1 or more and 6 or less carbon atoms, a morpholin-1-yl group, an piperazin-1-yl group, halogen, a nitro group, a cyano group, and the like. When a phenyl group, a naphthyl group, and a heterocyclyl group included in R^{c1} further have a substituent, the number of substituents is not particularly limited as long as the object of the present invention is not inhibited, and is preferably 1 or more and 4 or less. When a phenyl group, a naphthyl group, and a heterocyclyl group included in R^{c1} have plural substituents, plural substituents may be the same as or different each other.

Among R^{c1}(s), a group selected from the group consisting of an alkyl group having 1 or more and 6 or less carbon atoms, an alkoxy group having 1 or more and 6 or less carbon atoms, and a saturated aliphatic acyl group having 2 or more and 7 or less carbon atoms is preferred, an alkyl having 1 or more and 6 or less carbon atoms is more preferred, and a methyl group is particularly preferred, since these are chemically stable and facilitates the synthesis of an oxime ester compound due to little steric hindrance.

When the position of a bond of a phenyl group and a main skeleton of an oxime ester compound is regarded as the 1-position and the position of a methyl group is regarded as the 2-position with respect to the phenyl group to which R^{c1} is bonded, the position at which R^{c1} is bonded to a phenyl group is preferably the 4-position or the 5-position, and more preferably the 5-position. n1 is preferably an integer of 0 or more and 3 or less, more preferably an integer of 0 or more and 2 or less, and particularly preferably 0 or 1.

R^{c2} is an optionally substituted phenyl group, or an optionally substituted carbazolyl group. When R^{c2} is an optionally substituted carbazolyl group, the nitrogen atom on the carbazolyl group may be substituted with an alkyl group having 1 or more and 6 or less carbon atoms.

For R^{c2}, there is no particular limitation on substituents on the phenyl group or the carbazolyl group as long as they do not interfere with the object of the present invention. Examples of suitable substituents which the phenyl group or carbazolyl group may have on the carbon atom include an alkyl group having 1 or more and 20 or less carbon atoms, an alkoxy group having 1 or more and 20 or less carbon atoms, a cycloalkyl group having 3 or more and 10 or less carbon atoms, a cycloalkoxy group having 3 or more and 10 or less carbon atoms, a saturated aliphatic acyl group having 2 or more and 20 or less carbon atoms, an alkoxycarbonyl group having 2 or more and 20 or less carbon atoms, a saturated aliphatic acyloxy group having 2 or more and 20 or less carbon atoms, an optionally substituted phenyl group, an optionally substituted phenoxy group, an optionally substituted phenylthio group, an optionally substituted benzoyl group, an optionally substituted phenoxycarbonyl group, an optionally substituted benzoyloxy group, an optionally substituted phenylalkyl group having 7 or more and 20 or less carbon atoms, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group having 11 or more and 20 or less carbon atoms, an optionally substituted heterocyclyl group, an optionally substituted heterocyclylcarbonyl group, an amino group, an amino group substituted with 1 or 2 organic groups, a morpholin-1-yl group, a piperazin-1-yl group, halogen, a nitro group, a cyano group and the like.

In a case where R^{c2} is a carbazolyl group, examples of suitable substituent which the carbazolyl group may have on the nitrogen atom include an alkyl group having 1 or more and 20 or less carbon atoms, a cycloalkyl group having 3 or more and 10 or less carbon atoms, a saturated aliphatic acyl group having 2 or more and 20 or less carbon atoms, an alkoxycarbonyl group having 2 or more and 20 or less carbon atoms, an optionally substituted phenyl group, an optionally substituted benzoyl group, an optionally substituted phenoxycarbonyl group, an optionally substituted phenylalkyl group having 7 or more and 20 or less carbon atoms, an optionally substituted naphthyl group, an optionally substituted naphthoyl group, an optionally substituted naphthoxycarbonyl group, an optionally substituted naphthylalkyl group having 11 or more and 20 or less carbon atoms, an optionally substituted heterocyclyl group, an optionally substituted heterocyclylcarbonyl group and the like. Among these substituents, an alkyl group having 1 or more and 20 or less carbon atoms is preferred, and an alkyl group having 1 or more and 6 or less carbon atoms is more preferred, and in particular an ethyl group is preferred.

For an alkyl group, an alkoxy group, a cycloalkyl group, a cycloalkoxy group, a saturated aliphatic acyl group, an alkoxycarbonyl group, a saturated aliphatic acyloxy group, an optionally substituted phenylalkyl group, an optionally substituted naphthylalkyl group, an optionally substituted heterocyclyl group and an amino group substituted with 1 or 2 organic groups, specific examples of optional substituents on the phenyl group or the carbazolyl group are same as those in R^{c1}.

In a case where the phenyl group, the naphthyl group and the heterocyclyl group included in the substituent on the phenyl group or the carbazolyl group in R^{c2} further have a substituent, examples of the substituent include an alkyl group having 1 or more and 6 or less carbon atoms; an alkoxy group having 1 or more and 6 or less carbon atoms; a saturated aliphatic acyl group having 2 or more and 7 or less carbon atoms; an alkoxycarbonyl group having 2 or more and 7 or less carbon atoms; a saturated aliphatic acyloxy group having 2 or more and 7 or less carbon atoms; a phenyl group; a naphthyl group; a benzoyl group; a naphthoyl group; a benzoyl group substituted with a group selected from the group consisting of an alkyl group having 1 or more and 6 or less carbon atoms, a morpholin-1-yl group, a piperazin-1-yl group and a phenyl group; a monoalkylamino group having an alkyl group having 1 or more and 6 or less carbon atoms; a dialkylamino group having alkyl groups having 1 or more and 6 or less carbon atoms; a morpholin-1-yl group; a piperazin-1-yl group; halogen; a nitro group; and a cyano group. In a case where the phenyl group, the naphthyl group and the heterocyclyl group included in the substituent on the phenyl group or the carbazolyl group further have a substituent, the number of the substituent is not limited as far as objects of the present invention are not inhibited, but 1 or more and 4 or less is preferred. In a case where the phenyl group, the naphthyl group and the heterocyclyl group have multiple substituents, the substituents may be different from or the same as each other.

Among R^{c2}(s), a group represented by the following formula (c2) or (c3) is preferred, a group represented by the following formula (c2) is more preferred, and a group represented by the following formula (c2) in which A is S is particularly preferred, since a photopolymerization initiator with excellent sensitivity is easily obtained.

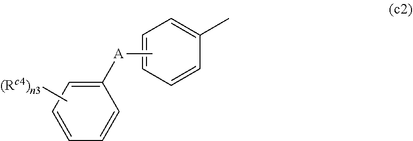

R^{c4} is a group selected from the group consisting of a monovalent organic group, an amino group, halogen, a nitro group and a cyano group; A is S or O; and n3 is an integer of 0 or more and 4 or less.

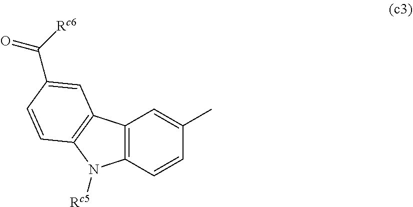

R^{c5} and R^{c6} each are a monovalent organic group.

When R^{c4} in formula (c2) is an organic group, R^{c4} can be selected from various kinds of organic groups as far as objects of the present invention are not inhibited. Preferred examples when R^{c4} is an organic group in formula (c2) include alkyl groups having 1 or more and 6 or less carbon atoms; alkoxy groups having 1 or more and 6 or less carbon atoms; saturated aliphatic acyl groups having 2 or more and 7 or less carbon atoms; alkoxycarbonyl groups having 2 or more and 7 or less carbon atoms; saturated aliphatic acyloxy groups having 2 or more and 7 or less carbon atoms; a phenyl group; a naphthyl group; a benzoyl group; a naphthoyl group; benzoyl groups substituted with a group selected from the group consisting of an alkyl group having 1 or more and 6 or less carbon atoms, a morpholine-1-yl group, a piperazine-1-yl group and a phenyl group; monoalkylamino groups having an alkyl group having 1 or more and 6 or less carbon atoms; dialkylamino groups having alkyl groups having 1 or more and 6 or less carbon atoms; a morpholine-1-yl group; a piperazine-1-yl group; halogen; a nitro group; and a cyano group.

Among R^{c4}, a benzoyl group; a naphthoyl group; a benzoyl groups substituted with a group selected from the group consisting of an alkyl group having 1 or more and 6 or less carbon atoms, a morpholin-1-yl group, a piperazin-1-yl group, and a phenyl group; and a nitro group are preferred, and a benzoyl group; a naphthoyl group; a 2-methylphenyl carbonyl group; a 4-(piperazin-1-yl)phenylcarbonyl group; and a 4-(phenyl)phenylcarbonyl group are more preferred.

In formula (c2), n3 is preferably an integer of 0 or more and 3 or less, more preferably an integer of 0 or more and 2 or less, and particularly preferably 0 or 1. When n3 is 1, the position at which R^{c4} bonds is preferably the para-position to the bonding through which the phenyl group (to which R^{c4} bonds) bonds to an oxygen atom or a sulfur atom.

R^{c5} in the formula (c3) can be selected from various organic groups as long as they do not interfere with the object of the present invention. Suitable examples of R^{c5} include an alkyl group having 1 or more and 20 or less carbon atoms, a cycloalkyl group having 3 or more and 10 or less carbon atoms, a saturated aliphatic acyl group having 2 or more and 20 or less carbon atoms, an alkoxycarbonyl group having 2 or more and 20 or less carbon atoms, an optionally substituted phenyl group, an optionally substituted benzoyl group, an optionally substituted phenoxycarbonyl group, an optionally substituted phenylalkyl group having 7 or more and 20 or less carbon atoms, an optionally substituted naphthyl group, an optionally substituted naphthoyl group, an optionally substituted naphthoxycarbonyl group, an optionally substituted naphthylalkyl group having 11 or more and 20 or less carbon atoms, an optionally substituted heterocyclyl group, an optionally substituted heterocyclylcarbonyl group, and the like.

Among R^{c5}, an alkyl group having 1 or more and 20 or less carbon atoms is preferred, an alkyl group having 1 or more and 6 or less carbon atoms is more preferred, and an ethyl group is particularly preferred.

There is no particular limitation for R^{c6} in the formula (c3) as long as it does not interfere with the object of the present invention, and it can be selected from various organic groups. Specific examples of the suitable group for R^{c6} include an alkyl group having 1 or more and 20 or less carbon atoms, an optionally substituted phenyl group, an optionally substituted naphthyl group and an optionally substituted heterocyclyl group. Among these groups, R^{c6} is more preferably an optionally substituted phenyl group, and in particular preferably a 2-methylphenyl group.

When a phenyl group, a naphthyl group, and a heterocyclyl group included in R^{c4}, R^{c5}, or R^{c6} further has a substituent, examples of the substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group having an alkyl group which has 1 or more and 6 or less carbon atoms, a dialkylamino group having an alkyl group which has 1 or more and 6 or less carbon atoms, a morpholin-1-yl group, a piperazin-1-yl group, halogen, a nitro group, and a cyano group. When the phenyl group, naphthyl group, and heterocyclyl group included in R^{c4}, R^{c5}, or R^{c6} further has a substituent, the number of substituents is not particularly limited as long as it does not interfere with the object of the present invention, but is preferably 1 or more and 4 or less. When the phenyl group, naphthyl group, and heterocyclyl group included in R^{c4}, R^{c5}, or R^{c6} further has plural substituents, plural substituents may be the same or different.

R^{c3} in the formula (c1) is a hydrogen atom, or an alkyl group having 1 or more and 6 or less carbon atoms. R^{c3} is preferably a methyl group or an ethyl group, and more preferably a methyl group.

Among the oxime ester compounds represented by the formula (c1), the particularly suitable compounds include the following PI-1 to PI-42.

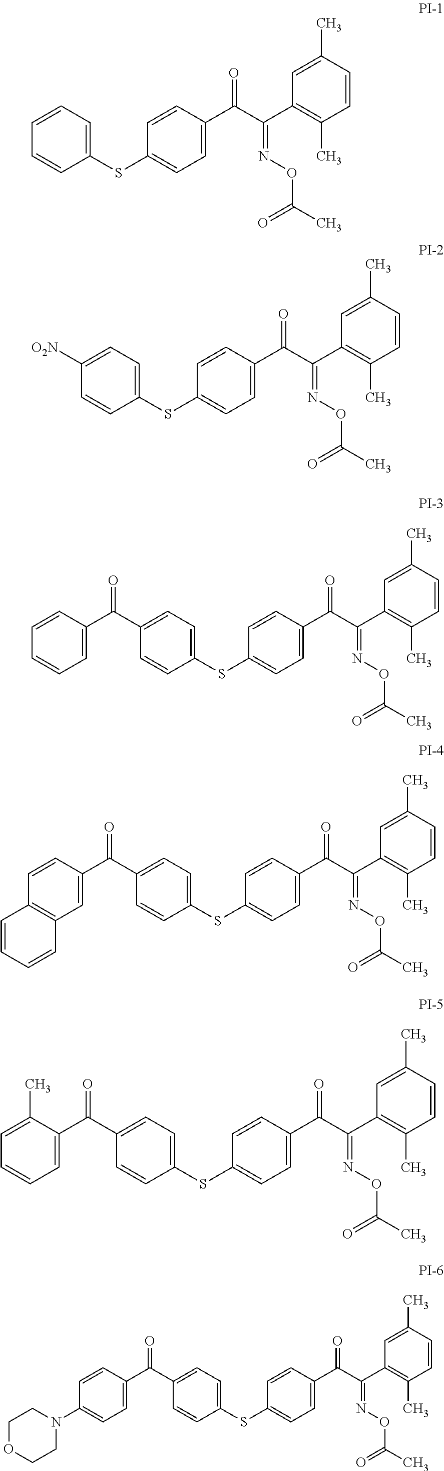 [SMILES: CC(=O)O/N=C(/C(=O)c1ccc(Sc2ccccc2)cc1)c1cc(C)ccc1C ; CC(=O)O/N=C(/C(=O)c1ccc(Sc2ccc([N+](=O)[O-])cc2)cc1)c1cc(C)ccc1C ; CC(=O)O/N=C(/C(=O)c1ccc(Sc2ccc(C(=O)c3ccccc3)cc2)cc1)c1cc(C)ccc1C ; CC(=O)O/N=C(/C(=O)c1ccc(Sc2ccc(C(=O)c3ccc4ccccc4c3)cc2)cc1)c1cc(C)ccc1C ; CC(=O)O/N=C(/C(=O)c1ccc(Sc2ccc(C(=O)c3ccccc3C)cc2)cc1)c1cc(C)ccc1C ; CC(=O)O/N=C(/C(=O)c1ccc(Sc2ccc(C(=O)c3ccc(N4CCOCC4)cc3)cc2)cc1)c1cc(C)ccc1C]

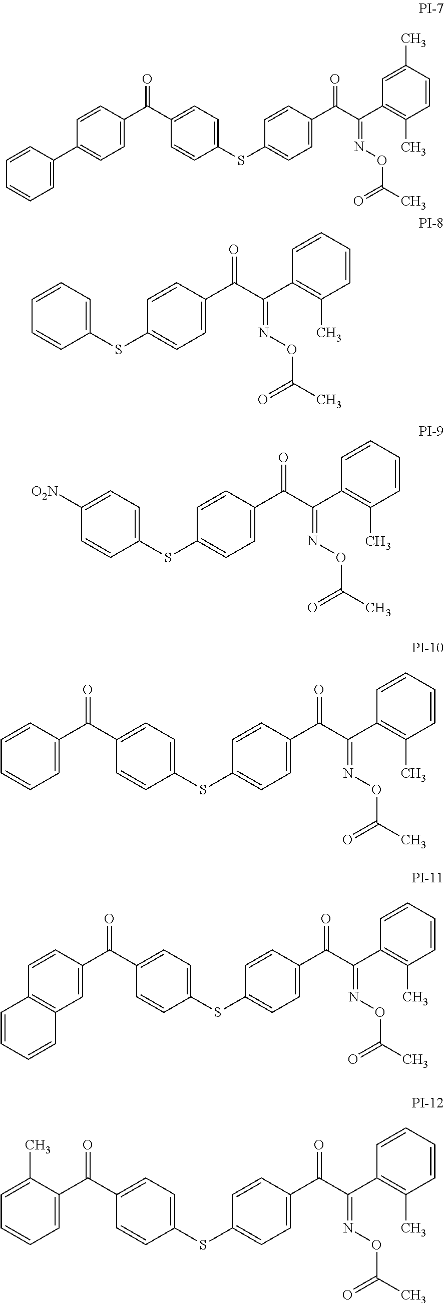 [SMILES: CC(=O)O/N=C(/C(=O)c1ccc(Sc2ccc(C(=O)c3ccc(-c4ccccc4)cc3)cc2)cc1)c1cc(C)ccc1C ; CC(=O)O/N=C(/C(=O)c1ccc(Sc2ccccc2)cc1)c1ccccc1C ; CC(=O)O/N=C(/C(=O)c1ccc(Sc2ccc([N+](=O)[O-])cc2)cc1)c1ccccc1C ; CC(=O)O/N=C(/C(=O)c1ccc(Sc2ccc(C(=O)c3ccccc3)cc2)cc1)c1ccccc1C ; CC(=O)O/N=C(/C(=O)c1ccc(Sc2ccc(C(=O)c3ccc4ccccc4c3)cc2)cc1)c1ccccc1C ; CC(=O)O/N=C(/C(=O)c1ccc(Sc2ccc(C(=O)c3ccccc3C)cc2)cc1)c1ccccc1C]

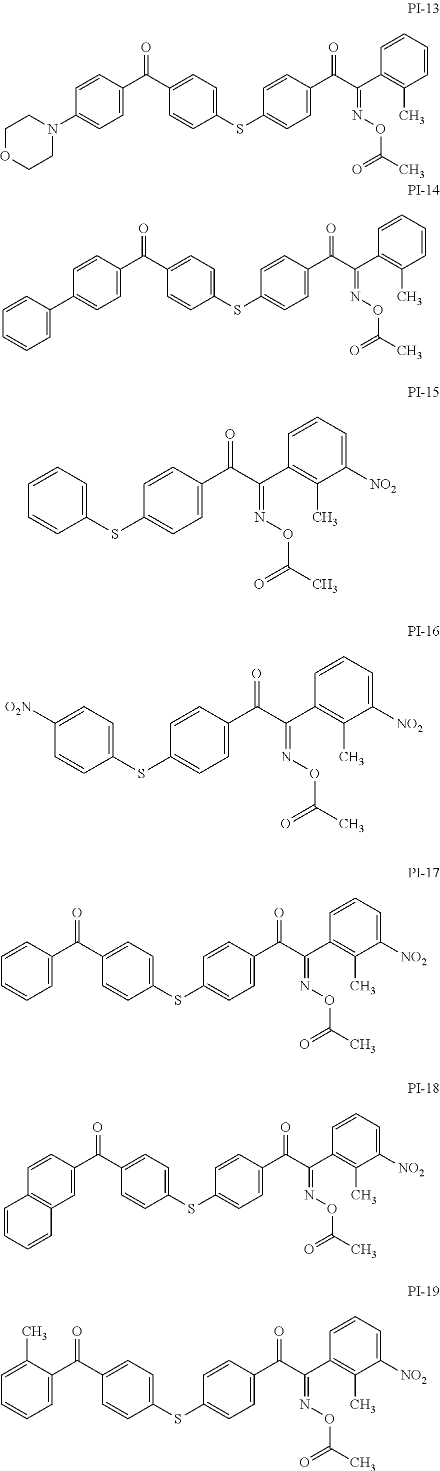

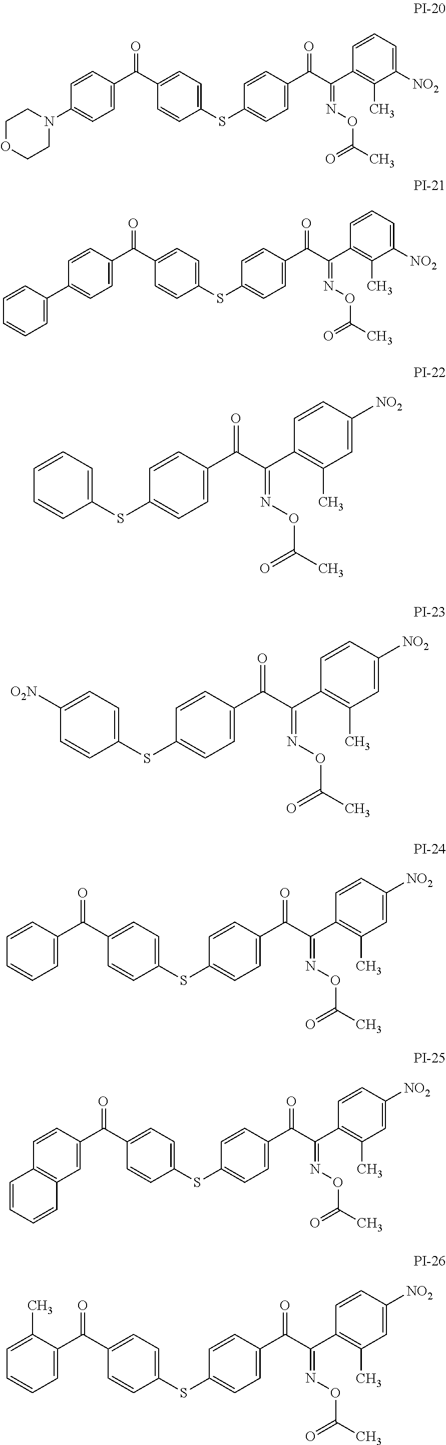

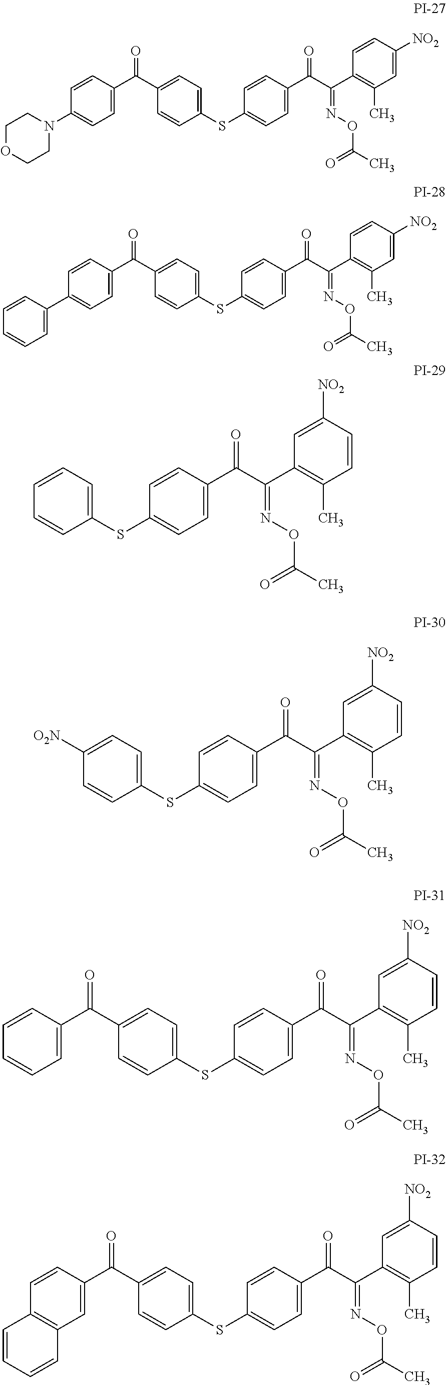

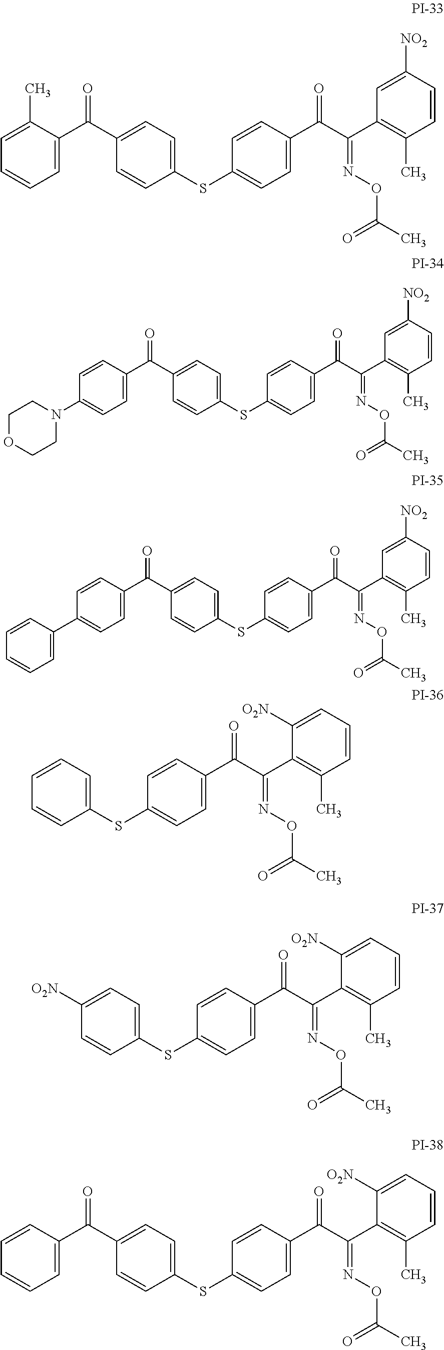 [SMILES: CC(=O)O/N=C(/C(=O)c1ccc(Sc2ccc(C(=O)c3ccccc3C)cc2)cc1)c1cc([N+](=O)[O-])ccc1C ; CC(=O)O/N=C(/C(=O)c1ccc(Sc2ccc(C(=O)c3ccc(N4CCOCC4)cc3)cc2)cc1)c1cc([N+](=O)[O-])ccc1C ; CC(=O)O/N=C(/C(=O)c1ccc(Sc2ccc(C(=O)c3ccc(-c4ccccc4)cc3)cc2)cc1)c1cc([N+](=O)[O-])ccc1C ; CC(=O)O/N=C(/C(=O)c1ccc(Sc2ccccc2)cc1)c1c(C)cccc1[N+](=O)[O-] ; CC(=O)O/N=C(/C(=O)c1ccc(Sc2ccc([N+](=O)[O-])cc2)cc1)c1c(C)cccc1[N+](=O)[O-] ; CC(=O)O/N=C(/C(=O)c1ccc(Sc2ccc(C(=O)c3ccccc3)cc2)cc1)c1c(C)cccc1[N+](=O)[O-]]

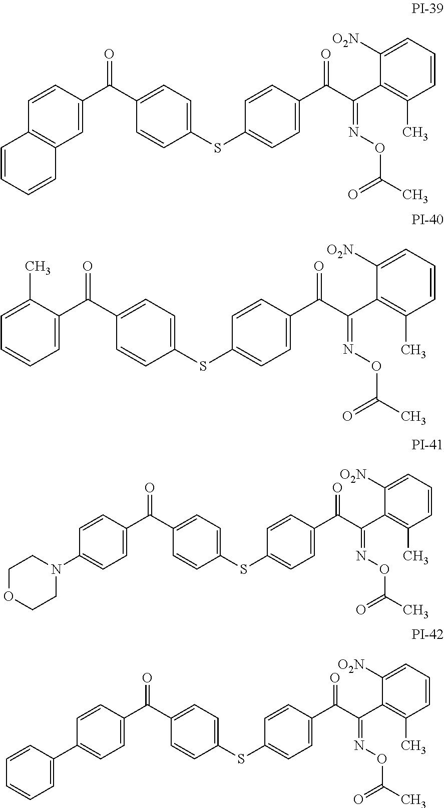 [SMILES: CC(=O)O/N=C(/C(=O)c1ccc(Sc2ccc(C(=O)c3ccc4ccccc4c3)cc2)cc1)c1c(C)cccc1[N+](=O)[O-] ; CC(=O)O/N=C(/C(=O)c1ccc(Sc2ccc(C(=O)c3ccccc3C)cc2)cc1)c1c(C)cccc1[N+](=O)[O-] ; CC(=O)O/N=C(/C(=O)c1ccc(Sc2ccc(C(=O)c3ccc(N4CCOCC4)cc3)cc2)cc1)c1c(C)cccc1[N+](=O)[O-] ; CC(=O)O/N=C(/C(=O)c1ccc(Sc2ccc(C(=O)c3ccc(-c4ccccc4)cc3)cc2)cc1)c1c(C)cccc1[N+](=O)[O-]]

Also preferred as (C) a photopolymerization initiator is an oxime ester compound represented by the following formula (c4). When using an oxime ester compound in combination with an a-aminoalkylphenone-based photopolymerization initiator, an oxime ester compound represented by the following formula (c4) is preferably used.

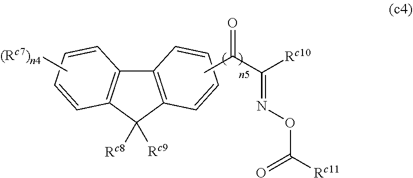

R^{c7} is a hydrogen atom, a nitro group, or a monovalent organic group, R^{c8} and R^{c9} each represent an optionally substituted chain alkyl group, an optionally substituted cyclic organic group, or a hydrogen atom, R^{c8} and R^{c9} may be bonded to one another to form a ring, R^{c10} is a monovalent organic group, R^{c11} is a hydrogen atom, an optionally substituted alkyl group having 1 or more and 11 or less carbon atoms, or an optionally substituted aryl group, n4 is an integer of 0 or more and 4 or less, and n5 is 0 or 1.

In the formula (c4), R^{c7} is a hydrogen atom, a nitro group, or a monovalent organic group. R^{c7} is bonded to a 6-membered aromatic ring which is different from the 6-membered aromatic ring bonded to a group represented as —(CO)ₙ₅— on a fluorene ring in the formula (c4). In the formula (c4), the bond position of R^{c7} to a fluorene ring is not particularly limited. When a compound represented by the formula (c4) has one or more R^{c7}(s), one of the one or more R^{c7}(s) is preferably bonded at the 2-position in the fluorene ring since the synthesis of the compound represented by the formula (c4) becomes easy. When plural R^{c7}s exist, the plural R^{c7}s may be the same or different.

When R^{c7} is an organic group, R^{c7} is not particularly limited as long as it does not interfere with the object of the present invention, and is appropriately selected from various organic groups. When R^{c7} is an organic group, suitable examples include an alkyl group, an alkoxy group, a cycloalkyl group, a cycloalkoxy group, a saturated aliphatic acyl group, a saturated aliphatic acyloxy group, an alkoxycarbonyl group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with one or two organic groups, a morpholin-1-yl group, and a piperazin-1-yl group.

When R^{c7} is an alkyl group, the number of carbon atoms of the alkyl group is preferably 1 or more and 20 or less, and more preferably 1 or more and 6 or less. When R^{c7} is an alkyl group, the alkyl group may be either one of a straight-chain or branched-chain alkyl group. When R^{c7} is an alkyl group, specific examples include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. When R^{c7} is an alkyl group, the alkyl group may contain an ether bond (—O—) in the carbon chain. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, a methoxypropyl group, and the like.

When R^{c7} is an alkoxy group, the number of carbon atoms of the alkoxy group is preferably 1 or more and 20 or less, and more preferably 1 or more and 6 or less. When R^{c7} is an alkoxy group, the alkoxy group may be a straight-chain or branched-chain group. When R^{c7} is an alkoxy group, specific examples thereof include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, and an isodecyloxy group. When R^{c7} is an alkoxy group, the alkoxy group may contain an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, and a methoxypropyloxy group.

When R^{c7} is a cycloalkyl group or a cycloalkoxy group, the number of carbon atoms of the cycloalkyl group or cycloalkoxy group is preferably 3 or more and 10 or less, and more preferably 3 or more and 6 or less. When R^{c7} is a cycloalkyl group, specific examples thereof include a cyclopropyl group, a cyclobutyl group, a cyclopentyl group, a cyclohexyl group, a cycloheptyl group, and a cyclooctyl group. When R^{c7} is a cycloalkoxy group, specific examples thereof include a cyclopropyloxy group, a cyclobutyloxy group, a cyclopentyloxy group, a cyclohexyloxy group, a cycloheptyloxy group, and a cyclooctyloxy group.

When R^{c7} is a saturated aliphatic acyl group or a saturated aliphatic acyloxy group, the number of carbon atoms of the saturated aliphatic acyl group or saturated aliphatic acyloxy group is preferably 2 or more and 21 or less, and more preferably 2 or more and 7 or less. When R^{c7} is a saturated aliphatic acyl group, specific examples thereof include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, and an n-hexadecanoyl group. When R^{c7} is a saturated aliphatic acyloxy group, specific examples thereof include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, and an n-hexadecanoyloxy group.

When R^{c7} is an alkoxycarbonyl group, the number of carbon atoms of the alkoxycarbonyl group is preferably 2 or more and 20 or less, and more preferably 2 or more and 7 or less. When R^{c7} is an alkoxycarbonyl group, specific examples thereof include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, and an isodecyloxycarbonyl group.

When R^{c7} is a phenylalkyl group, the number of carbon atoms of the phenylalkyl group is preferably 7 or more and 20 or less, and more preferably 7 or more and 10 or less. When R^{c7} is a naphthylalkyl group, the number of carbon atoms of the naphthylalkyl group is preferably 11 or more and 20 or less, and more preferably 11 or more and 14 or less. When R^{c7} is a phenylalkyl group, specific examples thereof include a benzyl group, a 2-phenylethyl group, a 3-phenylpropyl group, and a 4-phenylbutyl group. When R^{c7} is a naphthylalkyl group, specific examples thereof include an α-naphthylmethyl group, a β-naphthylmethyl group, a 2-(α-naphthyl)ethyl group, and a 2-(β-naphthyl)ethyl group. When R^{c7} is a phenylalkyl group or a naphthylalkyl group, R^{c7} may further have a substituent on a phenyl group or a naphthyl group.

When R^{c7} is a heterocyclyl group, the heterocyclyl group is a 5- or 6-membered single ring containing one or more N, S, and O, or a heterocyclyl group in which single rings are fused each other, or a single ring is fused with a benzene ring. When the heterocyclyl group is a fused ring, the number of fused ring is 3 or less. The heterocyclyl group may be any one of an aromatic group (heteroaryl group) and a non-aromatic group. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzoimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, and tetrahydrofuran. When R^{c7} is a heterocyclyl group, the heterocyclyl group may further have a substituent.

When R^{c7} is a heterocyclylcarbonyl group, a heterocyclyl group included in the heterocyclylcarbonyl group is the same as that in the case where R^{c7} is a heterocyclyl group.

When R^{c7} is an amino group substituted with one or two organic group(s), suitable examples of the organic group(s) include an alkyl group having 1 or more and 20 or less carbon atoms, a cycloalkyl group having 3 or more and 10 or less carbon atoms, a saturated aliphatic acyl group having 2 or more and 21 or less carbon atoms, an optionally substituted phenyl group, an optionally substituted benzoyl group, an optionally substituted phenylalkyl group having 7 or more and 20 or less carbon atoms, an optionally substituted naphthyl group, an optionally substituted naphthoyl group, an optionally substituted naphthylalkyl group having 11 or more 20 or less carbon atoms, and a heterocyclyl group. The specific examples of these suitable organic groups are the same as those of R^{c7}. Specific examples of the amino group substituted with one or two organic groups include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoylamino group, an n-hexanoylamino group, an n-heptanoylamino group, an n-octanoylamino group, an n-decanoylamino group, an benzoylamino group, an α-naphthoylamino group, and a β-naphthoylamino group.

When the phenyl group, the naphthyl group, and the heterocyclyl group included in R^{c7} further have a substituent, examples thereof include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group having an alkyl group which has 1 or more and 6 or less carbon atoms, a dialkylamino group having an alkyl group which has 1 or more and 6 or less carbon atoms, a morpholin-1-yl group, a piperazin-1-yl group, halogen, a nitro group, and a cyano group. When a phenyl group, a naphthyl group, and a heterocyclyl group included in R^{c7} further have substituents, the number of substituents is not particularly limited as long as it does not interfere with the object of the present invention, but is preferably 1 or more 4 or less. When a phenyl group, a naphthyl group, and a heterocyclyl group included in R^{c7} have plural substituents, the plural substituents may be the same or different.

Among the above-described groups, R^{c7} is preferably a nitro group or a group represented as R^{c12}—CO— since the sensitivity tends to be improved. R^{c12} is not particularly limited as long as it does not interfere with the object of the present invention, and can be selected from various organic groups. Examples of the group suitable as R^{c12} include an alkyl group having 1 or more and 20 or less carbon atoms, an optionally substituted phenyl group, an optionally substituted naphthyl group, and an optionally substituted heterocyclyl group. Among these groups, R^{c12} is particularly preferably a 2-methylphenyl group, a thiophen-2-yl group, and an α-naphthyl group. Moreover, it is preferred that R^{c7} is a hydrogen atom since the transparency tends to be satisfactory. When R^{c7} is a hydrogen atom and R^{c10} is a group represented by the formula (c4a) or (cob) mentioned later, the transparency tends to be even more satisfactory.

In the formula (c4), R^{c8} and R^{c9} each represent an optionally substituted chain alkyl group, an optionally substituted cyclic organic group, or a hydrogen atom. R^{c8} and R^{c9} may be bonded to one another to form a ring. Among these, preferably, R^{c8} and R^{c9} are optionally substituted chain alkyl groups. When R^{c8} and R^{c9} are optionally substituted chain alkyl groups, a chain alkyl group may be either a straight-chain alkyl group or a branched-chain alkyl group.

When R^{c8} and R^{c9} are chain alkyl groups having no substituent, the number of carbon atoms of the chain alkyl group is preferably 1 or more and 20 or less, more preferably 1 or more and 10 or less, and particularly preferably 1 or more and 6 or less. When R^{c8} and R^{c9} are chain alkyl groups, specific examples thereof include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, and an isodecyl group. When R^{c8} and R^{c9} are alkyl groups, the alkyl group may have an ether bond (—O—) in a carbon chain. Examples of the alkyl group having an ether bond in a carbon chain include a methoxyethyl group, an ethoxyethyl group, a methoxyethoxyethyl group, an ethoxyethoxyethyl group, a propyloxyethoxyethyl group, and a methoxypropyl group.

When R^{c8} and R^{c9} are chain alkyl groups having a substituent, the number of carbon atoms of the chain alkyl group is preferably 1 or more and 20 or less, more preferably 1 or more and 10 or less, and particularly preferably 1 or more and 6 or less. In this case, the number of carbon atoms of the substituent is not included in the number of carbon atoms of the chain alkyl group. The chain alkyl group having a substituent is preferably a straight-chain group. The substituent, with which the alkyl group is optionally substituted, is not particularly limited as long as it does not interfere with the object of the present invention. Suitable examples of the substituent include a cyano group, a halogen atom, a cyclic organic group, and an alkoxycarbonyl group. Examples of the halogen atom include a fluorine atom, a chlorine atom, a bromine atom, and an iodine atom. Among these, a fluorine atom, a chlorine atom, and a bromine atom are preferred. Examples of the cyclic organic group include a cycloalkyl group, an aromatic hydrocarbon group, and a heterocyclyl group. Specific examples of the cycloalkyl group are the same as suitable examples in case R^{c7} is a cycloalkyl group. Specific examples of the aromatic hydrocarbon group include a phenyl group, a naphthyl group, a biphenylyl group, an anthryl group, and a phenanthryl group. Specific examples of the heterocyclyl group are the same as suitable examples in case R^{c7} is a heterocyclyl group. When R^{c7} is an alkoxycarbonyl group, an alkoxy group included in the alkoxycarbonyl group may be either a straight-chain or branched-chain group, and preferably a straight-chain group. The number of carbon atoms of an alkoxy group included in the alkoxycarbonyl group is preferably 1 or more and 10 or less, and more preferably 1 or more and 6 or less.

When the chain alkyl group has a substituent, the number of substituents is not particularly limited. The number of substituents preferably varies depending on the number of carbon atoms of the chain alkyl group. The number of substituents is typically 1 or more and 20 or less, preferably 1 or more and 10 or less, and more preferably 1 or more and 6 or less.

When R^{c8} and R^{c9} are cyclic organic groups, the cyclic organic group may be either an alicyclic group or an aromatic group. Examples of the cyclic organic group include an aliphatic cyclic hydrocarbon group, an aromatic hydrocarbon group, and a heterocyclyl group. When R^{c8} and R^{c9} are cyclic organic groups, the substituent, with which the cyclic organic group is optionally substituted, is the same as in case R^{c8} and R^{c9} are chain alkyl groups.

When R^{c8} and R^{c9} are aromatic hydrocarbon groups, the aromatic hydrocarbon group is preferably a phenyl group, or a group formed by bonding plural benzene rings through a carbon-carbon bond, or a group formed by condensing plural benzene rings. When the aromatic hydrocarbon group is a phenyl group, or a group formed by bonding or condensing plural benzene rings, the number of rings of a benzene ring included in the aromatic hydrocarbon group is not particularly limited, and is preferably 3 or less, more preferably 2 or less, and particularly preferably 1. Preferred specific examples of the aromatic hydrocarbon group include a phenyl group, a naphthyl group, a biphenylyl group, an anthryl group, and a phenanthryl group.

When R^{c8} and R^{c9} are aliphatic cyclic hydrocarbon groups, the aliphatic cyclic hydrocarbon group may be either a monocyclic or polycyclic group. The number of carbon atoms of the aliphatic cyclic hydrocarbon group is not particularly limited, and is preferably 3 or more 20 or less, and more preferably 3 or more and 10 or less. Examples of the monocyclic cyclic hydrocarbon group include a cyclopropyl group, a cyclobutyl group, a cyclopentyl group, a cyclohexyl group, a cycloheptyl group, a cyclooctyl group, a norbornyl group, a isobornyl group, a tricyclononyl group, a tricyclodecyl group, a tetracyclododecyl group, and an adamantyl group.

When R^{c8} and R^{c9} are heterocyclyl groups, the heterocyclyl group is a 5-membered or 6-membered monocycle containing one or more, and preferably one or more and four or less, N, S, and O, or a heterocyclyl group in which these monocycles are condensed, or the monocycle and a benzene ring are condensed. When the heterocyclyl group is a condensation ring, the number of rings is 3 or less. The heterocyclyl group may be either an aromatic group (heteroaryl group) or a non-aromatic group. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzoimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, and tetrahydrofuran.

R^{c8} and R^{c9} may be bonded to one another to form a ring. The group composed of the ring formed by R^{c8} and R^{c9} is preferably a cycloalkylidene group. When R^{c8} and R^{c9} are bonded to form a cycloalkylidene group, the ring constituting the cycloalkylidene group is preferably a 5- to 6-membered ring, and more preferably a 5-membered ring.

When the group formed by bonding R^{c8} and R^{c9} is a cycloalkylidene group, the cycloalkylidene group may be fused with one or more other rings. Examples of the ring which may be fused with the cycloalkylidene group include a benzene ring, a naphthalene ring, a cyclobutane ring, a cyclopentane ring, a cyclohexane ring, a cycloheptane ring, a cyclooctane ring, a furan ring, a thiophene ring, a pyrrole ring, a pyridine ring, a pyrazine ring, a pyrimidine ring, and the like.

Examples of suitable group among R^{c8} and R^{c9} described above include a group represented by the formula: -A¹-A². In the formula, A¹ is a straight-chain alkylene group, and A² is an alkoxy group, a cyano group, a halogen atom, a halogenated alkyl group, a cyclic organic group, or an alkoxycarbonyl group.

The number of carbon atoms of the straight chain alkylene group for A¹ is preferably 1 or more and 10 or less, and more preferably 1 or more and 6 or less. When A² is an alkoxy group, the alkoxy group may be any one of straight chain and branched-chain alkoxy groups, and preferably a straight-chain alkoxy group. The number of carbon atoms of the alkoxy group is preferably 1 or more and 10 or less, and more preferably 1 or more and 6 or less. When A² is a halogen atom, a fluorine atom, a chlorine atom, a bromine atom, or an iodine atom is preferred, and a fluorine atom, a chlorine atom, or a bromine atom is more preferred. When A² is a halogenated alkyl group, a halogen atom included in the halogenated alkyl group is preferably a fluorine atom, a chlorine atom, a bromine atom, or an iodine atom, and more preferably is a fluorine atom, a chlorine atom, or a bromine atom. The halogenated alkyl group may be any one of straight-chain and branched-chain halogenated alkyl groups, and preferably a straight-chain halogenated alkyl group. When A² is a cyclic organic group, examples of the cyclic organic group are the same as the cyclic organic group possessed by R^{c8} and R^{c9} as the substituent. When A² is an alkoxycarbonyl group, examples of the alkoxycarbonyl group are the same as the alkoxycarbonyl group possessed by R^{c8} and R^{c9} as the substituent.

Suitable specific examples of R^{c8} and R^{c9} include alkyl groups such as an ethyl group, an n-propyl group, an n-butyl group, an n-hexyl group, an n-heptyl group, and an n-octyl group; alkoxyalkyl groups such as a 2-methoxyethyl group, a 3-methoxy-n-propyl group, a 4-methoxy-n-butyl group, a 5-methoxy-n-pentyl group, a 6-methoxy-n-hexyl group, a 7-methoxy-n-heptyl group, a 8-methoxy-n-octyl group, a 2-ethoxyethyl group, a 3-ethoxy-n-propyl group, a 4-ethoxy-n-butyl group, a 5-ethoxy-n-pentyl group, a 6-ethoxy-n-hexyl group, a 7-ethoxy-n-heptyl group, and a 8-ethoxy-n-octyl group; cyanoalkyl groups such as a 2-cyanoethyl group, a 3-cyano-n-propyl group, a 4-cyano-n-butyl group, a 5-cyano-n-pentyl group, a 6-cyano-n-hexyl group, a 7-cyano-n-heptyl group, and a 8-cyano-n-octyl group; phenylalkyl groups such as a 2-phenylethyl group, a 3-phenyl-n-propyl group, a 4-phenyl-n-butyl group, a 5-phenyl-n-pentyl group, a 6-phenyl-n-hexyl group, a 7-phenyl-n-heptyl group, and a 8-phenyl-n-octyl group; cycloalkylalkyl groups such as a 2-cyclohexylethyl group, a 3-cyclohexyl-n-propyl group, a 4-cyclohexyl-n-butyl group, a 5-cyclohexyl-n-pentyl group, a 6-cyclohexyl-n-hexyl group, a 7-cyclohexyl-n-heptyl group, a 8-cyclohexyl-n-octyl group, a 2-cyclopentylethyl group, a 3-cyclopentyl-n-propyl group, a 4-cyclopentyl-n-butyl group, a 5-cyclopentyl-n-pentyl group, a 6-cyclopentyl-n-hexyl group, a 7-cyclopentyl-n-heptyl group, and a 8-cyclopentyl-n-octyl group; alkoxycarbonylalkyl groups such as a 2-methoxycarbonylethyl group, a 3-methoxycarbonyl-n-propyl group, a 4-methoxycarbonyl-n-butyl group, a 5-methoxycarbonyl-n-pentyl group, a 6-methoxycarbonyl-n-hexyl group, a 7-methoxycarbonyl-n-heptyl group, a 8-methoxycarbonyl-n-octyl group, a 2-ethoxycarbonylethyl group, a 3-ethoxycarbonyl-n-propyl group, a 4-ethoxycarbonyl-n-butyl group, a 5-ethoxycarbonyl-n-pentyl group, a 6-ethoxycarbonyl-n-hexyl group, a 7-ethoxycarbonyl-n-heptyl group, and a 8-ethoxycarbonyl-n-octyl group; and halogenated alkyl groups such as a 2-chloroethyl group, a 3-chloro-n-propyl group, a 4-chloro-n-butyl group, a 5-chloro-n-pentyl group, a 6-chloro-n-hexyl group, a 7-chloro-n-heptyl group, a 8-chloro-n-octyl group, a 2-bromoethyl group, a 3-bromo-n-propyl group, a 4-bromo-n-butyl group, a 5-bromo-n-pentyl group, a 6-bromo-n-hexyl group, a 7-bromo-n-heptyl group, a 8-bromo-n-octyl group, a 3,3,3-trifluoropropyl group, and a 3,3,4,4,5,5,5-heptafluoro-n-pentyl group.

Among groups mentioned above, groups suitable as R^{c8} and R^{c9} are an ethyl group, an n-propyl group, an n-butyl group, an n-pentyl group, a 2-methoxyethyl group, a 2-cyanoethyl group, a 2-phenylethyl group, a 2-cyclohexylethyl group, a 2-methoxycarbonylethyl group, a 2-chloroethyl group, a 2-bromoethyl group, a 3,3,3-trifluoropropyl group, and a 3,3,4,4,5,5,5-heptafluoro-n-pentyl group.

Like R^{c7}, examples of suitable organic group for R^{c10} include an alkyl group, an alkoxy group, a cycloalkyl group, a cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, a naphthoyloxy group, an optionally substituted naphthylalkyl group, an optionally substituted heterocyclyl group, an optionally substituted heterocyclylcarbonyl group, an amino group substituted with one or two organic groups, a morpholin-1-yl group, a piperazin-1-yl group, and the like. Specific examples of these groups are the same as those described for R^{c7}. R^{c10} is also preferably a cycloalkylalkyl group, a phenoxyalkyl group which may have a substituent on an aromatic ring, and a phenylthioalkyl group which may have a substituent on an aromatic ring. The substituent which may be possessed by a phenoxyalkyl group and phenylthioalkyl group is the same as the substituent which may be possessed by a phenyl group included in R^{c7}.

Among organic groups, R^{c10} is preferably an alkyl group, a cycloalkyl group, an optionally substituted phenyl group, or a cycloalkylalkyl group, or a phenylthioalkyl group which may have a substituent on an aromatic ring. The alkyl group is preferably an alkyl group having 1 or more and 20 or less carbon atoms, more preferably, an alkyl group having 1 or more and 8 or less carbon atoms, particularly preferably, an alkyl group having 1 or more and 4 or less carbon atoms, and most preferably a methyl group. Among optionally substituted phenyl groups, a methylphenyl group is preferred and a 2-methylphenyl group is more preferred. The number of carbon atoms of the cycloalkyl group included in the cycloalkylalkyl group is preferably 5 or more and 10 or less, more preferably 5 or more and 8 or less, and particularly preferably 5 or 6. The number of carbon atoms of the alkylene group included in the cycloalkylalkyl group is preferably 1 or more and 8 or less, more preferably 1 or more and 4 or less, and particularly preferably 2. Among cycloalkylalkyl groups, a cyclopentylethyl group is preferred. The number of carbon atoms of the alkylene group which may have a substituent on an aromatic ring included in the phenylthioalkyl group, is preferably 1 or more and 8 or less, more preferably 1 or more and 4 or less, and particularly preferably 2. Among the phenylthioalkyl group which may have a substituent on an aromatic ring, a 2-(4-chlorophenylthio)ethyl group is preferred.

R^{c10} is also preferably a group represented by -A³-CO—O-A⁴. A³ is a divalent organic group, preferably a divalent hydrocarbon group, and more preferably an alkylene group. A⁴ is a monovalent organic group, and preferably a monovalent hydrocarbon group.

When A³ is an alkylene group, alkylene group may be any one of straight-chain and branched-chain alkylene groups, and preferably a straight-chain alkylene group. When A³ is an alkylene group, the number of carbon atoms of the alkylene group is preferably 1 or more and 10 or less, more preferably 1 or more and 6 or less, and particularly preferably 1 or more and 4 or less.

Suitable examples of A⁴ include an alkyl group having 1 or more and 10 or less carbon atoms, an aralkyl group having 7 or more and 20 or less carbon atoms, and an aromatic hydrocarbon group having 6 or more and 20 or less carbon atoms. Suitable specific examples of A⁴ include a methyl group, an ethyl group, an n-propyl group, an isopropyl group, an n-butyl group, an isobutyl group, a sec-butyl group, a tert-butyl group, an n-pentyl group, an n-hexyl group, a phenyl group, a naphthyl group, a benzyl group, a phenethyl group, an a-naphthylmethyl group, a β-naphthylmethyl group, and the like.

Suitable specific examples of the group represented by -A³-CO—O-A⁴ include a 2-methoxycarbonylethyl group, a 2-ethoxycarbonylethyl group, a 2-n-propyloxycarbonylethyl group, a 2-n-butyloxycarbonylethyl group, a 2-n-pentyloxycarbonylethyl group, a 2-n-hexyloxycarbonylethyl group, a 2-benzyloxycarbonylethyl group, a 2-phenoxycarbonylethyl group, a 3-methoxycarbonyl-n-propyl group, a 3-ethoxycarbonyl-n-propyl group, a 3-n-propyloxycarbonyl-n-propyl group, a 3-n-butyloxycarbonyl-n-propyl group, a 3-n-pentyloxycarbonyl-n-propyl group, a 3-n-hexyloxycarbonyl-n-propyl group, a 3-benzyloxycarbonyl-n-propyl group, a 3-phenoxycarbonyl-n-propyl group, and the like.

While R^{c10} has been described above, R^{c10} is preferably a group represented by the following formula (c4a) or (c4b):

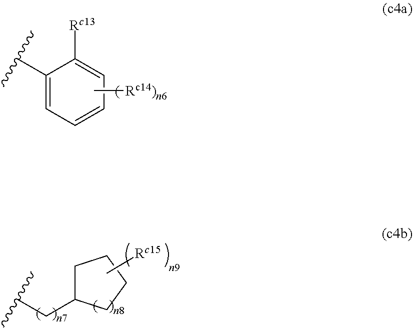

in which, in the formulas (c4a) and (c4b), R^{c13} and R^{c14} each are an organic group, n6 is an integer of 0 or more and 4 or less; when R^{c13} and R^{c14} exist at adjacent positions on a benzene ring, R^{c13} and R^{c14} may be bonded to one another to form a ring; n7 is an integer of 1 or more and 8 or less; n8 is an integer of 1 or more and 5 or less; n9 is an integer of 0 or more and (n8+3) or less; and R^{c15} is an organic group.

Examples of the organic group for R^{c13} and R^{c14} in the formula (c4a) are the same as those in R^{c7}. R^{c13} is preferably an alkyl group or a phenyl group. When R^{c13} is an alkyl group, the number of carbon atoms thereof is preferably 1 or more and 10 or less, more preferably 1 or more and 5 or less, particularly preferably 1 or more and 3 or less, and most preferably 1. Namely, R^{c13} is most preferably a methyl group. When R^{c13} and R^{c14} are bonded to form a ring, the ring may be either one of an aromatic ring or an aliphatic ring. Suitable examples of the group represented by the formula (c4a) in which R^{c13} and R^{c14} form a ring include a naphthalen-1-yl group, a 1,2,3,4-tetrahydronaphthalen-5-yl group, and the like. In the above formula (c4a), n6 is an integer of 0 or more and 4 or less, preferably 0 or 1, and more preferably 0.

In the above formula (c4b), R^{c15} is an organic group. Examples of the organic group include the same group as the organic group described for R^{c7}. Among the organic groups, an alkyl group is preferred. The alkyl group may be any one of straight-chain and branched-chain alkyl groups. The number of carbon atoms of the alkyl group is preferably 1 or more and 10 or less, more preferably, 1 or more and 5 or less, and particularly preferably 1 or more and 3 or less. Preferred examples of R^{c15} include a methyl group, an ethyl group, a propyl group, an isopropyl group, a butyl group, and the like. Among these, a methyl group is more preferred.

In the above formula (c4b), n8 is an integer of 1 or more and 5 or less, preferably 1 or more and 3 or less, and more preferably 1 or 2. In the formula (c4b), n9 is 0 or more and (n8+3) or less, preferably an integer of 0 or more and 3 or less, more preferably an integer of 0 or more and 2 or less, and particularly preferably 0. In the formula (c4b), n7 is an integer of 1 or more and 8 or less, preferably an integer of 1 or more and 5 or less, more preferably an integer of 1 or more and 3 or less, and particularly preferably 1 or 2.

In the formula (c4), R^{c11} is a hydrogen atom, an optionally substituted alkyl group having 1 or more and 11 or less carbon atoms, or an optionally substituted aryl group. When R^{c11} is an alkyl group, preferred examples of the substituent which may be possessed include a phenyl group, a naphthyl group, or the like. When R^{c7} is an aryl group, preferred examples of the substituent which may be possessed include an alkyl group having 1 or more and 5 or less carbon atoms, an alkoxy group, a halogen atom, or the like.

In the formula (c4), preferred examples of R^{c11} include a hydrogen atom, a methyl group, an ethyl group, an n-propyl group, an isopropyl group, an n-butyl group, a phenyl group, a benzyl group, a methylphenyl group, a naphthyl group, and the like. Among these, a methyl group or a phenyl group is more preferred.

Suitable specific examples of the compound represented by the formula (c4) include the following PI-43 to PI-83.

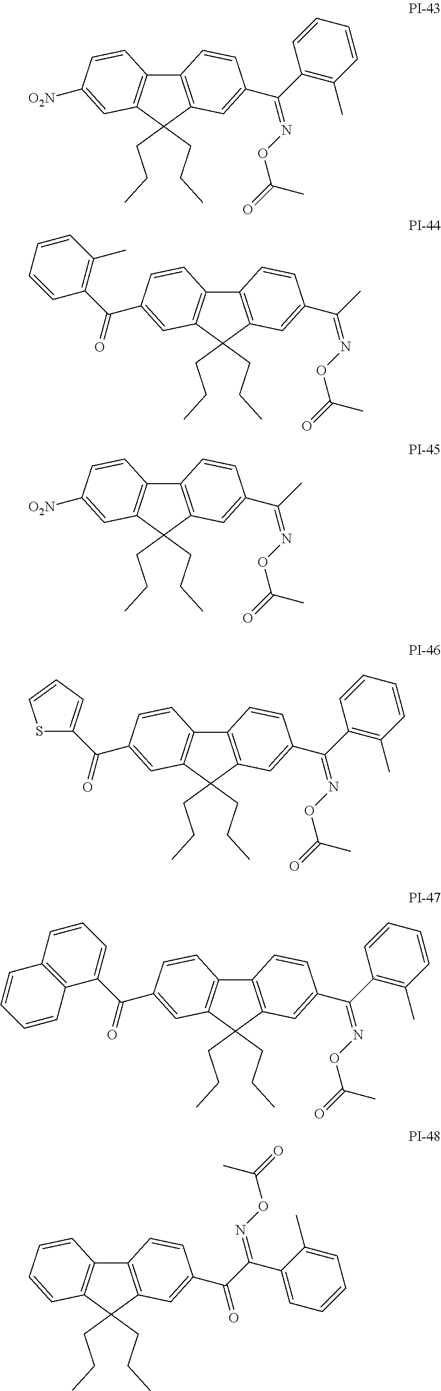

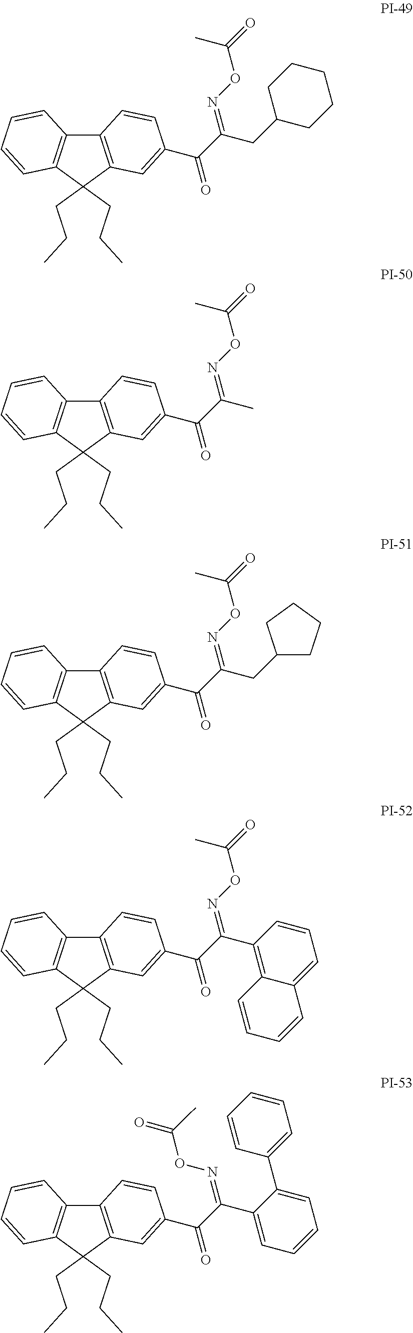 [SMILES: CCCC1(CCC)c2ccccc2-c2ccc(C(=O)/C(CC3CCCCC3)=N/OC(C)=O)cc21 ; CCCC1(CCC)c2ccccc2-c2ccc(C(=O)/C(C)=N/OC(C)=O)cc21 ; CCCC1(CCC)c2ccccc2-c2ccc(C(=O)/C(CC3CCCC3)=N/OC(C)=O)cc21 ; CCCC1(CCC)c2ccccc2-c2ccc(C(=O)/C(=N/OC(C)=O)c3cccc4ccccc34)cc21 ; CCCC1(CCC)c2ccccc2-c2ccc(C(=O)/C(=N\OC(C)=O)c3ccccc3-c3ccccc3)cc21]

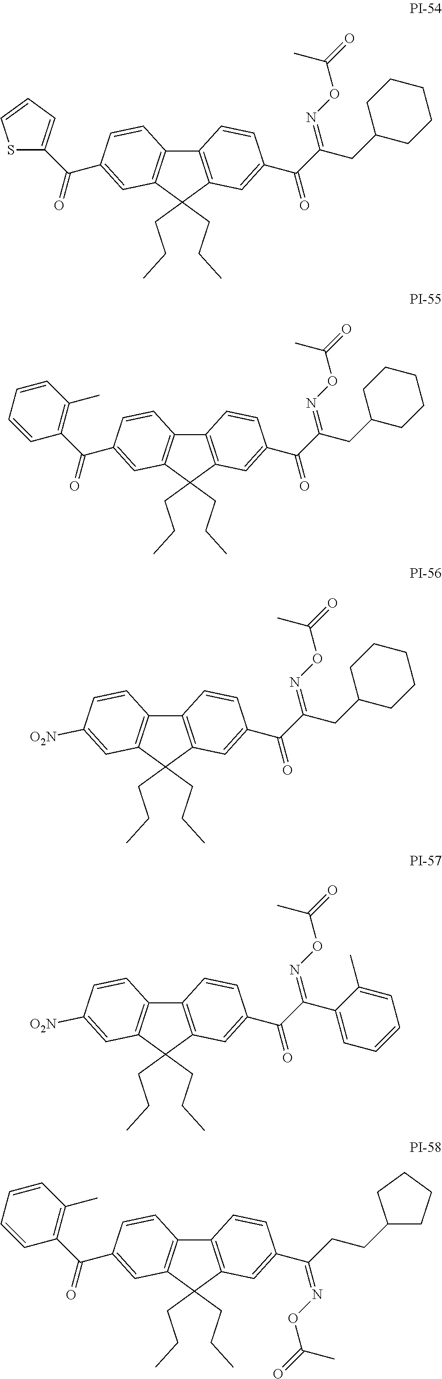 [SMILES: CCCC1(CCC)c2cc(C(=O)/C(CC3CCCCC3)=N/OC(C)=O)ccc2-c2ccc(C(=O)c3cccs3)cc21 ; CCCC1(CCC)c2cc(C(=O)/C(CC3CCCCC3)=N/OC(C)=O)ccc2-c2ccc(C(=O)c3ccccc3C)cc21 ; CCCC1(CCC)c2cc(C(=O)/C(CC3CCCCC3)=N/OC(C)=O)ccc2-c2ccc([N+](=O)[O-])cc21 ; CCCC1(CCC)c2cc(C(=O)/C(=N/OC(C)=O)c3ccccc3C)ccc2-c2ccc([N+](=O)[O-])cc21 ; CCCC1(CCC)c2cc(C(=O)c3ccccc3C)ccc2-c2ccc(/C(CCC3CCCC3)=N\OC(C)=O)cc21]

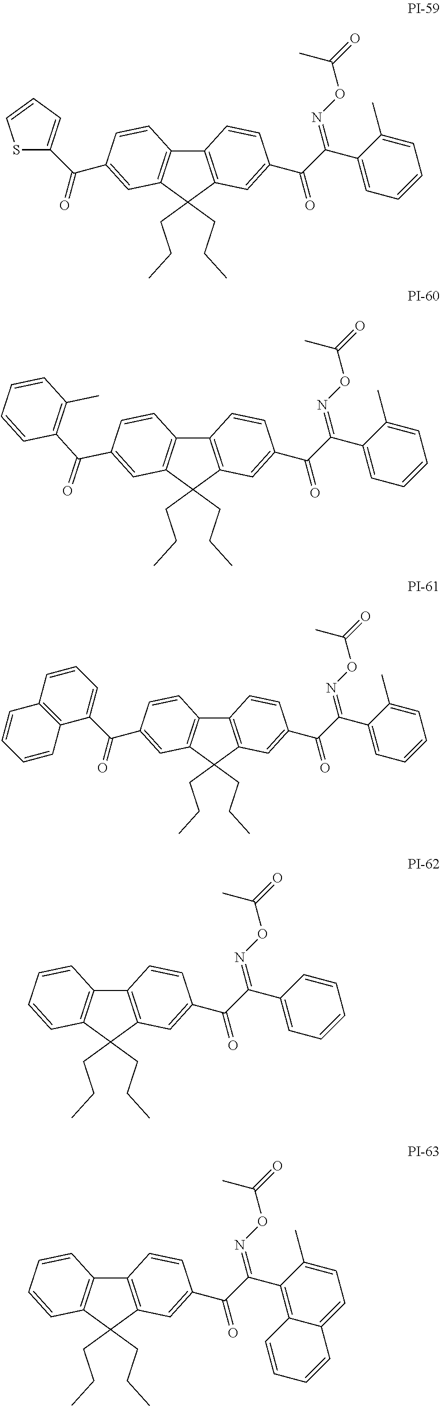 [SMILES: CCCC1(CCC)c2cc(C(=O)/C(=N/OC(C)=O)c3ccccc3C)ccc2-c2ccc(C(=O)c3cccs3)cc21 ; CCCC1(CCC)c2cc(C(=O)/C(=N/OC(C)=O)c3ccccc3C)ccc2-c2ccc(C(=O)c3ccccc3C)cc21 ; CCCC1(CCC)c2cc(C(=O)/C(=N/OC(C)=O)c3ccccc3C)ccc2-c2ccc(C(=O)c3cccc4ccccc34)cc21 ; CCCC1(CCC)c2ccccc2-c2ccc(C(=O)/C(=N/OC(C)=O)c3ccccc3)cc21 ; CCCC1(CCC)c2ccccc2-c2ccc(C(=O)/C(=N/OC(C)=O)c3c(C)ccc4ccccc34)cc21]

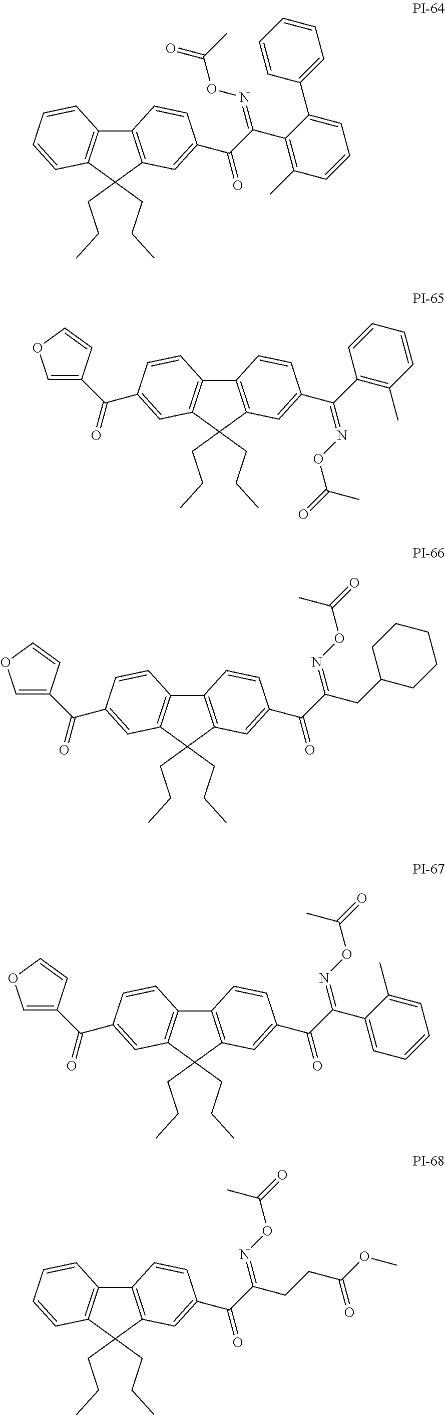 [SMILES: CCCC1(CCC)c2ccccc2-c2ccc(C(=O)/C(=N\OC(C)=O)c3c(C)cccc3-c3ccccc3)cc21 ; CCCC1(CCC)c2cc(C(=O)c3ccoc3)ccc2-c2ccc(/C(=N\OC(C)=O)c3ccccc3C)cc21 ; CCCC1(CCC)c2cc(C(=O)/C(CC3CCCCC3)=N/OC(C)=O)ccc2-c2ccc(C(=O)c3ccoc3)cc21 ; CCCC1(CCC)c2cc(C(=O)/C(=N/OC(C)=O)c3ccccc3C)ccc2-c2ccc(C(=O)c3ccoc3)cc21 ; CCCC1(CCC)c2ccccc2-c2ccc(C(=O)/C(CCC(=O)OC)=N/OC(C)=O)cc21]

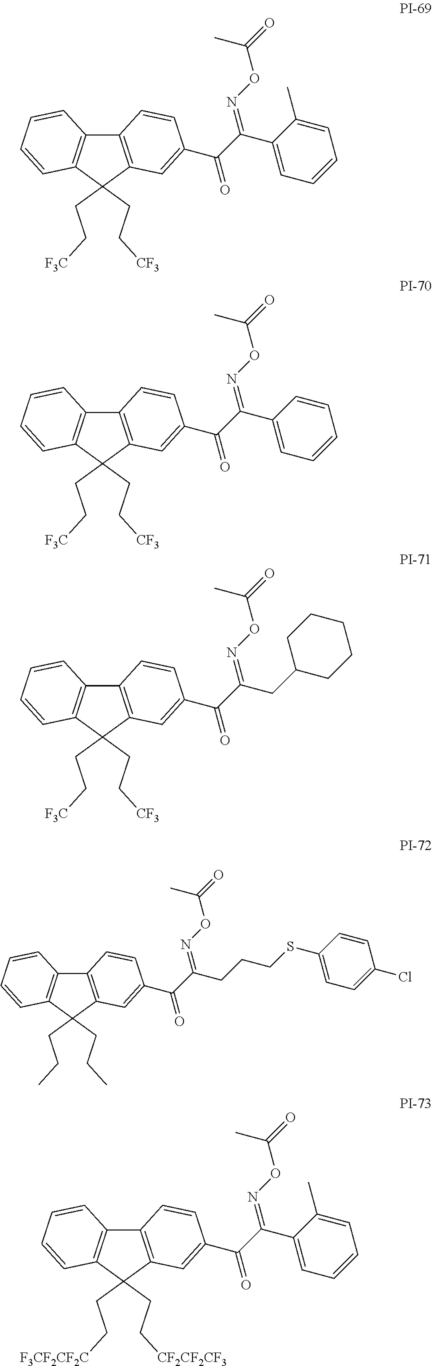

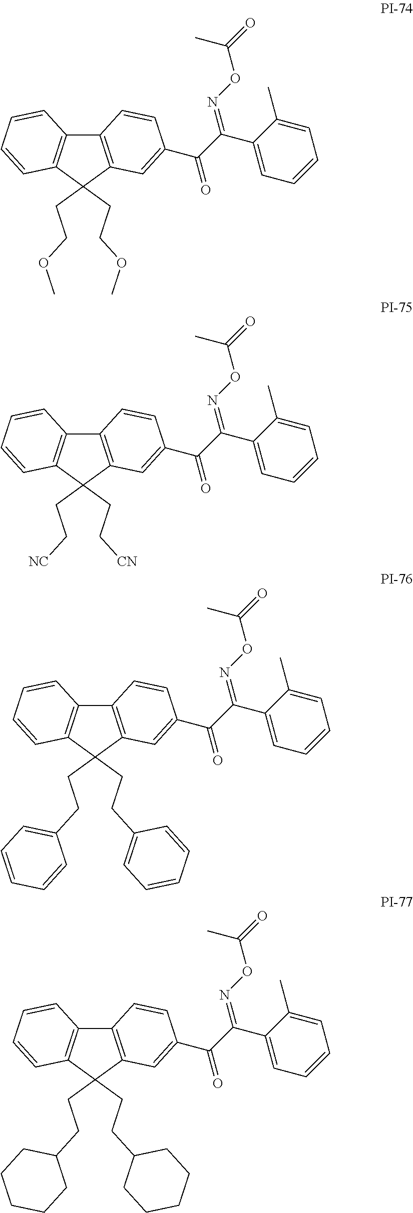 [SMILES: COCCC1(CCOC)c2ccccc2-c2ccc(C(=O)/C(=N/OC(C)=O)c3ccccc3C)cc21 ; CC(=O)O/N=C(/C(=O)c1ccc2c(c1)C(CCC#N)(CCC#N)c1ccccc1-2)c1ccccc1C ; CC(=O)O/N=C(/C(=O)c1ccc2c(c1)C(CCc1ccccc1)(CCc1ccccc1)c1ccccc1-2)c1ccccc1C ; CC(=O)O/N=C(/C(=O)c1ccc2c(c1)C(CCC1CCCCC1)(CCC1CCCCC1)c1ccccc1-2)c1ccccc1C]

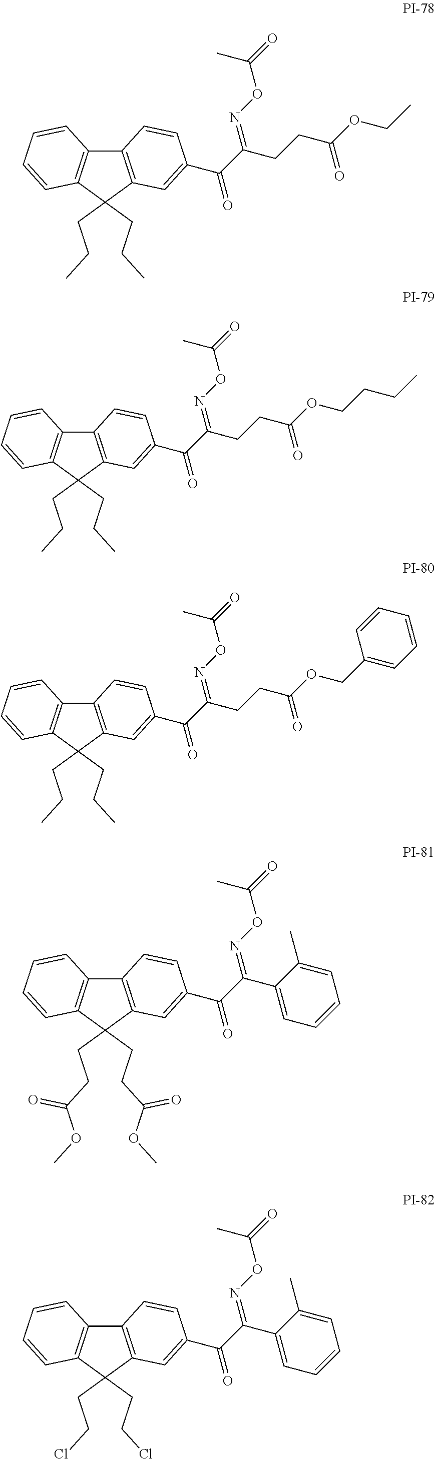 [SMILES: CCCC1(CCC)c2ccccc2-c2ccc(C(=O)/C(CCC(=O)OCC)=N/OC(C)=O)cc21 ; CCCCOC(=O)CC/C(=N\OC(C)=O)C(=O)c1ccc2c(c1)C(CCC)(CCC)c1ccccc1-2 ; CCCC1(CCC)c2ccccc2-c2ccc(C(=O)/C(CCC(=O)OCc3ccccc3)=N/OC(C)=O)cc21 ; COC(=O)CCC1(CCC(=O)OC)c2ccccc2-c2ccc(C(=O)/C(=N/OC(C)=O)c3ccccc3C)cc21 ; CC(=O)O/N=C(/C(=O)c1ccc2c(c1)C(CCCl)(CCCl)c1ccccc1-2)c1ccccc1C]

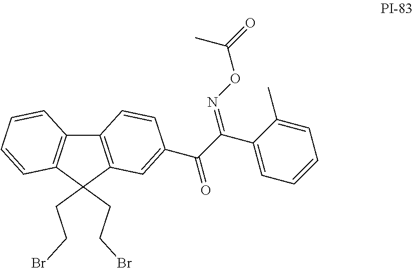 [SMILES: CC(=O)O/N=C(/C(=O)c1ccc2c(c1)C(CCBr)(CCBr)c1ccccc1-2)c1ccccc1C]

The content of the (C) photopolymerization initiator is preferably 0.5% by mass or more and 30% by mass or less, and more preferably 1% by mass or more and 20% by mass or less, based on the mass of the photosensitive resin composition excluding the mass (the mass of the total solid component) of the below-mentioned (S) organic solvent. It is possible to obtain a photosensitive resin composition having satisfactory curability in which defective pattern shapes are less likely to occur by adjusting the content of the (C) photopolymerization initiator in the above range.

When the photosensitive resin composition contains, as the (C) photopolymerization initiator, an oxime ester compound and an a-aminoalkylphenone-based photopolymerization initiator in combination, the content of the oxime ester compound in the (C) photopolymerization initiator is preferably more than the content of the a-aminoalkylphenone-based photopolymerization initiator. In this case, the content of the a-aminoalkylphenone-based photopolymerization initiator in the (C) photopolymerization initiator is preferably less than 50% by mass, more preferably 1% by mass or more and 40% by mass or less, and still more preferably 1% by mass or more and 30% by mass or less. The upper limit of the content of the a-aminoalkylphenone-based photopolymerization initiator in the (C) photopolymerization initiator may be, for example, 20% by mass or less or 15% by mass or less as long as it does not interfere with the object of the present invention. The upper limit may be 5% by mass or more.

When the photosensitive resin composition contains, as the (C) photopolymerization initiator, the above-mentioned oxime ester compound represented by the formula (c4), the content of the oxime ester compound represented by the formula (c4) in the (C) photopolymerization initiator is more preferably 1% by mass or more and 99% by mass or less, still more preferably 1% by mass or more and 70% by mass or less, and particularly preferably 1% by mass or more and 50% by mass or less.

When using in combination with the photopolymerization initiator other than the oxime ester compound, a ratio of the mass of the oxime ester compound to the mass of the (C) photopolymerization initiator is preferably 50% by mass or more, more preferably 50% by mass or more and 99% by mass or less, particularly preferably 70% by mass or more and 97% by mass or less, and most preferably 80% by mass or more and 95% by mass or less. When the oxime ester compound is contained in the (C) photopolymerization initiator in the amount within the above range, a patterned cured film having a width wider than a desired width is scarcely formed, particularly.

The (C) photopolymerization initiator may be used in combination with a photoinitiation auxiliary. Examples of the photoinitiation auxiliary include thiol compounds such as triethanolamine, methyldiethanolamine, triisopropanolamine, methyl 4-dimethylaminobenzoate, ethyl 4-dimethylaminobenzoate, isoamyl 4-dimethylaminobenzoate, 2-ethylhexyl 4-dimethylaminobenzoate, benzoic acid 2-dimethylaminoethyl, N,N-dimethyl p-toluidine, 4,4′-bis(dimethylamino)benzophenone, 9,10-dimethoxyanthracene, 2-ethyl-9,10-dimethoxyanthracene, 9,10-diethoxyanthracene, 2-ethyl-9,10-diethoxyanthracene, 2-mercaptobenzothiazole, 2-mercaptobenzoxazole, 2-mercaptobenzimidazole, 2-mercapto-5-methoxybenzothiazole, 3-mercaptopropionic acid, methyl 3-mercaptopropionate, pentaerythritol tetramercaptoacetate, and 3-mercaptopropionate. These photoinitiation auxiliaries can be used alone or in combination of two or more types thereof.

### <(D) Coloring Agent>

The photosensitive resin composition contains (D) a coloring agent. The (D) coloring agent contains (D1) a carbon black and/or an inorganic black pigment, and (D2) an organic pigment. When the photosensitive resin composition contains, as the (D) coloring agent, (D1) a carbon black and/or an inorganic black pigment, and (D2) an organic pigment, it is easy to achieve both formation of a cured film excellent in light shielding properties and satisfactory curing of a coating film by baking at low temperature. The reason is that use of (D1) a carbon black and/or an inorganic black pigment in combination with (D2) an organic pigment enables enhancement of light transmitting properties in a wavelength region which can be utilized by the (C) photopolymerization initiator in the photosensitive resin composition.

((D1) Carbon Black and/or Inorganic Black Pigment)

As the carbon black, known carbon black such as channel black, furnace black, thermal black, and lamp black are usable. Also, a resin-coated carbon black may be used.

As the carbon black, a carbon black having been processed to introduce an acidic group is preferred. The acidic group to be introduced to the carbon black is a functional group which is acidic according to the definition by Bronsted. Specific examples of the acidic group include a carboxy group, a sulfonic group, and a phosphonic group. The acidic group introduced to the carbon black may form a salt. Cation forming the salt and the acidic group is not particularly limited as long as it does not interfere with the objective of the present invention. As an example of the cation, various metal ions, cations of a nitrogen-containing compound, ammonium ions and the like can be exemplified, and alkali metal ions such as sodium ions, potassium ions, and lithium ions as well as ammonium ions are preferred.

Among the above described carbon black having been processed to introduce an acidic group, carbon black having one or more functional groups selected from the group consisting of a carboxylic acid group, a carboxylic acid salt group, a sulfonic group, and a sulfonic acid salt group is preferred, in view of achieving higher insulation properties of a light shielding cured film formed by using the photosensitive resin composition.

A method of introducing an acidic group to carbon black is not particularly limited. As a method of introducing an acidic group, for example, the following methods may be exemplified:

1) A method of introducing a sulfonic group into carbon black by a direct substitution method using concentrated sulfuric acid, fuming sulfuric acid, and chlorosulfonic acid, or an indirect substitution method using sulfite, hydrogen sulfite and the like;
2) A method of diazo-coupling an organic compound having an amino group and an acidic group with carbon black;
3) A method of reacting an organic compound having a halogen atom and an acidic group with carbon black having a hydroxyl group by the Williamson etherification method;
4) A method of reacting an organic compound having a halocarbonyl group and an acidic group protected by a protecting group with carbon black having a hydroxyl group; and
5) A method of performing a Friedel-Crafts reaction on carbon black using an organic compound having a halocarbonyl group and an acidic group protected by a protecting group, followed by deprotection.

Among these methods, the method 2), allowing easy and safe introduction of an acidic group, is preferred. As the organic compound having an amino group and an acidic group used in the method 2), a compound in which an amino group and an acidic group are bound to an aromatic group is preferred. As such a compound, aminobenzenesulfonic acid such as sulfanilic acid and aminobenzoic acid such as 4-aminobenzoic acid can be exemplified.

A molar number of the acidic group to be introduced into the carbon black is not particularly limited as long as it does not interfere with the objective of the present invention. A molar number of the acidic group to be introduced to the carbon black is preferably 1 mmol or more and 200 mmol or less, and more preferably 5 mmol or more and 100 mmol or less, based on 100 g of carbon black.

Carbon black having an acidic group introduced thereinto may be subjected to a coating treatment with a resin. When using a photosensitive resin composition containing carbon black coated with a resin, it is easy to form a light shielding cured film with excellent light shielding properties and insulation properties, and low surface reflectivity. The coating treatment with a resin does not exert an adverse influence particularly on a dielectric constant of a light shielding cured film formed by using the resin composition. Examples of the resin, which can be used for coating carbon black, include thermosetting resins such as a phenol resin, a melamine resin, a xylene resin, a diallyl phthalate resin, a glyptal resin, an epoxy resin, and an alkylbenzene resin, and thermoplastic resins such as polystyrene, polycarbonate, polyethylene terephthalate, polybutylene terephthalate, modified polyphenylene oxide, polysulfone, polyparaphenyleneterephthalamide, polyamideimide, polyimide, polyaminobismaleimide, polyether sulfopolyphenylene sulfone, polyarylate, and polyether ether ketone. The amount of the resin, with which carbon black is coated, is preferably 1% by mass or more and 30% by mass or less, based on the total mass of carbon black and the resin.

To satisfactorily disperse carbon black in the photosensitive resin composition and to form a cured film having low transmittance of light having a wide wavelength region, a volume average particle diameter of carbon black is preferably 10 nm or more and 1,000 nm or less, more preferably 10 nm or more and 500 nm or less, and particularly preferably 10 nm or more and 300 nm or less. When the volume particle diameter of carbon black is in the above range, it is easy to stably form a cured film having a smooth surface with low arithmetic average roughness Ra.

Examples of the inorganic black pigment include various types of pigments irrespective of whether it is an organic substance or an inorganic substance, such as fine particles containing a silver-tin (AgSn) alloy as a main component, titanium black, metal oxides, composite oxides, metal sulfides, metal sulfates, and metal carbonates of copper, iron, manganese, cobalt, chromium, nickel, zinc, calcium, silver, or the like. Among these inorganic black pigments, fine particles containing a silver-tin (AgSn) alloy as a main component are preferable since it is easily available and is easy to form a cured film having excellent light shielding properties. Color hue of the black pigment is not limited to black which is an achromatic color from the chromatic point of view, and may be purplish black, bluish black, or reddish black.

Fine particles containing a silver-tin (AgSn) alloy as a main component (hereinafter referred to as “AgSn alloy fine particles”) only need to contain an AgSn alloy as a main component, and also may contain Ni, Pd, Au, and the like as other metal components. A volume average particle diameter of the AgSn alloy fine particles is preferably 1 nm or more and 300 nm or less.

When the AgSn alloy is represented by the chemical formula AgxSn, a chemically stable AgSn alloy is obtained if x satisfies the inequality expression: 1≤x≤10, and the chemical stability and blackness are simultaneously obtained if x satisfies the inequality expression: 3≤x≤4. When a mass ratio of Ag in an AgSn alloy is determined in the above range of x, the following relations:

when x=1, Ag/AgSn=0.4762
when x=3, 3.Ag/Ag₃Sn=0.7317
when x=4, 4.Ag/Ag₄Sn=0.7843
when x=10, 10.Ag/Ag₁₀Sn=0.9008
are obtained. Therefore, this AgSn alloy becomes chemically stable when containing 47.6% by mass or more and 90% by mass or less of Ag, and it is possible to obtain the chemical stability and blackness effectively to the amount of Ag when containing 73.17% by mass or more and 78.43% by mass or less of Ag.

The AgSn alloy fine particles can be fabricated using a usual fine particle synthesis method. Examples of fine particle synthesis method include a gas phase reaction method, an atomized pyrolysis method, an atomizing method, a liquid phase reaction method, a freeze-drying method, a hydrothermal method, and the like.

Although AgSn alloy fine particles have high insulation properties, a surface thereof may be covered with an insulation film so as to further enhance insulation properties of a cured film. The material of the insulation film is suitably metal oxide or an organic polymer compound. It is possible to suitably use, as the metal oxide, metal oxides with insulation properties, for example, silicon oxide (silica), aluminum oxide (alumina), zirconium oxide (zirconia), yttrium oxide (yttria), titanium oxide (titania), and the like. It is also possible to suitably use, as the organic polymer compound, resins with insulation properties, for example, polyimide, polyether, polyacrylate, polyamine compound, and the like.

To sufficiently enhance insulation properties of a surface of AgSn alloy fine particles, a thickness of the insulation film is preferably 1 nm or more and 100 nm or less, and more preferably 5 nm or more and 50 nm or less. The insulation film can easily be formed by surface modification technique or surface coating technique. Particularly, when using an alkoxide such as tetraethoxysilane or aluminum triethoxide, an insulation film with a uniform thickness can be formed at comparatively low temperature, preferably.

### ((D2) Organic Pigment)

Color hue of (D2) an organic pigment is not particularly limited as long as entire color hue of (D) a coloring agent is black. It is possible to use, as (D2) the organic pigment, not only a black organic pigment, but also pigments with chromatic colors such as red, blue, yellow, and green hues, and the black organic pigment is preferred.

Suitable examples of the black organic pigment include (D2a) a perylene-based pigment and (D2b) a lactam-based pigment. These pigments may be used in combination of two or more types thereof.

The (D2a) perylene-based pigment is not particularly limited as long as it is a pigment composed of a compound having a perylene skeleton and exhibits black. Specific examples of the (D2a) perylene-based pigment include a perylene-based pigment represented by the following formula (d-1), a perylene-based pigment represented by the following formula (d-2), and a perylene-based pigment represented by the following formula (d-3). It is possible to preferably use, as the (D2a) perylene-based pigment, commercially available products, for example, K0084 and K0086 (product name) manufactured by BASF Corporation, and Pigment Black 21, 30, 31, 32, 33, and 34.

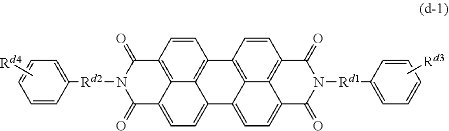

In the formula (d-1), R^{d1} and R^{d2} each independently represent an alkylene group having 1 or more and 3 or less carbon atoms, and R^{d3} and R^{d4} each independently represent a hydrogen atom, a hydroxyl group, a methoxy group, or an acetyl group.

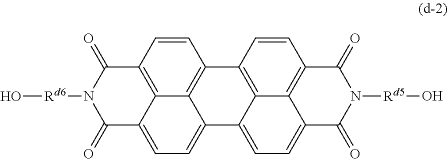

In the formula (d-2), R^{d5} and R^{d6} each independently represent an alkylene group having 1 or more and 7 or less carbon atoms.

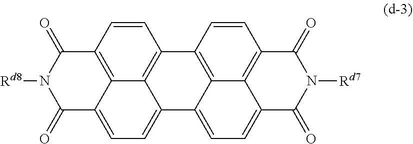

In the formula (d-3), R^{d7} and R^{d8} each independently represent a hydrogen atom, an alkyl group having 1 or more and 22 or less carbon atoms, and may contain a heteroatom of N, O, S, or P. When R^{d7} and R^{d8} are alkyl groups, the alkyl group may be either a straight-chain or branched-chain alkyl group.

The compound represented by the formula (d-1), the compound represented by the formula (d-2), the compound represented by the formula (d-3) can be synthesized by using the method mentioned, for example, in Japanese Unexamined Patent Application Publication No. 62-1753 and Japanese Examined Patent Application Publication No. 63-26784. Using perylene-3,5,9,10-tetracarboxylic acid or a dianhydride thereof and amines as raw materials, a heating reaction is performed in water or an organic solvent. The thus obtained crude product is reprecipitated in sulfuric acid, or recrystallized in water, an organic solvent, or a mixed solvent thereof, thus making it possible to obtain an objective substance.

To satisfactorily disperse a (D2a) perylene-based pigment in the photosensitive resin composition and to form a cured film having low transmittance of light having a wide wavelength region, a volume average particle diameter of the perylene-based pigment is preferably 10 nm or more and 1,000 nm or less, more preferably 10 nm or more and 500 nm or less, and particularly preferably 10 nm or more and 200 nm or less. When the volume particle diameter of the perylene-based pigment is in the above range, it is easy to stably form a cured film having a smooth surface with low arithmetic average roughness Ra.

The (D2b) lactam-based pigment includes, for example, a compound represented by the following formula (d-4).

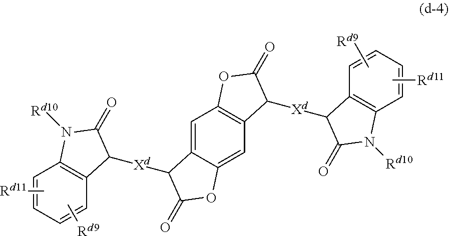

In the formula (d-4), X^{d} represents a double bond, E form or Z form each independently exists as a geometrical isomer, R^{d9}(s) each independently represent a hydrogen atom, a methyl group, a nitro group, a methoxy group, a bromine atom, a chlorine atom, a fluorine atom, a carboxy group, or a sulfo group, R^{d10}(s) each independently represent a hydrogen atom, a methyl group, or a phenyl group, and R^{d11}(s) each independently represent a hydrogen atom, a methyl group, or a chlorine atom. Compounds represented by the formula (d-4) can be used alone or used in combination of two or more types thereof. R^{d9} is preferably bonded at the 6-position of a dihydroindolone ring in view of easily producing a compound represented by the formula (d-4), and R^{d11} is preferably bonded at the 4-position of a dihydroindolone ring. From the same viewpoint, R^{d9}, R^{d10}, and R^{d11} are preferably hydrogen atoms. The compound represented by the formula (d-4) includes, as geometrical isomers, EE form, ZZ form, and EZ form, and may be either a single compound of any one of them, or a mixture of these geometrical isomers. The compound represented by the formula (d-4) can be produced, for example, by the methods mentioned in WO 2000/24736 A1 and WO 2010/081624 A1.

To satisfactorily disperse a lactam-based pigment in the photosensitive resin composition, volume average particle diameter of the lactam-based pigment is preferably 10 nm or more and 1,000 nm or less.

For the purpose of adjusting color tone, a (D) coloring agent may contain colors with purple, red, orange, yellow, and green hues. It is possible to appropriately select colors with other hues of black pigments from known colors. The amount of colors with other hues of black pigments to be used is preferably 15% by mass or less, more preferably 10% by mass or less, and preferably 1% by mass or more, based on the total mass of the black pigment.

To uniformly disperse the above-described (D) coloring agent in the photosensitive resin composition, a dispersant can be further used. It is preferred to use, as the dispersant, a polyethyleneimine-based, a urethane resin-based, and an acrylic resin-based polymer dispersants. Particularly, when carbon black is dispersed, it is preferred to use, as the dispersant, an acrylic resin-based dispersant and a urethane rein-based dispersant. A corrosive gas due to the dispersant may generate from the cured film. Therefore, it is an example of preferred aspect that the (D) coloring agent is subjected to a dispersion treatment without using the dispersant.

In the photosensitive resin composition, a pigment may be used in combination with a dye as the (D) coloring agent. This dye is appropriately selected from known materials. Examples of the dye applicable to the resin composition include an azo dye, a metal complex salt azo dye, an anthraquinone dye, a triphenylmethane dye, a xanthene dye, a cyanine dye, a naphthoquinone dye, a quinoneimine dye, a methine dye, a phthalocyanine dye, and the like. These dyes can also be used as the (D) coloring agent after dispersing in an organic solvent by laking (salification). It is also possible to preferably use, in addition to these dyes, dyes mentioned in Japanese Unexamined Patent Application Publication No. 2013-225132, Japanese Unexamined Patent Application Publication No. 2014-178477, Japanese Unexamined Patent Application Publication No. 2013-137543, Japanese Unexamined Patent Application Publication No. 2011-38085, Japanese Unexamined Patent Application Publication No. 2014-197206, and the like.

The total content of the (D) coloring agent in photosensitive resin composition can be appropriately selected as long as it does not interfere with the objective of the present invention. Typically, the total content is preferably 90% by mass or less, preferably 10% by mass or more and 85% by mass or less, more preferably 15% by mass or more and 80% by mass or less, and still more preferably 20% by mass or more and 70% by mass or less, based on the mass of the total solid component of the photosensitive resin composition. As long as a cured film having sufficiently high light shielding properties can be formed using the photosensitive resin composition, the upper limit of the total content of the (D) coloring agent may be 50% by mass or less, 45% by mass or less, or 40% by mass or less, based on the mass of the total solid component of the photosensitive resin composition.

The total content of the mass of the (D1) carbon black and/or the inorganic black pigment and the mass of the (D2) organic pigment in the total mass of the (D) coloring agent is preferably 70% by mass or more, more preferably 80% by mass or more, still more preferably 90% by mass or more, particularly preferably 95% by mass or more, and most preferably 100% by mass.

There is no particular limitation on the content of the mass of the (D1) carbon black and/or the inorganic black pigment and the content of the mass of the (D2) organic pigment based on the mass of the (D) coloring agent as long as they do not interfere with the objective of the present invention. The content of the mass of the (D1) carbon black and/or the inorganic black pigment based on the mass of the (D) coloring agent is preferably 30% by mass or more and 65% by mass or less, more preferably 35% by mass or more and 60% by mass or less, and particularly preferably 40% by mass or more and 55% by mass or less. The content of the mass of the (D2) organic pigment based on the mass of the (D) coloring agent is preferably 10% by mass or more and 70% by mass or less, more preferably 20% by mass or more and 70% by mass or less, and particularly preferably 30% by mass or more and 60% by mass or less. By using the (D1) carbon black and/or the inorganic black pigment in combination with the (D2) organic pigment in the ratio mentioned above, it is particularly easy to achieve both formation of a cured film excellent in light shielding properties and satisfactory curing of a coating film by baking at low temperature.

The (D) coloring agent is preferably added to the photosensitive resin composition after forming a dispersion prepared by dispersing in an appropriate concentration in the presence or absence of a dispersant. Each pigment to be used as the (D) coloring agent may be dispersed in a state of being mixed, or may be added to a resin composition in a state of being individually dispersed. In view of an advantage capable of dispersing each pigment under optimum conditions, each pigment is preferably added to a resin composition in a state of being individually dispersed. In the present specification, the amount of the above-mentioned (D) coloring agent used can be defined as the value which also includes this existing dispersant.

### <(E) Thermosetting Compound>

The photosensitive resin composition contains (E) a thermosetting compound. When the photosensitive resin composition contains the above-mentioned (B) photopolymerizable compound and (C) photopolymerization initiator, and the (D) coloring agent and (E) thermosetting compound which satisfy predetermined conditions, it is easy to perform satisfactory curing of the photosensitive resin composition at low temperature.

It is possible to use, as the (E) thermosetting compound, various thermosetting compounds which have conventionally been blended in the photosensitive resin composition. If necessary, the (E) thermosetting compound and a curing agent corresponding to the type of the (E) thermosetting compound may also be contained. When using the curing agent, in view of the long-term stability of the photosensitive resin composition, it is preferred to use a latent curing agent capable of producing an action as the curing agent by baking.

Typical examples of the (E) thermosetting compound include an isocyanate compound, a melamine compound, an oxetane compound, an epoxy compound, and the like. Among these compounds, an epoxy compound and an oxetane compound are preferable, and an epoxy compound is more preferable, because of satisfactory curability thereof.

The epoxy compound is preferably (E1) a polyfunctional epoxy compound since dense crosslinking can be performed in a cured article of the photosensitive resin composition. Here, the (E1) polyfunctional epoxy compound is an epoxy compound having two or more epoxy groups in a molecule. When the photosensitive resin composition contains, as the (E) thermosetting compound, the (E1) polyfunctional epoxy compound, it is easy to form a cured film which exhibits satisfactory adhesion to a substrate, solvent resistance, heat resistance, and the like.

Examples of the commonly used epoxy compound include difunctional epoxy resins such as a bisphenol A type epoxy resin, a bisphenol F type epoxy resin, a bisphenol S type epoxy resin, a bisphenol AD type epoxy resin, a naphthalene type epoxy resin, and a biphenyl type epoxy resin; epoxy group-containing fluorene compounds such as 9,9-bis[4-(glycidyloxy)phenyl]-9H-fluorene, 9,9-bis[4-[2-(glycidyloxy)ethoxy]phenyl]-9H-fluorene, 9,9-bis[4-[2-(glycidyloxy)ethyl]phenyl]-9H-fluorene, 9,9-bis[4-(glycidyloxy)-3-methylphenyl]-9H-fluorene, 9,9-bis[4-(glycidyloxy)-3,5-dimethylphenyl]-9H-fluorene, and 9,9-bis(6-glycidyloxynaphthalen-2-yl)-9H-fluorene; glycidyl amine type epoxy resins such as tetraglycidyl aminodiphenylmethane, triglycidyl-p-aminophenol, tetraglycidyl metaxylylenediamine, and tetraglycidyl bisaminomethylcyclohexane; trifunctional type epoxy resins such as phloroglucinol triglycidyl ether, trihydroxybiphenyl triglycidyl ether, trihydroxyphenylmethane triglycidyl ether, 2-[4-(2,3-epoxypropoxy)phenyl]-2-[4-[1,1-bis[4-(2,3-epoxypropoxy)phenyl]ethyl]phenyl]propane, and 1,3-bis[4-[1-[4-(2,3-epoxypropoxy)phenyl]-1-[4-[1-[4-(2,3-epoxypropoxy)phenyl]-1-methylethyl]phenyl]ethyl]phenoxy]-2-propanol; tetrafunctional type epoxy resins such as tetrahydroxyphenylethane tetraglycidyl ether, tetraglycidyl benzophenone, bisresorcinol tetraglycidyl ether, and tetraglycidoxybiphenyl; and a 1,2-epoxy-4-(2-oxiranyl) cyclohexane adduct of 2,2-bis(hydroxymethyl)-1-butanol. A 1,2-epoxy-4-(2-oxiranyl)cyclohexane adduct of 2,2-bis(hydroxymethyl)-1-butanol is commercially available as EHPE-3150 (manufactured by Daicel Corporation).

It is also possible to preferably use an oligomer or polymer type polyfunctional epoxy compound as the epoxy compound. Typical examples thereof include a phenol novolak type epoxy compound, a brominated phenol novolak type epoxy compound, an orthocresol novolak type epoxy compound, a xylenol novolak type epoxy compound, a naphthol novolak type epoxy compound, a bisphenol A novolak type epoxy compound, a bisphenol AD novolak type epoxy compound, an epoxidized product of a dicyclopentadiene type phenol resin, an epoxidized product of a naphthalene type phenol resin, and the like.

A compound represented by the following formula (e1) can also be exemplified as a preferable example of the oligomer or polymer type polyfunctional epoxy compound.

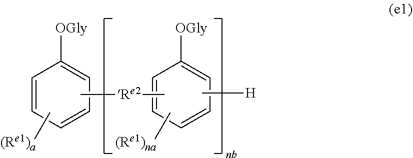

(In the formula (e1), OGly is a glycidyloxy group, R^{e1} is a halogen atom or a monovalent group having 1 to 8 carbon atoms, na is an integer of 0 or more and 4 or less, nb is a repetition number of a constituent unit in parenthesis, and when a is an integer of 2 or more, two R^{e1}s adjacent on a benzene ring may be bonded to each other to form a ring, R^{e2} is a divalent aliphatic cyclic group or a group represented by the following formula (e1-1):

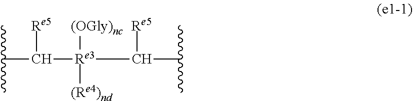

in the formula (e1-1), OGly is a glycidyloxy group, R^{e3} is an aromatic hydrocarbon group, R^{e4} is a halogen atom, or an alkyl group having 1 or more and 4 or less carbon atoms, nc is 0 or 1, nd is an integer of 0 or more and 8 or less, R^{e5} is a hydrogen atom, or a group represented by the following formula (e1-2):

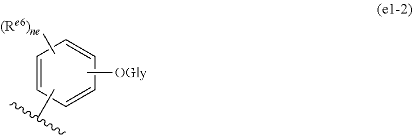

in the formula (e1-2), OGly is a glycidyloxy group, R^{e6} is a halogen atom, an alkyl group having 1 or more and 4 or less carbon atoms, or a phenyl group, and ne is an integer of 0 or more and 4 or less.)

It is preferred that the epoxy compound represented by the above formula (e1) has an average molecular weight of 800 or more. By using, as the epoxy compound represented by the formula (e1), such compound having an average molecular weight, it is easy to form a cured film excellent in water resistance and strength. An average molecular weight of the epoxy compound represented by the formula (e1) is preferably 1,000 or more, more preferably 1,200 or more, and particularly preferably 1,500 or more. The average molecular weight of the epoxy compound represented by the formula (e1) is preferably 50,000 or less, and more preferably 20,000 or less.

In the formula (e1), R^{e1} is a halogen atom or a monovalent group having 1 or more and 8 or less carbon atoms. Specific examples of the monovalent group having 1 or more and 8 or less carbon atoms include an alkyl group, an alkoxy group, a phenoxy group, an aliphatic acyl group, an aliphatic acyloxy group, a benzoyl group, a benzyl group, a phenethyl group, and an unsaturated aliphatic hydrocarbon group. The alkyl group, the alkoxy group, the aliphatic acyl group, the aliphatic acyloxy group, and the unsaturated aliphatic hydrocarbon group may be straight-chain or branched-chain.

Suitable examples of the halogen atom as R^{e1} include a fluorine atom, a chlorine atom, a bromine atom, and an iodine atom. Suitable examples of the alkyl group as R^{e1} are preferably a methyl group, an ethyl group, an n-propyl group, an isopropyl group, an n-butyl group, an isobutyl group, a sec-butyl group, and a tert-butyl group, and more preferably a methyl group and an ethyl group.

When R^{e1} is a monovalent group having 1 or more and 8 or less carbon atoms, the monovalent group is preferably an alkyl group and an alkoxy group. Specific examples of the alkyl group include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, and a 2-ethylhexyl group. Specific examples of the alkoxy group include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an n-hexyloxy group, an n-heptyloxy group, an n-octyloxy group, and a 2-ethylhexyloxy group.

When na is an integer of 2 or more and 4 or less, among plural R^{e1}s, two R^{e1}s adjacent on a benzene ring may be bonded to each other to form a ring. The ring formed by bonding two R^{e1}s may be an aromatic ring, an aliphatic ring, a hydrocarbon ring, or a heterocyclic ring. When the ring formed by bonding two R^{e1}s is a heterocyclic ring, examples of the heteroatom included in the ring include N, O, S, and Se. Suitable examples of the group which is formed together with the benzene ring by bonding two R^{e1}s include a naphthalene ring and a tetralin ring.

In the formula (e1), the divalent aliphatic cyclic group as R^{e2} is not particularly limited and may be a dicyclic or higher polycyclic group of a monocyclic group. Usually, the divalent aliphatic cyclic group has no epoxy group in a structure thereof, and preferably has no epoxy group. Specific examples of the divalent aliphatic cyclic group include groups in which two hydrogen atoms are eliminated from monocycloalkane, and polycycloalkanes such as bicycloalkane, tricycloalkane, and tetracycloalkane. More specific examples thereof include groups in which two hydrogen atoms are eliminated from monocycloalkanes such as cyclopentane and cyclohexane, and polycycloalkanes such as adamantane, norbornane, isobornane, tricyclodecane, and tetracyclododecane. The number of carbon atoms of the divalent aliphatic cyclic group is preferably 3 or more and 50 or less, more preferably 3 or more and 30 or less, particularly preferably 3 or more and 20 or less, and most preferably 3 or more and 15 or less.

Specific examples of the divalent aliphatic cyclic group as R^{e2} include groups shown below.

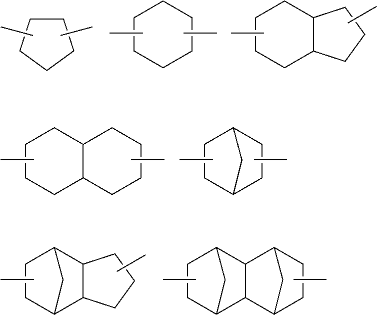

R^{e3} is an aromatic hydrocarbon group. A valence of the aromatic hydrocarbon group as R^{e3} is 2+nc+nd. There is no particular limitation on the aromatic hydrocarbon group. An aromatic hydrocarbon ring constituting the aromatic hydrocarbon group is typically a 6-membered aromatic hydrocarbon ring (benzene ring) or a ring in which two or more benzene rings are fused each other, or bonded via a single ring. Suitable specific examples of the aromatic hydrocarbon ring constituting the aromatic hydrocarbon group include benzene, naphthalene, anthracene, phenanthrene, biphenyl, and terphenyl. A group in which 2+nc+nd hydrogen atoms are eliminated from these aromatic hydrocarbon rings is suitable as an aromatic hydrocarbon group as R^{e3}.

In the group represented by the formula (e1-1), nc is 0 or 1. Namely, no glycidyloxy group may be bonded to R^{e3} which is an aromatic hydrocarbon group, or one glycidyloxy group may be bonded thereto.

In the group represented by the formula (e1-1), R^{e4} is a halogen atom or an alkyl group having 1 or more and 4 or less carbon atoms, and d is an integer of 0 or more and 8 or less. Namely, R^{e4} is a substituent other than a glycidyloxy group on R^{e3} as an aromatic hydrocarbon group, and the number of substituents on R^{e3} is 0 or more and 8 or less. nd is preferably an integer of 0 or more and 4 or less, more preferably an integer of 0 or more and 2 or less, and particularly preferably 0 or 1. Suitable examples of the halogen atom as R^{e4} include a fluorine atom, a chlorine atom, a bromine atom, and an iodine atom. Suitable examples of the alkyl group as R^{e4} are preferably a methyl group, an ethyl group, an n-propyl group, an isopropyl group, an n-butyl group, an isobutyl group, a sec-butyl group, and a tert-butyl group, and more preferably a methyl group and an ethyl group.

In the group represented by the formula (e1-1), R^{e5} is a hydrogen atom, or a group represented by the above-mentioned formula (e1-2). R^{e6} in the formula (e1-2) is a halogen atom, an alkyl group having 1 or more and 4 or less carbon atoms, or a phenyl group. Specific examples of the halogen atom and the alkyl group having 1 or more and 4 or less carbon atoms are the same as those in R^{e4}.

Regarding the above-described epoxy compound represented by the formula (e1), it is preferred that R^{e2} is a divalent aliphatic cyclic group or the above-mentioned divalent group represented by the formula (e1-1), nc is 0, and R^{e5} is a hydrogen atom. In this case, when appropriate distance exists between plural epoxy groups contained in the epoxy compound represented by the formula (e1), it is easier to form a cured article with satisfactory water resistance.

The epoxy compound represented by the formula (e1) is obtained as commercially available products. Specific examples of the commercially available product include NC-Series, XD-Series and the like manufactured by Nippon Kayaku Co., Ltd. Equivalent products having a specific structure are also available from DIC Corporation and SHOWA DENKO K.K.

Suitable specific examples of a chemical structure of the epoxy compound represented by the formula (e1) are shown below. In the following formula, OGly represents a glycidyloxy group and p represents a repetition number of a constituent unit in parenthesis.

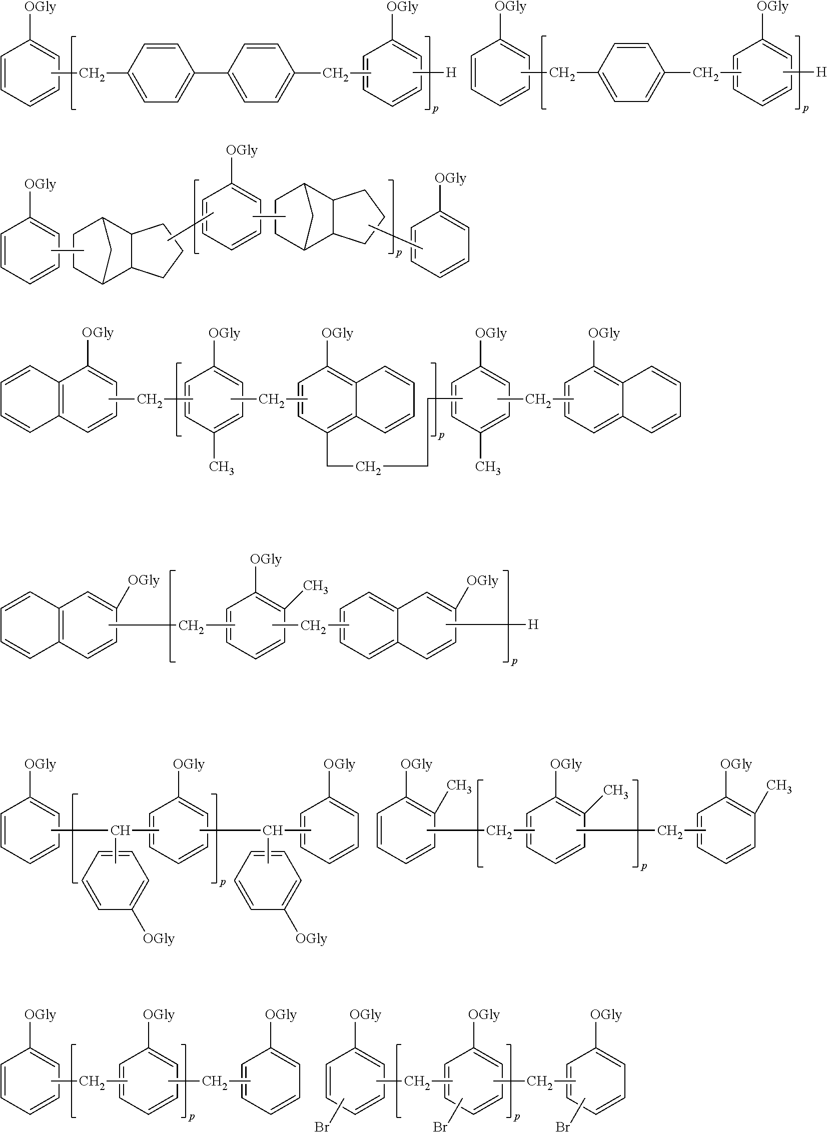

As other examples of suitable epoxy compound, a polyfunctional alicyclic epoxy compound having alicyclic epoxy groups is exemplified. Specific examples of the alicyclic epoxy compound include 2-(3,4-epoxycyclohexyl-5,5-spiro-3,4-epoxy)cyclohexane-meta-dioxane, bis(3,4-epoxycyclohexylmethyl)adipate, bis(3,4-epoxy-6-methylcyclohexylmethyl)adipate, 3,4-epoxy-6-methylcyclohexyl-3′,4′-epoxy-6′-methylcyclohexane carboxylate, s-caprolactone-modified 3,4-epoxycyclohexylmethyl-3′,4′-epoxycyclohexane carboxylate, trimethylcaprolactone-modified 3,4-epoxycyclohexylmethyl-3′,4′-epoxycyclohexane carboxylate, β-methyl-5-valerolactone-modified 3,4-epoxycyclohexylmethyl-3′,4′-epoxycyclohexane carboxylate, methylenebis(3,4-epoxycyclohexane), di(3,4-epoxycyclohexylmethyl)ether of ethylene glycol, ethylenebis(3,4-epoxycyclohexane carboxylate), a polyfunctional epoxy resin compound having a tricyclodecene oxide group, and a compound represented by the following formulas (E1-1) to (E1-5). These alicyclic epoxy compounds can be used alone, or two or more alicyclic epoxy compounds can be used as a mixture.

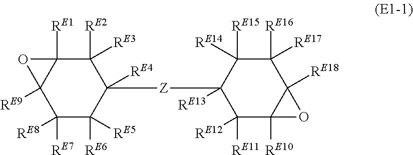

In the formula (E1-1), Z is a single bond, or a linking group (divalent group having one or more atoms). R^{E1} to R^{E18} are each independently a group selected from the group consisting of a hydrogen atom, a halogen atom and an organic group.

Example of linking group Z includes a divalent group selected form the group consisting of a divalent hydrocarbon group, —O—, —O—CO—, —S—, —SO—, —SO₂—, —CBr₂—, —C(CBr₃)₂—, —C(CF₃)₂—, and —R^{E19}—O—CO— or a group formed by bonding plural of these divalent groups.

When the linking group Z is a divalent hydrocarbon group, example of the hydrocarbon group includes a straight-chain or branched-chain alkylene group having 1 or more and 18 or less carbon atoms, a divalent alicyclic hydrocarbon group, and the like. The straight-chain or branched-chain alkylene group having 1 or more and 18 or less carbon atoms includes, for example, a methylene group, a methylmethylene group, a dimethylmethylene group, a dimethylene group, a trimethylene group, and the like. Above-mentioned divalent alicyclic hydrocarbon group includes, for example, a cycloalkylene group (including a cyclohexylidene group) such as a 1,2-cyclopentylene group, a 1,3-cyclopentylene group, a cyclopentylidene group, a 1,2-cyclohexylene group, 1,3-cyclohexylene group, 1,4-cyclohexylene group, and a cyclohexylidene group.

R^{E19} is an alkylene group having 1 or more and 8 or less carbon atoms, and preferably a methylene group or an ethylene group.

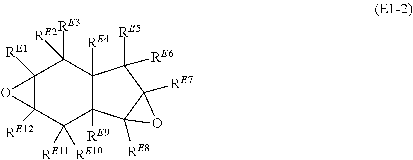

In the formula (E1-2), R^{E1} to R^{E12} each independently represent a group selected from the group consisting of a hydrogen atom, a halogen atom, and an organic group.

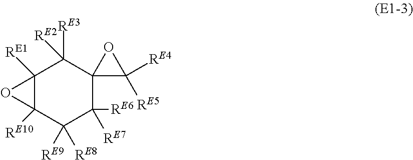

In the formula (E1-3), R^{E1} to R^{E10} each independently represent a group selected from the group consisting of a hydrogen atom, a halogen atom, and an organic group. R^{E2} and R^{E8} may be combined to each other.

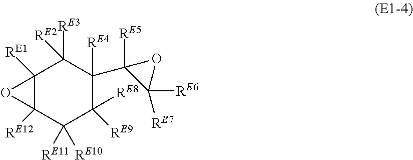

In the formula (E1-4), R^{E1} to R^{E12} each independently represent a group selected from the group consisting of a hydrogen atom, a halogen atom, and an organic group. R^{E2} and R^{E10} may be combined to each other.

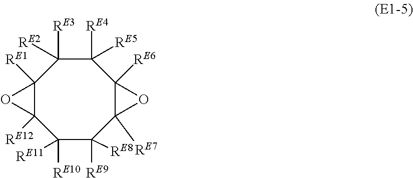

In the formula (E1-5), R^{E1} to R^{E12} each independently represent a group selected from the group consisting of a hydrogen atom, a halogen atom, and an organic group.

In the formulas (E1-1) to (E1-5), when R^{E1} to R^{E18} are organic groups, the organic group is not particularly limited as long as the object of the present invention is not impaired, and may be a hydrocarbon group, or a group consisting of a carbon atom and a halogen atom, or a group having heteroatoms such as a halogen atom, an oxygen atom, a sulfur atom, a nitrogen atom, and a silicon atom, together with a carbon atom and a hydrogen atom. Examples of the halogen atom include a chlorine atom, a bromine atom, an iodine atom, and a fluorine atom.

The organic group is preferably a group consisting of a hydrocarbon group, a group consisting of a carbon atom, a hydrogen atom, and an oxygen atom; a halogenated hydrocarbon group, a group consisting of a carbon atom, an oxygen atom, and a halogen atom; and a group consisting of a carbon atom, a hydrogen atom, an oxygen atom, and a halogen atom. When the organic group is a hydrocarbon group, the hydrocarbon group may be an aromatic hydrocarbon group, or an aliphatic hydrocarbon group, or a group including an aromatic skeleton and an aliphatic skeleton. The number of carbon atoms of the organic group is preferably 1 or more and 20 or less, more preferably 1 or more and 10 or less, and particularly preferably 1 or more and 5 or less.

Specific examples of the hydrocarbon group include chain alkyl groups such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethylhexyl group, an n-nonyl group, an n-decyl group, an n-undecyl group, an n-tridecyl group, an n-tetradecyl group, an n-pentadecyl group, an n-hexadecyl group, an n-heptadecyl group, an n-octadecyl group, an n-nonadecyl group, and an n-icosyl group; chain alkenyl groups such as a vinyl group, a 1-propenyl group, a 2-n-propenyl group (allyl group), a 1-n-butenyl group, a 2-n-butenyl group, and a 3-n-butenyl group; cycloalkyl groups such as a cyclopropyl group, a cyclobutyl group, a cyclopentyl group, a cyclohexyl group, and a cycloheptyl group; aryl groups such as a phenyl group, an o-tolyl group, an m-tolyl group, a p-tolyl group, an a-naphthyl group, a β-naphthyl group, a biphenyl-4-yl group, a biphenyl-3-yl group, a biphenyl-2-yl group, an anthryl group, and a phenanthryl group; and aralkyl groups such as a benzyl group, a phenethyl group, an α-naphthylmethyl group, a β-naphthylmethyl group, an α-naphthylethyl group, and a β-naphthylethyl group.

Specific examples of the halogenated hydrocarbon group include halogenated chain alkyl groups such as a chloromethyl group, a dichloromethyl group, a trichloromethyl group, a bromomethyl group, a dibromomethyl group, a tribromomethyl group, a fluoromethyl group, a difluoromethyl group, a trifluoromethyl group, a 2,2,2-trifluoroethyl group, a pentafluoroethyl group, a heptafluoropropyl group, a perfluorobutyl group, and a perfluoropentyl group, a perfluorohexyl group, a perfluoroheptyl group, a perfluorooctyl group, a perfluorononyl group, and a perfluorodecyl group; halogenated cycloalkyl groups such as a 2-chlorocyclohexyl group, a 3-chlorocyclohexyl group, a 4-chlorocyclohexyl group, a 2,4-dichlorocyclohexyl group, a 2-bromocyclohexyl group, a 3-bromocyclohexyl group, and a 4-bromocyclohexyl group; halogenated aryl groups such as a 2-chlorophenyl group, a 3-chlorophenyl group, a 4-chlorophenyl group, a 2,3-dichlorophenyl group, a 2,4-dichlorophenyl group, a 2,5-dichlorophenyl group, a 2,6-dichlorophenyl group, a 3,4-dichlorophenyl group, a 3,5-dichlorophenyl group, a 2-bromophenyl group, a 3-bromophenyl group, a 4-bromophenyl group, a 2-fluorophenyl group, a 3-fluorophenyl group, and a 4-fluorophenyl group; and halogenated aralkyl groups such as a 2-chlorophenylmethyl group, a 3-chlorophenylmethyl group, a 4-chlorophenylmethyl group, a 2-bromophenylmethyl group, a 3-bromophenylmethyl group, a 4-bromophenylmethyl group, a 2-fluorophenylmethyl group, a 3-fluorophenylmethyl group, and a 4-fluorophenylmethyl group.

Specific examples of the group consisting of a carbon atom, a hydrogen atom, and an oxygen atom include hydroxy chain alkyl groups such as a hydroxymethyl group, a 2-hydroxyethyl group, a 3-hydroxy-n-propyl group, and a 4-hydroxy-n-butyl group; halogenated cycloalkyl groups such as a 2-hydroxycyclohexyl group, a 3-hydroxycyclohexyl group, and a 4-hydroxycyclohexyl group; hydroxyaryl groups such as a 2-hydroxyphenyl group, a 3-hydroxyphenyl group, a 4-hydroxyphenyl group, a 2,3-dihydroxyphenyl group, a 2,4-dihydroxyphenyl group, a 2,5-dihydroxyphenyl group, a 2,6-dihydroxyphenyl group, a 3,4-dihydroxyphenyl group, and a 3,5-dihydroxyphenyl group; hydroxyaralkyl groups such as a 2-hydroxyphenylmethyl group, a 3-hydroxyphenylmethyl group, and a 4-hydroxyphenylmethyl group; chain alkoxy groups such as a methoxy group, an ethoxy group, an n-propoxy group, an isopropoxy group, an n-butyloxy group, an isobutyloxy group, a sec-butyloxy group, a tert-butyloxy group, an n-pentyloxy group, an n-hexyloxy group, an n-heptyloxy group, an n-octyloxy group, a 2-ethylhexyloxy group, an n-nonyloxy group, an n-decyloxy group, an n-undecyloxy group, an n-tridecyloxy group, an n-tetradecyloxy group, an n-pentadecyloxy group, an n-hexadecyloxy group, an n-heptadecyloxy group, an n-octadecyloxy group, an n-nonadecyloxy group, and an n-icosyloxy group; chain alkenyloxy groups such as a vinyloxy group, a 1-propenyloxy group, a 2-n-propenyloxy group (allyloxy group), a 1-n-butenyloxy group, a 2-n-butenyloxy group, and a 3-n-butenyloxy group; aryloxy groups such as a phenoxy group, an o-tolyloxy group, an m-tolyloxy group, a p-tolyloxy group, an α-naphthyloxy group, a β-naphthyloxy group, a biphenyl-4-yloxy group, a biphenyl-3-yloxy group, a biphenyl-2-yloxy group, an anthryloxy group, and a phenanthryloxy group; aralkyloxy groups such as a benzyloxy group, a phenethyloxy group, an α-naphthylmethyloxy group, a β-naphthylmethyloxy group, an α-naphthylethyloxy group, and a β-naphthylethyloxy group; alkoxyalkyl groups such as a methoxymethyl group, an ethoxymethyl group, an n-propoxymethyl group, a 2-methoxyethyl group, a 2-ethoxyethyl group, a 2-n-propoxyethyl group, a 3-methoxy-n-propyl group, a 3-ethoxy-n-propyl group, a 3-n-propoxy-n-propyl group, a 4-methoxy-n-butyl group, a 4-ethoxy-n-butyl group, and a 4-n-propoxy-n-butyl group; alkoxyalkoxy groups such as a methoxymethoxy group, an ethoxymethoxy group, an n-propoxymethoxy group, a 2-methoxyethoxy group, a 2-ethoxyethoxy group, a 2-n-propoxyethoxy group, a 3-methoxy-n-propoxy group, a 3-ethoxy-n-propoxy group, a 3-n-propoxy-n-propoxy group, a 4-methoxy-n-butyloxy group, a 4-ethoxy-n-butyloxy group, and a 4-n-propoxy-n-butyloxy group; alkoxyaryl groups such as a 2-methoxyphenyl group, a 3-methoxyphenyl group, and a 4-methoxyphenyl group; alkoxyaryloxy groups such as a 2-methoxyphenoxy group, a 3-methoxyphenoxy group, and a 4-methoxyphenoxy group; aliphatic acyl groups such as a formyl group, an acetyl group, a propionyl group, a butanoyl group, a pentanoyl group, a hexanoyl group, a heptanoyl group, an octanoyl group, a nonanoyl group, and a decanoyl group; aromatic acyl groups such as a benzoyl group, an α-naphthoyl group, and a β-naphthoyl group; chain alkyloxycarbonyl groups such as a methoxycarbonyl group, an ethoxycarbonyl group, an n-propoxycarbonyl group, an n-butyloxycarbonyl group, an n-pentyloxycarbonyl group, an n-hexylcarbonyl group, an n-heptyloxycarbonyl group, an n-octyloxycarbonyl group, an n-nonyloxycarbonyl group, and an n-decyloxycarbonyl group; aryloxycarbonyl groups such as a phenoxycarbonyl group, an a-naphthoxycarbonyl group, and a β-naphthoxycarbonyl group; aliphatic acyloxy groups such as a formyloxy group, an acetyloxy group, a propionyloxy group, a butanoyloxy group, a pentanoyloxy group, a hexanoyloxy group, a heptanoyloxy group, an octanoyloxy group, a nonanoyloxy group, and a decanoyloxy group; and aromatic acyloxy groups such as a benzoyloxy group, an α-naphthoyloxy group, and a β-naphthoyloxy group.

R^{E1} to R^{E18} are preferably each independently a group selected from the group consisting of a hydrogen atom, a halogen atom, an alkyl group having 1 or more and 5 or less carbon atoms, and an alkoxy group having 1 or more and 5 or less carbon atoms and, particularly, all R^{E1} to R^{E18} are more preferably hydrogen atoms in view of the fact that a cured film obtained by using a curable composition has excellent mechanical properties.

In the formulas (E1-2) to (E1-5), R^{E1} to R^{E12} are the same as R^{E1} to R^{E12} in the formula (E1-1). In the formula (E1-2) and the formula (E1-4), the divalent group formed when R^{E2} and R^{E10} are combined to each other includes, for example, —CH₂— and —C(CH₃)₂—. In the formula (E1-3), the divalent group formed when R^{E2} and R^{E2} are combined to each other includes, for example, —CH₂— and —C(CH₃)₂—.

Specific examples of a suitable compound for the alicyclic epoxy compounds represented by the formula (E1-1) include alicyclic epoxy compounds represented by the following formulas (E1-1a), (E1-1b) and (E1-1c), 2,2-bis(3,4-epoxycyclohexane-1-yl)propane [=2,2-bis(3,4-epoxy-epoxycyclohexyl)propane], and the like.

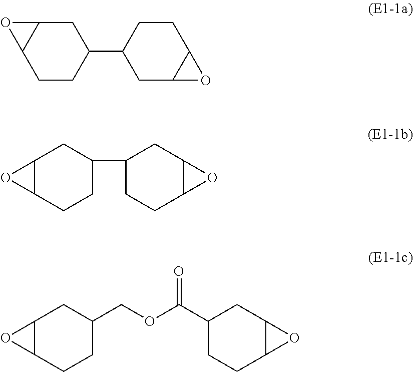 [SMILES: C1CC2OC2CC1C1CCC2OC2C1 ; C1CC2OC2CC1C1CCC2OC2C1 ; O=C(OCC1CCC2OC2C1)C1CCC2OC2C1]

Specific examples of suitable compound for the alicyclic epoxy compounds represented by the formula (E1-2) include bicyclononadiene diepoxide represented by the following formula (E1-2a), or dicyclononadiene diepoxide, and the like.

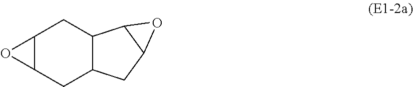 [SMILES: C1C2CC3OC3C2CC2OC12]

Specific examples of suitable compound for the alicyclic epoxy compounds represented by the formula (E1-3) include S-spiro[3-oxatricyclo[3.2.1.0^{2,4}]octane-6,2′-oxirane], and the like.

Specific examples of suitable compound for the alicyclic epoxy compounds represented by the formula (E1-4) include 4-vinylcyclohexene dioxide, dipentene dioxide, limonene dioxide, 1-methyl-4-(3-methyloxirane-2-yl)-7-oxabicyclo[4.1.0]heptane, and the like.

Specific examples of suitable compound for the alicyclic epoxy compounds represented by the formula (E1-5) include 1,2,5,6-diepoxycyclooctane, and the like.

In addition, it is possible to use a compound represented by the following formula (E-1) as the epoxy compound.

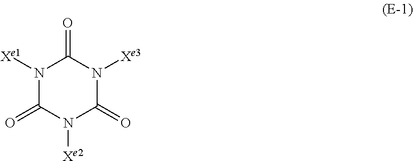

In the formula (E-1), X^{e1}, X^{e2}, and X^{e3} each independently is a hydrogen atom, or an organic group optionally having an epoxy group, and the total number of epoxy groups possessed by X^{e1}, X^{e2}, and X^{e3} is 2 or more and 3 or less.

The above compound represented by the formula (E-1) is preferably a compound represented by the following formula (E1-6).

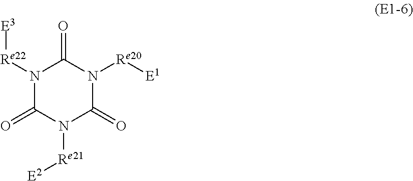

In the formula (E1-6), R^{e20} to R^{e22} are a straight-chain, branched-chain or cyclic alkylene group, an arylene group, —O—, —C(═O)—, —NH—, and combination thereof. R^{e20} to R^{e22} may be the same or different from each other. Each of E¹ to E³ is at least one selected from the group consisting of an epoxy group, an oxetanyl group, an ethylenically unsaturated group, an alkoxysilyl group, an isocyanate group, a blocked isocyanate group, a thiol group, a carboxy group, a hydroxy group, and a succinic acid anhydride group, or a hydrogen atom. However, each of two or more and three or less of E¹ to E³ is one selected from the group consisting of an epoxy group.

In the formula (E1-6), each of at least two of a group represented by R^{En} and E¹, a group represented by R^{E21} and E², and a group represented by R^{E22} and E³ is preferably a group represented by the following formula (E1-6a). It is more preferred that all of these groups are groups represented by the following formula (E1-6a). Plural groups represented by the formula (E1-6a) bonding to one compound are preferably the same group.

-L-C^{a} (E1-6a)

In the formula (E1-6a), L is a straight-chain, branched-chain, or cyclic alkylene group, an arylene group, —O—, —C(═O)—, —NH—, or the combination thereof, and C^{a} is an epoxy group. In the formula (D1-6a), L and C^{a} may bond to one another to form a ring structure.

In the formula (E1-6a), as a straight-chain, branched-chain, or cyclic alkylene group for L, an alkylene group having 1 or more and 10 or less carbon atoms is preferred. Furthermore, as an arylene group for L, an arylene group having 5 or more and 10 or less carbon atoms is preferred. In the formula (E1-6a), L is preferably a straight-chain alkylene group having 1 or more and 3 or less carbon atoms, a phenylene group, —O—, —C(═O)—, —NH—, or the combination thereof, and more preferably a combination of at least one of a phenylene group, and a straight-chain alkylene group having 1 or more and 3 or less carbon atoms such as a methylene group and with at least one of —O—, —C(═O)—, and —NH—.

In the formula (E1-6a), when L and C^{a} bond to one another to form a ring structure, examples of the ring structure include a ring structure formed by bonding of a branched-chain alkylene group and an epoxy group (a structure having an alicyclic epoxy group) and organic groups represented by the following formula (E1-6b) and (E1-6c).

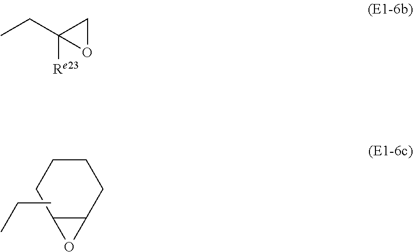

In the formula (E1-6b), R^{e23} is a hydrogen atom or a methyl group.

Hereinafter, an epoxy compound having an oxiranyl group or an alicyclic epoxy group is exemplified as examples of the compound represented by the formula (E1-6), but not limited thereto.

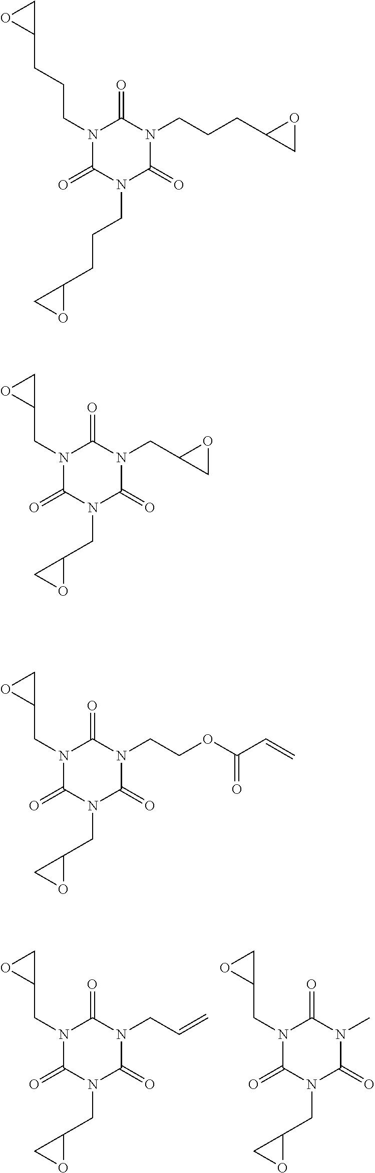

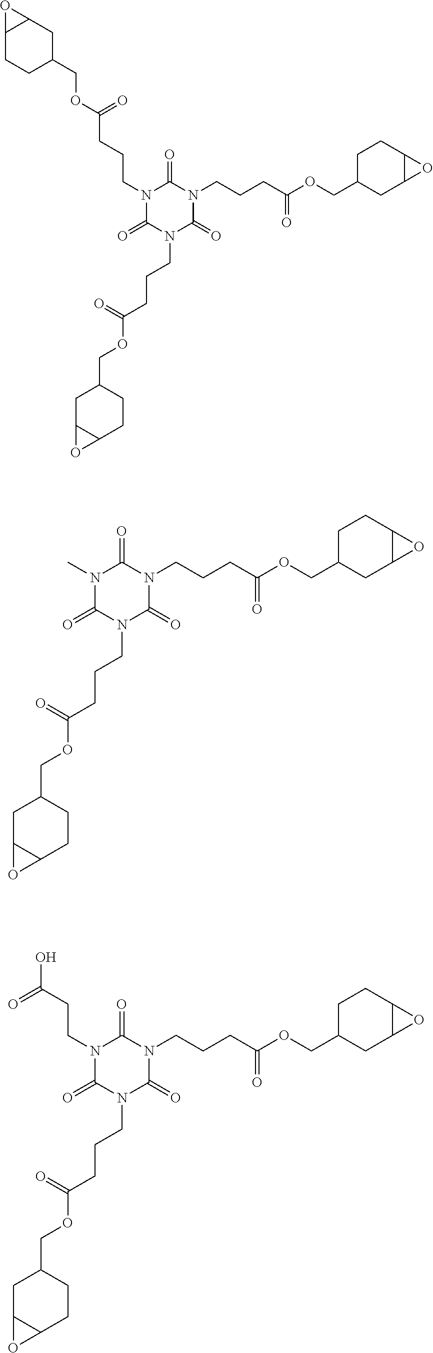 [SMILES: O=C(CCCn1c(=O)n(CCCC(=O)OCC2CCC3OC3C2)c(=O)n(CCCC(=O)OCC2CCC3OC3C2)c1=O)OCC1CCC2OC2C1 ; Cn1c(=O)n(CCCC(=O)OCC2CCC3OC3C2)c(=O)n(CCCC(=O)OCC2CCC3OC3C2)c1=O ; O=C(O)CCn1c(=O)n(CCCC(=O)OCC2CCC3OC3C2)c(=O)n(CCCC(=O)OCC2CCC3OC3C2)c1=O]

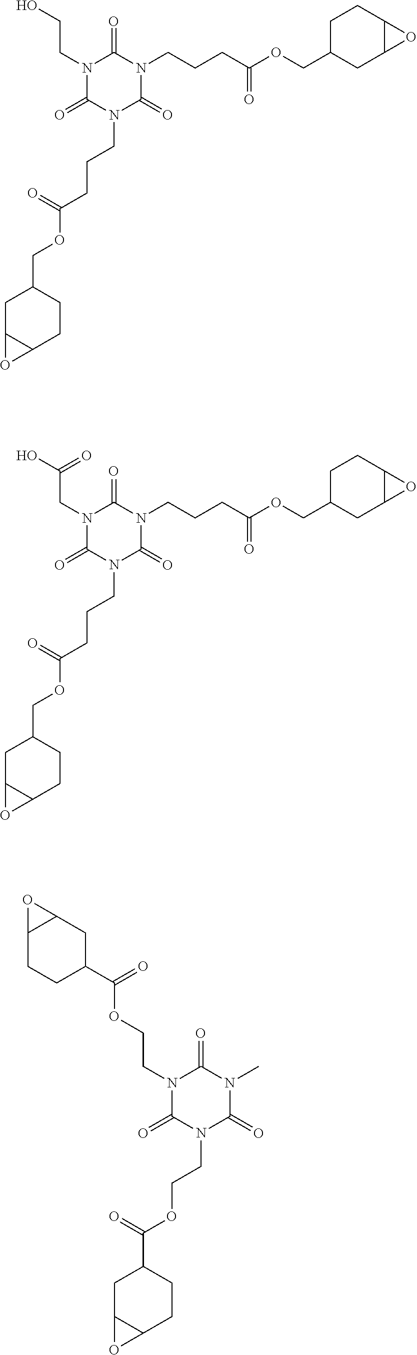 [SMILES: O=C(CCCn1c(=O)n(CCO)c(=O)n(CCCC(=O)OCC2CCC3OC3C2)c1=O)OCC1CCC2OC2C1 ; O=C(O)Cn1c(=O)n(CCCC(=O)OCC2CCC3OC3C2)c(=O)n(CCCC(=O)OCC2CCC3OC3C2)c1=O ; Cn1c(=O)n(CCOC(=O)C2CCC3OC3C2)c(=O)n(CCOC(=O)C2CCC3OC3C2)c1=O]

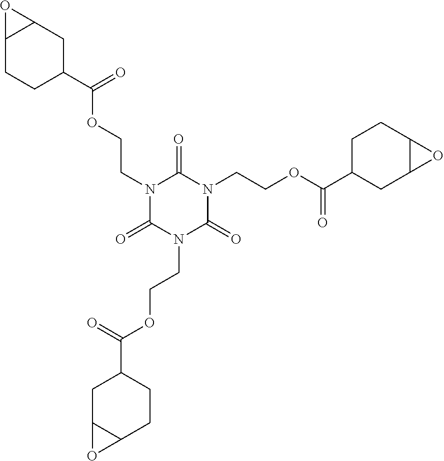 [SMILES: O=C(OCCn1c(=O)n(CCOC(=O)C2CCC3OC3C2)c(=O)n(CCOC(=O)C2CCC3OC3C2)c1=O)C1CCC2OC2C1]

Furthermore, examples of a compound which can preferably be used as the epoxy compound include a siloxane compound having two or more epoxy groups in a molecule (hereinafter also referred to as “siloxane compound”). The upper limit of the number of epoxy groups of the siloxane compound in a molecule is not particularly limited and is, for example, 6 or less.

The siloxane compound is a compound having a siloxane skeleton constituted with siloxane bonds (Si—O—Si) and two or more glycidyl groups in a molecule. The upper limit of the number of glycidyl groups of the siloxane compound in a molecule is not particularly limited and is, for example, 6 or less. Examples of the siloxane skeleton in the siloxane compound include a cyclic siloxane skeleton, a polyhedral or ladder polysilsesquioxane skeleton, and the like.

Among the siloxane compounds, a compound having a cyclic siloxane skeleton represented by the following formula (E1-7) (hereinafter also referred to as “cyclic siloxane”) is preferred.

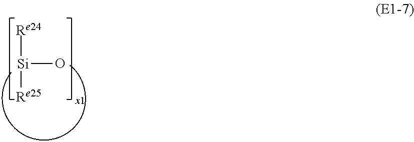

In the formula (E1-7), each of R^{e24} and R^{e25} represent a monovalent group having an epoxy group, or an alkyl group. However, at least two of x1 R^{e24}s and x1 R^{e25}s in the compound represented by the formula (E1-7) are monovalent groups including epoxy groups. Furthermore, x1 in the formula (E1-7) represents an integer of 3 or more. In a compound represented by the formula (E1-7), R^{e24} and R^{e25} may be the same or different. In addition, plural R^{e24}s may be the same or different. Plural R^{e25}s may also be the same or different.

As the above-mentioned monovalent group including an epoxy group, a glycidyl ether group represented by -D-O—R^{e26} [where D represents an alkylene group, and R^{e26} represents a glycidyl group] is preferred. Examples of the above-mentioned D (alkylene group) include a straight-chain or branched-chain alkylene group having 1 or more and 18 or less carbon atoms such as a methylene group, a methylmethylene group, a dimethylmethylene group, a dimethylene group, and a trimethylene group. An alicyclic epoxy group-containing group represented by -D-R^{e27} is also preferred. R^{e27} is an epoxycycloalkyl group. As mentioned above, D is an alkylene group. Preferred examples of the alkylene group as D are as mentioned above. The epoxycycloalkyl group as R^{e27} is preferably a 2,3-epoxycyclopentyl group, a 3,4-epoxycyclohexyl group, and a 2,3-epoxycyclohexyl group. The group represented by -D-R^{e27} is preferably a 2-(3,4-epoxycyclohexyl)ethyl group.

Preferred examples of alkyl groups as R^{e24}, and Rees include a straight-chain or branched-chain alkyl group having 1 or more and 18 or less carbon atoms (preferably 1 or more and 6 or less carbon atoms, and particularly preferably 1 or more and 3 or less carbon atoms) such as a methyl group, an ethyl group, a propyl group, and an isopropyl group.

In the formula (E1-7), x1 represents an integer of 3 or more, and is particularly preferably an integer of 3 or more and 6 or less in view of excellent crosslinking reactivity when cured film is formed.

The number of epoxy groups possessed by the siloxane compound in a molecule is two or more, preferably 2 or more and 6 or less, and particularly preferably 2 or more and 4 or less, in view of excellent crosslinking reactivity when cured film is formed.

The photosensitive resin composition may contain, in addition to the siloxane compound represented by the formula (E1-7), compounds including a siloxane skeleton, such as an alicyclic epoxy group-containing cyclic siloxane, an alicyclic epoxy group-containing silicone resin mentioned in Japanese Unexamined Patent Application, Publication No. 2008-248169, and an organopolysilsesquioxane resin having at least two epoxy functional groups in one molecule mentioned in Japanese Unexamined Patent Application, Publication No. 2008-19422.

More specifically, cyclic siloxane compounds represented by the following formulas having two or more and six or less epoxy groups in a molecule are exemplified as the siloxane compound. Furthermore, X-40-2670, X-40-2701, X-40-2728, X-40-2738, and X-40-2740 (all manufactured by Shinetsu Chemical Co., Ltd.) may also be used as the siloxane compound.

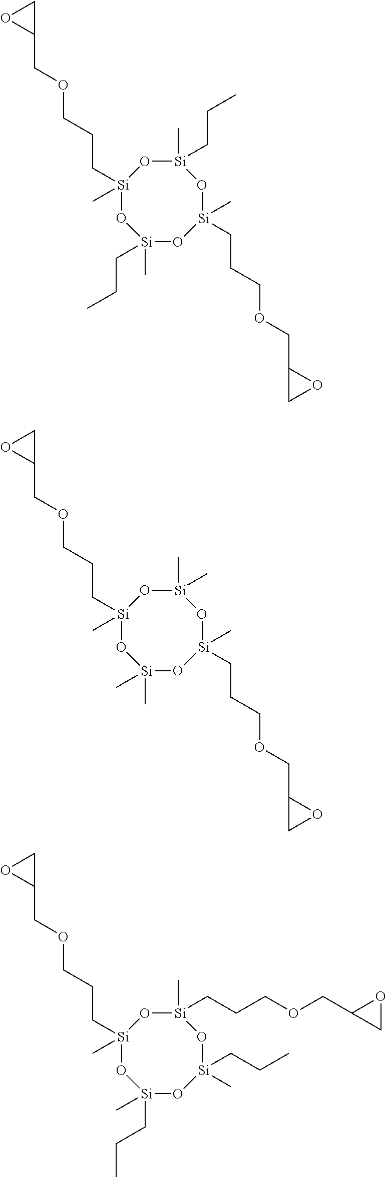 [SMILES: CCC[Si]1(C)O[Si](C)(CCCOCC2CO2)O[Si](C)(CCC)O[Si](C)(CCCOCC2CO2)O1 ; C[Si]1(C)O[Si](C)(CCCOCC2CO2)O[Si](C)(C)O[Si](C)(CCCOCC2CO2)O1 ; CCC[Si]1(C)O[Si](C)(CCC)O[Si](C)(CCCOCC2CO2)O[Si](C)(CCCOCC2CO2)O1]

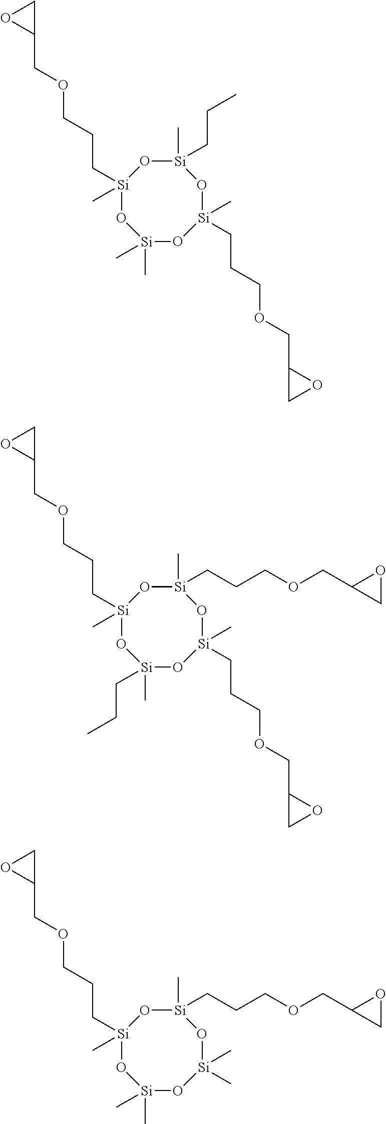 [SMILES: CCC[Si]1(C)O[Si](C)(CCCOCC2CO2)O[Si](C)(C)O[Si](C)(CCCOCC2CO2)O1 ; CCC[Si]1(C)O[Si](C)(CCCOCC2CO2)O[Si](C)(CCCOCC2CO2)O[Si](C)(CCCOCC2CO2)O1 ; C[Si]1(C)O[Si](C)(C)O[Si](C)(CCCOCC2CO2)O[Si](C)(CCCOCC2CO2)O1]

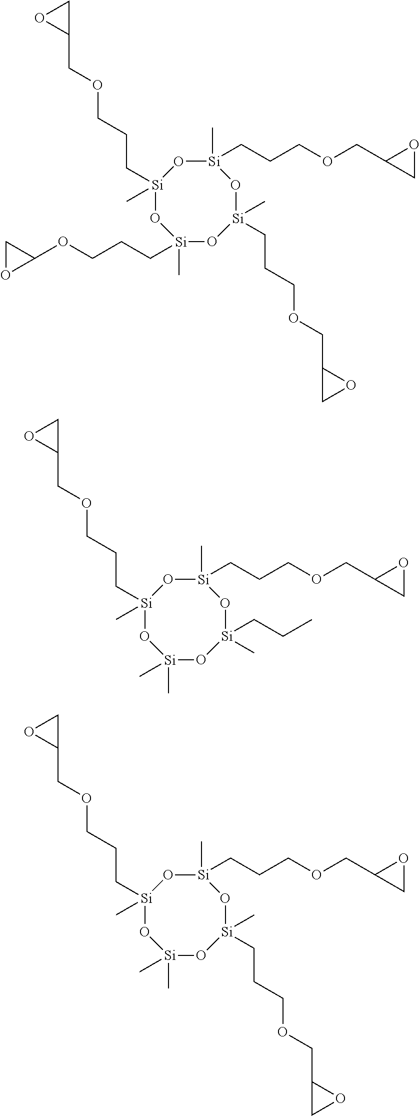 [SMILES: C[Si]1(CCCOCC2CO2)O[Si](C)(CCCOCC2CO2)O[Si](C)(CCCOC2CO2)O[Si](C)(CCCOCC2CO2)O1 ; CCC[Si]1(C)O[Si](C)(C)O[Si](C)(CCCOCC2CO2)O[Si](C)(CCCOCC2CO2)O1 ; C[Si]1(C)O[Si](C)(CCCOCC2CO2)O[Si](C)(CCCOCC2CO2)O[Si](C)(CCCOCC2CO2)O1]

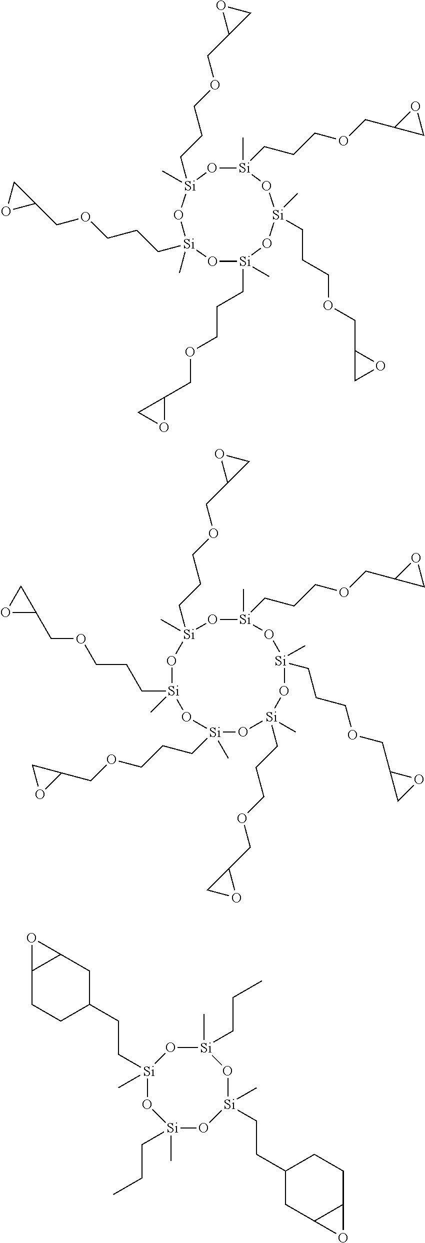 [SMILES: C[Si]1(CCCOCC2CO2)O[Si](C)(CCCOCC2CO2)O[Si](C)(CCCOCC2CO2)O[Si](C)(CCCOCC2CO2)O[Si](C)(CCCOCC2CO2)O1 ; C[Si]1(CCCOCC2CO2)O[Si](C)(CCCOCC2CO2)O[Si](C)(CCCOCC2CO2)O[Si](C)(CCCOCC2CO2)O[Si](C)(CCCOCC2CO2)O[Si](C)(CCCOCC2CO2)O1 ; CCC[Si]1(C)O[Si](C)(CCC2CCC3OC3C2)O[Si](C)(CCC)O[Si](C)(CCC2CCC3OC3C2)O1]

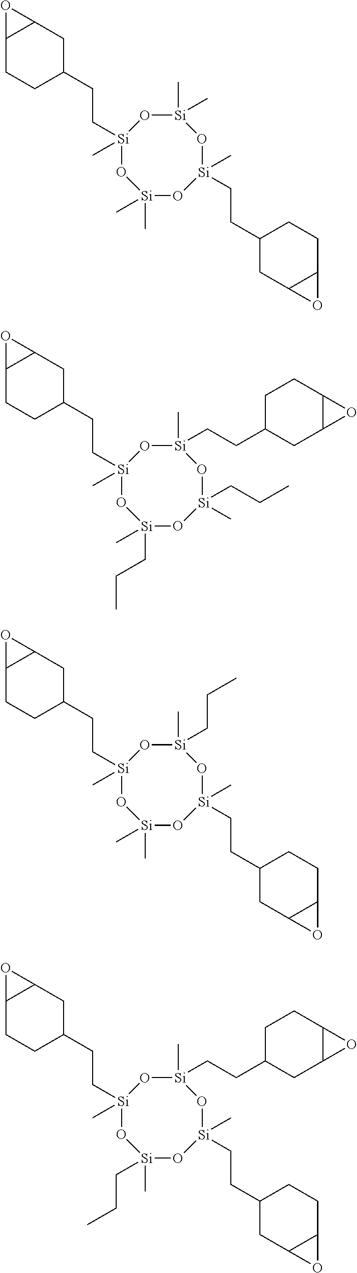 [SMILES: C[Si]1(C)O[Si](C)(CCC2CCC3OC3C2)O[Si](C)(C)O[Si](C)(CCC2CCC3OC3C2)O1 ; CCC[Si]1(C)O[Si](C)(CCC)O[Si](C)(CCC2CCC3OC3C2)O[Si](C)(CCC2CCC3OC3C2)O1 ; CCC[Si]1(C)O[Si](C)(CCC2CCC3OC3C2)O[Si](C)(C)O[Si](C)(CCC2CCC3OC3C2)O1 ; CCC[Si]1(C)O[Si](C)(CCC2CCC3OC3C2)O[Si](C)(CCC2CCC3OC3C2)O[Si](C)(CCC2CCC3OC3C2)O1]

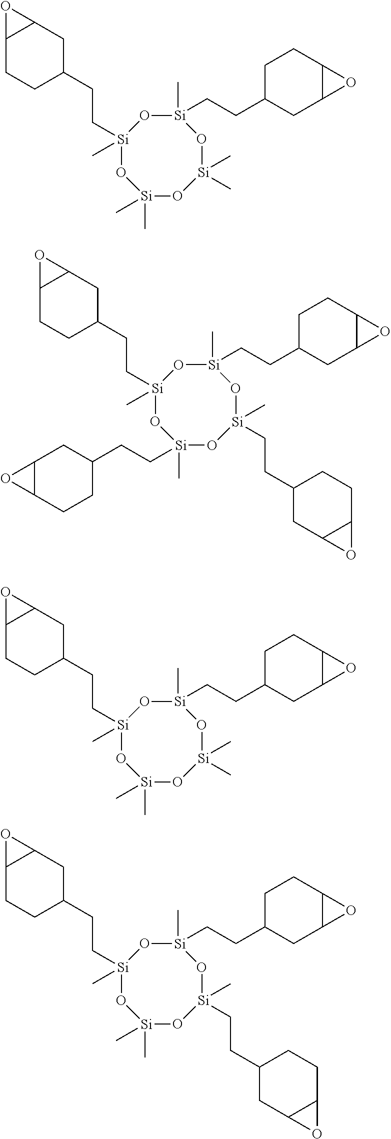 [SMILES: C[Si]1(C)O[Si](C)(C)O[Si](C)(CCC2CCC3OC3C2)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O1 ; C[Si]1(C)O[Si](C)(C)O[Si](C)(CCC2CCC3OC3C2)O[Si](C)(CCC2CCC3OC3C2)O1 ; C[Si]1(C)O[Si](C)(CCC2CCC3OC3C2)O[Si](C)(CCC2CCC3OC3C2)O[Si](C)(CCC2CCC3OC3C2)O1]

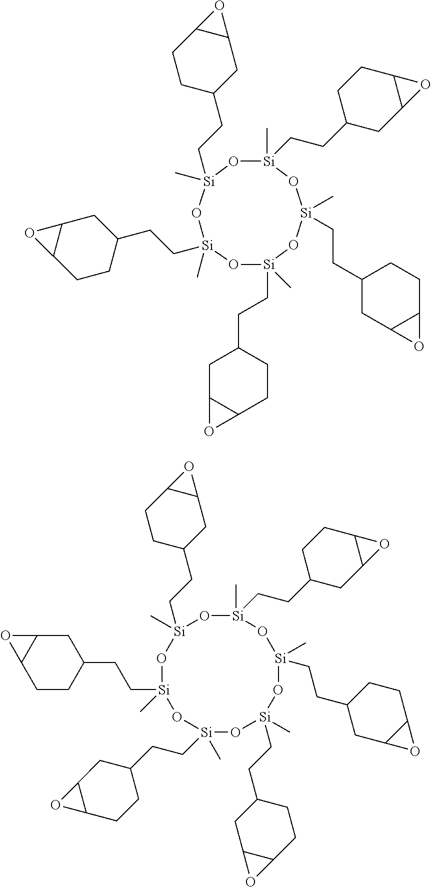

The content of the (E) thermosetting compound in the photosensitive resin composition is preferably 1% by mass or more and 15% by mass or less, more preferably, 1.5% by mass or more and 12% by mass or less, and particularly preferably 2% by mass or more and 10% by mass or less, in the total solid component of the photosensitive resin composition.

### <(F) Light Absorber>

The photosensitive resin composition may contain (F) a light absorber. The (F) light absorber is not particularly limited as long as it can absorb exposure light, and is particularly preferably a light absorber which absorbs light having a wavelength range of 200 or more and 450 nm or less. Examples thereof include a naphthalene compound, a dinaphthalene compound, an anthracene compound, a phenanthroline compound, a dye, and the like.

Specific examples thereof include cinnamic acid derivatives such as 2-ethylhexyl cinnamate, 2-ethylhexyl paramethoxycinnamate, isopropyl methoxycinnamate, and isoamyl methoxycinnamate; naphthalene derivatives such as α-naphthol, β-naphthol, α-naphtholmethylether, α-naphtholethylether, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,6-dihydroxynaphthalene, and 2,7-dihydroxynaphthalene; anthracenes and derivatives thereof such as anthracene and 9,10-dihydroxyanthracene; and dyes such as an azo-based dye, a benzophenone-based dye, an aminoketone-based dye, a quinoline-based dye, an anthraquinone-based dye, a diphenylcyanoacrylate-based dye, a triazine-based dye, and a β-aminobenzoic acid-based dye. Among these, cinnamic acid derivatives and naphthalene derivatives are preferably used, and cinnamic acid derivatives are particularly preferably used. These light absorbers can be used alone or in combination of two or more types thereof.

When the (F) light absorber is contained, the content is preferably 0.5 part by mass or more and 20 parts by mass or less based on 100 parts by mass of the solid component of the photosensitive resin composition. By adjusting within the above range, it is possible to increase a change in film thickness when an exposure dose is changed while satisfactorily maintaining the breakage strength of the cured film.

### <(S) Organic Solvent>

The photosensitive resin composition preferably contains (S) an organic solvent for dilution. Specific examples of the (S) organic solvent include (poly)alkylene glycol monoalkyl ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers such as diethylene glycol dimethyl ether, diethylene glycol methylethyl ether, diethylene glycol diethyl ether, and tetrahydrofuran; ketones such as methyl ethyl ketone, cyclohexanone, 2-heptanone, and 3-heptanone; lactic acid alkyl esters such as methyl 2-hydroxypropionate and ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl formate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, and ethyl 2-oxobutanoate; aromatic hydrocarbons such as toluene and xylene; amides such as N-methylpyrrollidone, N,N-dimethylformamide, and N,N-dimethylacetamide; and the like.

Among these, alkylene glycol monoalkyl ethers, alkylene glycol monoalkyl ether acetates, above-mentioned other ethers, lactic acid alkyl esters, and above-mentioned other esters are preferred, and alkylene glycol monoalkyl ether acetates and above-mentioned other ethers are more preferred. These solvents can be used alone, or two or more solvents can be used in combination. The content of the (S) organic solvent is preferably the amount to adjust the solid component concentration of the photosensitive resin composition to 1% by mass or more and 50% by mass or less, and more preferably 5% by mass or more and 40% by mass or less.

### <Other Components>

If necessary, the photosensitive resin composition may contain various additives. Examples of the additives include sensitizers, curing accelerators, fillers, dispersants, adhesion promoters such as silane coupling agents, antioxidants, aggregation inhibitors, thermal polymerization inhibitors, defoaming agents, surfactants, and the like.

### <Method for Preparing Resin Composition>

The photosensitive resin composition is prepared by mixing the respective components mentioned above using a stirrer. To make the thus obtained photosensitive resin composition uniform, the mixture may be filtered through a membrane filter or the like.

### <<Second Photosensitive Resin Composition>>

The second photosensitive resin composition is the same as the first photosensitive resin composition, except that it is essential that the amount of the (D1) carbon black and/or the inorganic black pigment is 30% by mass or more and 65% by mass or less, and the amount of the (D2) organic pigment is 10% by mass or more and 70% by mass or less, in the entire (D) coloring agent. The preferred compound as the (D) coloring agent and the content are as described about the first photosensitive resin composition.

The second photosensitive resin composition can achieve both high optical density and excellent curability at low temperature, like the first photosensitive resin composition, since blending of the pigment in the entire (D) coloring agent is appropriately set.

### <<Cured Film>>

Hereinafter, in the description of the cured film, both the first photosensitive resin composition and the second photosensitive resin composition are collectively called “photosensitive resin composition”, simply.

The cured film is not particularly limited as long as it is a cured film obtained by curing the above-mentioned photosensitive resin composition. There is no particular limitation on a method for forming a cured film and, typically, a cured film is formed in accordance with the pattern forming method mentioned later. In the pattern forming method mentioned later, a method including regioselective exposure and development will be described. As a matter of course, a cured film can be formed even when using a method in which the entire surface of a coating film made of a photosensitive resin composition is exposed and development is omitted.

It is preferred that an optical density (O.D.) of the cured film formed of the photosensitive resin composition is 1.5/μm or more. As the curing conditions herein, the following conditions are typically employed. It is also possible to employ, as the exposure conditions herein, conditions under which exposure was performed at an exposure gap of 50 μm using Proximity Aligner (product name: TME-150RTO) manufactured by TOPCON CORPORATION. O.D. is more preferably 2.0/μm or more, and particularly preferably 2.5/μm or more. The upper limit of O.D. is not particularly limited and is, for example, 5.0/μm or less.

### <Conditions>

The photosensitive resin composition is applied on a glass substrate in a thickness of 1±0.1 μm, followed by exposure at an exposure dose of 200 mJ/cm² and further baking under conditions at 100° C. for 30 minutes to form a cured film.

An average (%) of a transmittance at a wavelength in a range of 380 nm or more and 780 nm or less of the cured film is preferably 2% or less and more preferably 1% or less, and 0% or more.

The cured film described above is suitably used as light-shielding materials such as a black matrix and a black column spacer in various image display devices such as a liquid crystal display and an organic EL display after optionally being patterned. When using the photosensitive resin composition mentioned above, a cured film cured satisfactorily can be formed, for example, by baking at low temperature of 125° C. or lower. Therefore, the cured film can be particularly preferably used as a light-shielding material in an image display device using a material having low heat resistance.

### <<Pattern Forming Method>>

Hereinafter, in the description of the pattern forming method, both the first photosensitive resin composition and the second photosensitive resin composition are collectively called “photosensitive resin composition”, simply.

The pattern forming method is not particularly limited as long as it is a method capable of curing a coating film made of a photosensitive resin composition while patterning.

Typically, a pattern composed of a cured film obtained by curing the photosensitive resin composition mentioned above is formed by the method including the steps of:

applying the photosensitive resin composition according to claim 1 to form a coating film,
regioselectively exposing the coating film,
developing the exposed coating film, and
baking the developed coating film to obtain a cured film.

First, a photosensitive resin composition is applied on a substrate on which a pattern is to be formed using a contact transfer coating applicator such as a roll coater, a reverse coater, and a bar coater; and non-contact coaters such as a spinner (a rotary applicator) and a curtain flow coater. After applying the photosensitive resin composition, a solvent is optionally removed by drying to form a coating film. Drying is preferably performed at low temperature, for example, 80° C. or lower, and preferably 60° C. or lower so as to prevent thermal curing of the photosensitive resin composition from excessively proceeding. The lower limit of the drying temperature is not particularly limited and is, for example, 0° C. or higher, and preferably 20° C. or higher. Drying is optionally performed in a reduced-pressure atmosphere.

Next, the coating film is exposed by regioselectively irradiating with active energy rays such as ultraviolet rays and excimer laser beams through a negative mask in accordance with a desired pattern shape. During exposure, it is possible to use a light source capable of emitting ultraviolet rays, such as a high pressure mercury lamp, an ultra-high pressure mercury lamp, a xenon lamp, and a carbon arc lamp. An exposure dose varies depending on the composition of the photosensitive resin composition and is preferably, for example, about 10 mJ/cm² or more and 600 mJ/cm² or less.

When an element is formed on a substrate such as a TFT substrate, it is sometimes necessary to form a pattern of the cured film on the element, or on the position facing an element of a substrate which is paired with the substrate on which the element is formed. In such case, it is necessary to change the height of the cured film at the position where the element is formed and other positions, taking the height of the element into consideration. In such case, exposure is preferably performed through a half-tone mask.

Next, the exposed coating film is developed with a developing solution to form a pattern of the cured film. The developing method is not particularly limited, and it is possible to use an immersion method, a spraying method, and the like. Specific examples of the developing solution include aqueous solutions of organic compounds such as monoethanolamine, diethanolamine, and triethanolamine; sodium hydroxide, potassium hydroxide, sodium carbonate, ammonia, quaternary ammonium salt, and the like.

Thereafter, the developed coating film is cured with heating by baking. The baking temperature can be set, for example, at 150° C. or lower, 145° C. or lower, or 140° C. or lower. The baking temperature is preferably 135° C. or lower, more preferably 130° C. or lower, still more preferably 125° C. or lower, yet more preferably 120° C. or lower, further preferably 115° C. or lower, and particularly preferably 110° C. or lower. The lower limit of the baking temperature is not particularly limited as long as curing of the coating film satisfactory proceeds, and is preferably 70° C. or higher, and more preferably 80° C. or higher. The baking time is not particularly limited, and baking is performed until curing of the coating film sufficiently proceeds. Typically, the baking time is preferably 15 to 60 minutes.

The pattern forming method mentioned above can also be applied to a substrate provided with a light-emitting element, and typically,

it is possible to form a pattern composed of a cured film obtained by curing the above photosensitive resin composition to the substrate provided with a light-emitting element, by the method including the steps of:
applying the photosensitive resin composition to the substrate provided with a light-emitting element to form a coating film,
regioselectively exposing the coating film,
developing the exposed coating film, and
baking the developed coating film to obtain a cured film.

Regarding the substrate provided with a light-emitting element, a light-emitting element is formed in advance in the substrate on which a pattern is to be formed, or a light-emitting element is formed in the substrate during the process of forming a pattern. Like the pattern forming method mentioned above, the photosensitive resin composition is cured with heating by baking after regioselective exposure of the coating film and development. It is possible to preferably use, as the baking temperature and time, the temperature and time mentioned above.

Herein, the light-emitting element is a light-emitting element using an organic substance as a light-emitting material as an example, and specific examples thereof include an organic EL element, an organic electrochemical light-emitting element (OECL), an organic light-emitting transistor (OLET), a wavelength conversion display element due to quantum dot-polymer matrix, and the like. The light-emitting element using an organic substance as a light-emitting material generally tends to exhibit low heat resistance, and the above-mentioned pattern forming method to the substrate provided with a light-emitting element can be suitably used since it is a production process with less thermal damage.

Aspects of the present invention include reference aspects shown in the following [1] to [14].

[1]
A photosensitive resin composition including:
(A) a binder resin,
(B) a photopolymerizable compound,
(C) a photopolymerization initiator,
(D) a coloring agent, and
(E) a thermosetting compound, wherein
the (D) coloring agent includes (D1) a carbon black and/or an inorganic black pigment, and (D2) an organic black pigment, and wherein
when the photosensitive resin composition is cured under the following conditions to obtain a cured film, T2/T1 is 0.80 or more, where T1 is a thickness of the cured film and T2 is a thickness of the cured film after immersing in propylene glycol monomethyl ether acetate for 300 seconds:

### (Conditions)

the photosensitive resin composition is applied on a glass substrate in a thickness of 1±0.1 μm, followed by exposure at an exposure dose of 200 mJ/cm² and further baking under conditions at 100° C. for 30 minutes to form a cured film.
[2]
A photosensitive resin composition including:
(A) a binder resin,
(B) a photopolymerizable compound,
(C) a photopolymerization initiator,
(D) a coloring agent, and
(E) a thermosetting compound, wherein
the (D) coloring agent includes (D1) a carbon black and/or an inorganic black pigment, and (D2) an organic black pigment, and wherein
the amount of the (D1) carbon black and/or the inorganic black pigment in the total (D) coloring agent is 30% by mass or more and 65% by mass or less, and the amount of the (D2) organic black pigment is 10% by mass or more and 70% by mass or less.
[3]
The photosensitive resin composition according to [1] or [2], wherein the content of the (E) thermosetting compound in the total solid component of the photosensitive resin composition is 1% by mass or more and 15% by mass or less.
[4]
The photosensitive resin composition according to any one of [1] to [3], wherein the (E) thermosetting compound is (E1) a polyfunctional epoxy compound.
[5]

The photosensitive resin composition according to any one of [1] to [4], wherein the organic black pigment (D2) includes one or more selected from (D2a) a perylene-based pigment and (D2b) a lactam-based pigment.

[6]
The photosensitive resin composition according to any one of [1] to [5], which is used to form a black matrix.
[7]
The photosensitive resin composition according to any one of [1] to [6], wherein the (A) binder resin is an alkali-soluble resin.
[8]
The photosensitive resin composition according to [7], wherein the alkali-soluble resin contains a resin having a photopolymerizable group in a molecule.
[9]
The photosensitive resin composition according to [7] or [8], wherein the alkali-soluble resin contains a resin having a cardo structure in a molecule.
[10]
The photosensitive resin composition according to any one of [1] to [9], wherein an optical density (O.D.) when forming a cured film is 1.5/μm or more.
[11]
A cured film obtained by curing the photosensitive resin composition according to any one of [1] to [10].
[12]
A display device including the cured film according to [11].
[13]
A pattern forming method, which includes the steps of: applying the photosensitive resin composition according to any one of [1] to [10] to form a coating film, regioselectively exposing the coating film, developing the exposed coating film, and baking the developed coating film to obtain a cured film.
[14]
The pattern forming method according to [13], wherein baking of the developed coating film is performed at 150° C. or lower.

### EXAMPLES

The present invention will be more specifically described below by way of Examples, but the scope of the present invention is not limited to these Examples.

### Example 1, Example 2, and Comparative Examples 1 to 3

In Examples and Comparative Examples, a resin A1 which is an alkali-soluble cardo resin was used as (A) a binder resin ((A) component). The resin A1 is the resin obtained in the following Preparation Example 1.

### Preparation Example 1

First, in a 500 ml four-necked flask, 235 g of a bisphenol fluorene type epoxy resin (epoxy equivalent of 235), 110 mg of tetramethylammonium chloride, 100 mg of 2,6-di-tert-butyl-4-methylphenol, and 72.0 g of acrylic acid were charged, followed by dissolution with heating at 90 to 100° C. while blowing air at a rate of 25 ml/minute. The temperature was gradually raised in a state where the solution is in a white turbid state, followed by complete dissolution by heating to 120° C. In this case, although the solution gradually became transparent and viscous, stirring was continued. During stirring, an acid value was measured and stirring with heating was continued until the acid value became less than 1.0 mgKOH/g. It required 12 hours until the acid value reached the target. After cooling to room temperature, a bisphenol fluorene type epoxy acrylate represented by the following formula, which is colorless and transparent and is solid, was obtained.

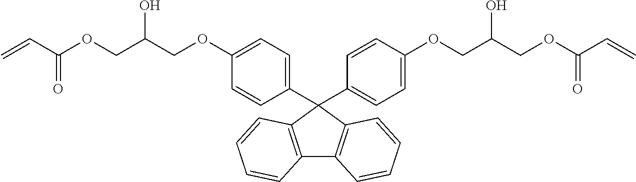 [SMILES: C=CC(=O)OCC(O)COc1ccc(C2(c3ccc(OCC(O)COC(=O)C=C)cc3)c3ccccc3-c3ccccc32)cc1]

After dissolving 307.0 g of the thus obtained bisphenol fluorene type epoxy acrylate by adding 600 g of 3-methoxybutyl acetate thereto, 80.5 g of benzophenonetetracarboxylic dianhydride and 1 g of tetraethylammonium bromide were mixed and the mixture was reacted at 110 to 115° C. for 4 hours by gradually raising the temperature. After confirming the disappearance of an acid anhydride group, 38.0 g of 1,2,3,6-tetrahydrophthalic anhydride was mixed, followed by a reaction at 90° C. for 6 hours to obtain a resin A1. The disappearance of the acid anhydride group was confirmed by IR spectrum.

In Examples and Comparative Examples, dipentaerythritol hexaacrylate was used as (B) a photopolymerizable compound ((B) component).

In Examples and Comparative Examples, a compound represented by the following formula was used as (C) a photopolymerization initiator ((C) component).

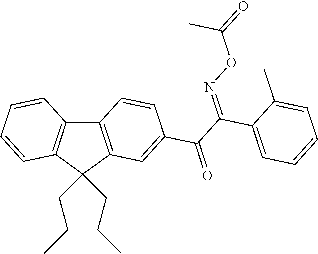 [SMILES: CCCC1(CCC)c2ccccc2-c2ccc(C(=O)/C(=N/OC(C)=O)c3ccccc3C)cc21]

In Examples and Comparative Examples, the following D1 to D3 were used as (D) a coloring agent ((D) component). The contents of D1 to D3 (% by mass) in the (D) coloring agent are shown in Table 1 below. In Table 1, the numerical values of the total value of the solid component of the pigment and the dispersant contained in a pigment dispersion are shown. D1: Carbon black dispersion (urethane-based resin dispersion, volume average particle diameter of 150 nm or less)

D2: Perylene-based black pigment dispersion (volume average particle diameter of 150 nm or less)
D3: Lactam-based black pigment dispersion (volume average molecular weight of 150 nm or less)

In Examples and Comparative Examples, a compound of the following formula was used as (E) a thermosetting compound ((E) component).

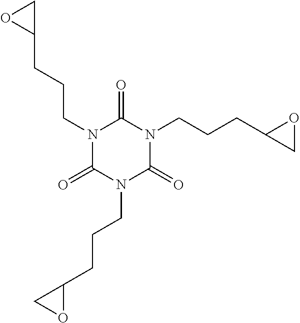 [SMILES: O=c1n(CCCC2CO2)c(=O)n(CCCC2CO2)c(=O)n1CCCC1CO1]

20 parts by mass of the (A) component, 3 parts by mass of the (B) component, 3 parts by mass of the (C) component, the (D) component of type and amount (mass ratio) shown in Table 1 (the entire amount of the (D) component is 70 parts by mass), and 4 parts by mass of the (E) component were uniformly dissolved and dispersed in a mixed solvent of 20% by mass of 3-methoxybutyl acetate and 80% by mass of propylene glycol monomethyl ether acetate so that the solid component concentration became 20% by mass to obtain photosensitive resin compositions of Examples 1 and 2, and Comparative Examples 1 and 2. In the same manner as in Example 1, except that the (E) component was not used, the amount of the (A) component was changed to 22 parts by mass, and the amount of the (B) component was changed to 5 parts by mass, a photosensitive resin composition of Comparative Example 3 was obtained.

### Test Example 1

The photosensitive resin composition thus obtained was cured under the following conditions to obtain a cured film, and curability at low temperature at 100° C. was evaluated by the value of T2/T1 where T1 is a thickness of the cured film and T2 is a thickness of the cured film after immersing in propylene glycol monomethyl ether acetate for 300 seconds.

### (Conditions)

The photosensitive resin composition is applied on a glass substrate in a thickness of 1±0.1 μm, followed by exposure at an exposure dose of 200 mJ/cm² and further baking under conditions at 100° C. for 30 minutes to form a cured film.

An average (%) of a transmittance at a wavelength in a range of 380 nm or more and 780 nm or less of the cured film formed under the above conditions was measured.

These evaluation results are shown in Table 1.

TABLE 1

| | (D) Coloring agent (Mass ratio) | | | | |
|---|---|---|---|---|---|
| | | D2 | D3 | | |
| | D1 | Perylene- | Lactam- | Curability | |
| | Carbon | based | based | (100° C.) | Transmittance |
| | black | pigment | pigment | T2/T1 | (%) |
| Example 1 | 45 | — | 55 | 0.95 | 1 |
| Example 2 | 45 | 55 | — | 0.95 | 2 |
| Comparative | 80 | — | 20 | 0.70 | 1 |
| Example 1 | | | | | |
| Comparative | 70 | — | 30 | 0.70 | 1 |
| Example 2 | | | | | |
| Comparative | 45 | — | 55 | 0.75 | 1 |
| Example 3 | | | | | |

As is apparent from Example 1 and Example 2, in a photosensitive resin composition including (A) a binder resin, (B) a photopolymerizable compound, (C) a photopolymerization initiator, (D) a coloring agent, and (E) a thermosetting compound, by adjusting the contents of (D1) a carbon black and/or an inorganic black pigment and (D2) an organic pigment, it is possible to achieve both formation of a cured film excellent in light shielding properties and satisfactory curing of a coating film by baking at low temperature (100° C.)

As is apparent from Comparative Example 1 and Comparative Example 2, when the amount of carbon black is excessive, it is difficult to satisfactory cure a coating film made of the photosensitive resin composition by baking at low temperature (100° C.). As is apparent from Comparative Example 3, when the photosensitive resin composition does not contain (E) a thermosetting compound, it is also difficult to satisfactorily cure a coating film made of the photosensitive resin composition by baking at low temperature (100° C.)

### Test Example 2

In the same manner as in Test Example 1, except that the baking temperature of the photosensitive resin compositions of Comparative Examples 1 to 3 was changed to 110° C., 120° C., 130° C., 140° C., or 150° C., a cured film was fabricated and evaluated, and the baking temperature at which T2/T1 became 0.95 or more was determined.

Regarding the photosensitive resin compositions of Comparative Examples 1 to 2, T2/T1 became 0.95 or more at the baking temperature of 130° C. Regarding the photosensitive resin composition of Comparative Example 3, T2/T1 became 0.95 or more at the baking temperature of 150° C. The baking temperature can impart thermal damage to a substrate provided with an organic light-emitting element. From such a point of view, it can be said that the photosensitive resin compositions of Examples 1 and 2, which are preferably cured even at low temperature, are useful to construct a device provided with a light-emitting element.

What is claimed is:

1. A photosensitive resin composition used to form a pattern on a substrate provided with a light-emitting element, the photosensitive resin composition comprising:
(A) a binder resin;
(B) a photopolymerizable compound;
(C) a photopolymerization initiator;
(D) a coloring agent; and
(E) a thermosetting compound, wherein
the (D) coloring agent comprises (D1) a carbon black and/or an inorganic black pigment, and (D2) an organic black pigment, and wherein
when the photosensitive resin composition is cured under the following conditions to obtain a cured film, T2/T1 is 0.80 or more, where T1 is a thickness of the cured film and T2 is a thickness of the cured film after immersing in propylene glycol monomethyl ether acetate for 300 seconds:
(Conditions)
the photosensitive resin composition is applied on a glass substrate in a thickness of 1±0.1 μm, followed by exposure at an exposure dose of 200 mJ/cm2 and further baking under conditions at 100° C. for 30 minutes to form a cured film.

2. A photosensitive resin composition comprising:
(A) a binder resin;
(B) a photopolymerizable compound;
(C) a photopolymerization initiator;
(D) a coloring agent; and
(E) a thermosetting compound, wherein
the (D) coloring agent comprises (D1) a carbon black and/or an inorganic black pigment, and (D2) an organic black pigment, and wherein
the amount of the (D1) carbon black and/or the inorganic black pigment in the total (D) coloring agent is 30% by mass or more and 65% by mass or less, and the amount of the (D2) organic black pigment is 10% by mass or more and 70% by mass or less.

3. The photosensitive resin composition according to claim 1, wherein the (E) thermosetting compound is (E1) a polyfunctional epoxy compound.

4. The photosensitive resin composition according to claim 1, wherein the (D2) organic black pigment comprises one or more selected from the group consisting of (D2a) a perylene-based pigment and (D2b) a lactam-based pigment.

5. The photosensitive resin composition according to claim 1, wherein the (A) binder resin is an alkali-soluble resin.

6. The photosensitive resin composition according to claim 1, wherein an optical density (O.D.) when forming a cured film is 1.5/μm or more.

7. A cured film obtained by curing the photosensitive resin composition according to claim 1.

8. A display device comprising the cured film according to claim 7.

9. A pattern forming method, comprising:
applying the photosensitive resin composition according to claim 1 to form a coating film;
regioselectively exposing the coating film;
developing the exposed coating film; and
baking the developed coating film to obtain a cured film.

10. The pattern forming method according to claim 9, wherein baking of the developed coating film is performed at 125° C. or lower.

11. The photosensitive resin composition according to claim 2, wherein the (E) thermosetting compound is (E1) a polyfunctional epoxy compound.

12. The photosensitive resin composition according to claim 2, wherein the (D2) organic black pigment comprises one or more selected from the group consisting of (D2a) a perylene-based pigment and (D2b) a lactam-based pigment.

13. The photosensitive resin composition according to claim 2, wherein the (A) binder resin is an alkali-soluble resin.

14. The photosensitive resin composition according to claim 2, wherein an optical density (O.D.) when forming a cured film is 1.5/μm or more.

15. A cured film obtained by curing the photosensitive resin composition according to claim 2.

16. A display device comprising the cured film according to claim 15.

17. A pattern forming method, comprising:
applying the photosensitive resin composition according to claim 2 to form a coating film;
regioselectively exposing the coating film;
developing the exposed coating film; and
baking the developed coating film to obtain a cured film.

18. The pattern forming method according to claim 17, wherein baking of the developed coating film is performed at 125° C. or lower.

19. A pattern forming method, comprising:
applying a photosensitive resin composition to a substrate provided with a light-emitting element to form a coating film;
regioselectively exposing the coating film;
developing exposed coating film; and
baking the developed coating film to obtain a cured film,
wherein
the photosensitive resin composition comprises:
(A) a binder resin;
(B) a photopolymerizable compound;
(C) a photopolymerization initiator;
(D) a coloring agent; and
(E) a thermosetting compound, wherein
the (D) coloring agent comprises (D1) a carbon black and/or an inorganic black pigment, and (D2) an organic black pigment, and wherein
when the photosensitive resin composition is cured under the following conditions to obtain a cured film, T2/T1 is 0.80 or more, where T1 is a thickness of the cured film and T2 is a thickness of the cured film after immersing in propylene glycol monomethyl ether acetate for 300 seconds:
(Conditions)
the photosensitive resin composition is applied on a glass substrate in a thickness of 1±0.1 μm, followed by exposure at an exposure dose of 200 mJ/cm2 and further baking under conditions at 100° C. for 30 minutes to form a cured film.

20. The pattern forming method according to claim 19, wherein baking of the developed coating film is performed at 125° C. or lower.
